(19) United States
(12) Patent Application Publication
(10) Pub. No.: US 2025/0185229 A1
(43) Pub. Date: Jun. 5, 2025

(54) Semiconductor Device

(71) Applicant: Semiconductor Energy Laboratory Co., Ltd., Kanagawa-ken (JP)

(72) Inventors: Tatsuya ONUKI, Atsugi, Kanagawa (JP); Hitoshi KUNITAKE, Machida, Tokyo (JP); Motoki NAKASHIMA, Atsugi, Kanagawa (JP); Shunpei YAMAZAKI, Setagaya, Tokyo (JP)

(73) Assignee: Semiconductor Energy Laboratory Co., Ltd., Kanagawa-ken (JP)

(21) Appl. No.: 18/842,344

(22) PCT Filed: Feb. 21, 2023
(86) PCT No.: PCT/IB2023/051550

§ 371 Date: Aug. 28, 2024

(30) Foreign Application Priority Data
Mar. 4, 2022 (JP) 2022-033577

(51) Int. Cl. H10B 12/00

(52) U.S. Cl. CPC H10B 12/00

(57) ABSTRACT

A semiconductor device that can be miniaturized or highly integrated is provided. The semiconductor device includes first and second transistors and a capacitor. The first transistor is provided in the same layer as the second transistor. Each of the first and second transistors includes second to fourth conductors, a metal oxide, and a first insulator. The third conductor is provided over the second conductor. The third conductor includes an opening overlapping with the second conductor. The metal oxide includes a region in contact with the side surface of the opening and the top surface of the second conductor. The first insulator is provided in a concave portion of the metal oxide. The fourth conductor is provided in a concave portion of the first insulator and includes a region overlapping with the metal oxide with the first insulator therebetween. The capacitor includes a fifth conductor, a second insulator over the fifth conductor, and a sixth conductor over the second insulator. The fifth conductor is electrically connected to the second conductor included in the first transistor and the fourth conductor included in the second transistor.

### TECHNICAL FIELD

One embodiment of the present invention relates to a semiconductor device, a storage device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method of manufacturing any of them.

In this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, semiconductor devices such as an LSI (Large Scale Integration), a CPU (Central Processing Unit), and a memory (memory device) have been developed. These semiconductor devices have been used in various electronic devices such as computers and portable information terminals. In addition, memories under development employ various memory systems for intended uses such as temporary storage at the time of executing arithmetic processing and long-term storage of data. Memories with typical memory systems include a DRAM (Dynamic Random Access Memory), an SRAM (Static Random Access Memory), and a flash memory.

With the increase in the amount of data dealt with, semiconductor devices having a larger memory capacity have been required. Patent Document 1 and Non-Patent Document 1 disclose memory cells in which transistors are stacked.

In order to increase the memory capacity of the semiconductor device, miniaturization of transistors included in the semiconductor device has been promoted. To miniaturize the transistors, a transistor having a vertical structure has been actively studied. For example, Non-Patent Document 2 and Non-Patent Document 3 disclose a transistor having a vertical structure including a metal oxide in a region where a channel is formed (also referred to as a channel formation region).

### REFERENCES

### Patent Document

[Patent Document 1] PCT International Publication No. 2021/053473

### Non-Patent Documents

[Non-Patent Document 1] M. Oota, et al, “3D-Stacked CAAC-In—Ga—Zn Oxide FETs with Gate Length of 72 nm”, IEDM Tech. Dig., 2019, pp. 50-53
[Non-Patent Document 2] X. Duan et al, “Novel Vertical Channel-All-Around (CAA) IGZO FETs for 2TOC DRAM with High Density beyond 4F2 by Monolithic Stacking”, IEDM Tech. Dig., 2021, pp. 222-225
[Non-Patent Document 3] H. Fujiwara et al, “Surrounding Gate Vertical-Channel FET with Gate Length of 40 nm Using BEOL Compatible High-Thermal-Tolerance In—Al—Zn Oxide Channel”, 2020 Symposium on VLSI Technology, TH2.2

### SUMMARY OF THE INVENTION

### Problems to be Solved by the Invention

An object of one embodiment of the present invention is to provide a semiconductor device that can be scaled down or highly integrated. Another object of one embodiment of the present invention is to provide a semiconductor device with a high operating speed. Another object of one embodiment of the present invention is to provide a semiconductor device having excellent electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device.

Another object of one embodiment of the present invention is to provide a memory device having large memory capacity. Another object of one embodiment of the present invention is to provide a memory device occupying a small area. Another object of one embodiment of the present invention is to provide a highly reliable memory device. Another object of one embodiment of the present invention is to provide a memory device with low power consumption. Another object of one embodiment of the present invention is to provide a novel memory device.

Note that the description of these objects does not preclude the presence of other objects. One embodiment of the present invention does not need to achieve all of these objects. Other objects can be derived from the description of the specification, the drawings, and the claims.

### Means for Solving the Problems

One embodiment of the present invention is a semiconductor device including a first transistor, a second transistor, a capacitor, and a first conductor. The first transistor is provided in the same layer as the second transistor. Each of the first transistor and the second transistor includes a second conductor to a fourth conductor, a metal oxide, and a first insulator. The third conductor is provided over the second conductor. The third conductor includes an opening overlapping with the second conductor in the top view. The metal oxide includes a region in contact with each of the side surface of the opening and the top surface of the second conductor. The first insulator is provided in a concave portion of the metal oxide. The fourth conductor is provided in a concave portion of the first insulator. The fourth conductor includes a region overlapping with the metal oxide with the first insulator therebetween in a region between the second conductor and the third conductor in the cross-sectional view. The capacitor is provided over the second transistor. The capacitor includes a fifth conductor, a second insulator over the fifth conductor, and a sixth conductor over the second insulator. The fifth conductor is electrically connected to the second conductor included in the first transistor through the first conductor. The fifth conductor is electrically connected to the fourth conductor included in the second transistor.

In the above semiconductor device, it is preferable that the seventh conductor be further included, the seventh conductor be electrically connected to the fourth conductor included in the first transistor, the seventh conductor be provided in the same layer as the fifth conductor, and the direction in which the seventh conductor extends be the same as the direction in which the sixth conductor extends.

One embodiment of the present invention is a semiconductor device including a first transistor, a second transistor, a capacitor, and a first conductor. The first transistor is provided in the same layer as the second transistor. Each of the first transistor and the second transistor includes a second conductor to a fourth conductor, a metal oxide, and a first insulator. The third conductor is provided over the second conductor. The third conductor includes an opening overlapping with the second conductor in the top view. The metal oxide includes a region in contact with the side surface of the opening and the top surface of the second conductor. The first insulator is provided in a concave portion of the metal oxide. The fourth conductor is provided in a concave portion of the first insulator. The fourth conductor includes a region overlapping with the metal oxide with the first insulator therebetween in a region between the second conductor and the third conductor in the cross-sectional view. The capacitor includes the second conductor included in the first transistor, a second insulator, and a fifth conductor. The second insulator is provided below the second conductor included in the first transistor. The fifth conductor is provided below the second insulator. The second conductor included in the first transistor is electrically connected to the fourth conductor included in the second transistor through the first conductor.

In the above semiconductor device, it is preferable that the sixth conductor be further included, the sixth conductor be electrically connected to the fourth conductor included in the first transistor, and the direction in which the sixth conductor extends be the same as the direction in which the fifth conductor extends.

In the above semiconductor device, it is preferable that the channel length of the second transistor be larger than the channel length of the first transistor. In the above semiconductor device, it is preferable that the shortest distance from the top surface of the second conductor to the bottom surface of the third conductor in the second transistor be larger than the shortest distance from the top surface of the second conductor to the bottom surface of the third conductor in the first transistor.

In the above semiconductor device, it is preferable that the channel width of the second transistor be larger than the channel width of the first transistor. In the above semiconductor device, it is preferable that the diameter of the opening provided in the third conductor included in the second transistor be larger than the diameter of the opening provided in the third conductor included in the first transistor.

Another embodiment of the present invention is a semiconductor device including a first transistor, a second transistor, a capacitor, and a first conductor. The first transistor is provided in the same layer as the second transistor. Each of the first transistor and the second transistor includes a second conductor to a fourth conductor, a metal oxide, and a first insulator. The fourth conductor is provided over the second conductor. The fourth conductor includes an opening overlapping with the second conductor in the top view. The third conductor is provided over the fourth conductor. The third conductor includes a region overlapping with the opening. The first insulator includes a region in contact with the side surface of the opening. The metal oxide includes a region in contact with the top surface of the second conductor, a region in contact with the bottom surface of the third conductor, and a region overlapping with the fourth conductor with the first insulator therebetween. The capacitor includes the second conductor included in the first transistor, a second insulator, and a fifth conductor. The second insulator is provided below the second conductor included in the first transistor. The fifth conductor is provided below the second insulator. The second conductor included in the first transistor is electrically connected to the fourth conductor included in the second transistor through the first conductor.

In the above semiconductor device, it is preferable that the channel length of the second transistor be larger than the channel length of the first transistor.

In the above semiconductor device, it is preferable that the channel width of the second transistor be larger than the channel width of the first transistor. In the above semiconductor device, it is preferable that the diameter of an opening provided in the fourth conductor included in the second transistor be larger than the diameter of an opening provided in the fourth conductor included in the first transistor.

In the above semiconductor device, it is preferable that the metal oxide include two or three selected from indium, an element M, and zinc, and the element M be one or more kinds selected from aluminum, gallium, yttrium, and tin.

### Effect of the Invention

According to one embodiment of the present invention, a semiconductor device that can be scaled down or highly integrated can be provided. According to one embodiment of the present invention, a semiconductor device with high operating speed can be provided. According to one embodiment of the present invention, a semiconductor device having favorable electrical characteristics can be provided. According to one embodiment of the present invention, a semiconductor device with a small variation in electrical characteristics of transistors can be provided. According to one embodiment of the present invention, a highly reliable semiconductor device can be provided. According to one embodiment of the present invention, a semiconductor device with a high on-state current can be provided. According to one embodiment of the present invention, a semiconductor device with low power consumption can be provided. According to one embodiment of the present invention, a novel semiconductor device can be provided.

According to one embodiment of the present invention, a memory device having a large memory capacity can be provided. According to one embodiment of the present invention, a memory device occupying a small area can be provided. According to one embodiment of the present invention, a highly reliable memory device can be provided. According to one embodiment of the present invention, a memory device with low power consumption can be provided. According to one embodiment of the present invention, a novel memory device can be provided.

Note that the description of these effects does not preclude the presence of other effects. One embodiment of the present invention does not necessarily have all the effects. Other effects can be derived from the description of the specification, the drawings, and the claims.

### BRIEF DESCRIPTION OF THE DRAWINGS

FIG. 1A is a top view illustrating a structure example of a semiconductor device. FIG. 1B is a cross-sectional view illustrating the structure example of the semiconductor device. FIG. 1C is a circuit diagram illustrating the structure of the semiconductor device.

FIG. 2 is a top view illustrating a structure example of a semiconductor device.

FIG. 3A and FIG. 3D are top views each illustrating a structure example of a transistor. FIG. 3B and FIG. 3C are cross-sectional views each illustrating the structure example of the transistor.

FIG. 4A to FIG. 4D are cross-sectional views each illustrating a structure example of the transistor.

FIG. 5A, FIG. 5D, and FIG. 5E are top views each illustrating a structure example of a transistor.

FIG. 5B and FIG. 5C are cross-sectional views illustrating the structure example of the transistor.

FIG. 6A to FIG. 6C are cross-sectional views each illustrating a structure example of a transistor.

FIG. 7A, FIG. 7C, FIG. 7E, and FIG. 7G are top views each illustrating a structure example of a capacitor. FIG. 7B, FIG. 7D, FIG. 7F, and FIG. 7H are cross-sectional views each illustrating the structure example of the capacitor.

FIG. 8 is a cross-sectional view illustrating a structure example of a semiconductor device.

FIG. 9A and FIG. 9B are top views each illustrating a structure example of a semiconductor device.

FIG. 10A is a top view illustrating a structure example of a semiconductor device. FIG. 10B is a cross-sectional view illustrating the structure example of the semiconductor device. FIG. 10C is a circuit diagram illustrating a structure of the semiconductor device.

FIG. 11A to FIG. 11C are top views each illustrating a structure example of a semiconductor device.

FIG. 12A is a top view illustrating a structure example of a semiconductor device. FIG. 12B is a cross-sectional view illustrating the structure example of the semiconductor device. FIG. 12C is a circuit diagram illustrating a structure of the semiconductor device.

FIG. 13A is a cross-sectional view illustrating a structure example of a semiconductor device.

FIG. 13B is a circuit diagram illustrating a structure of the semiconductor device.

FIG. 14A and FIG. 14B are cross-sectional views each illustrating a structure example of a semiconductor device.

FIG. 15A is a top view illustrating a structure example of a semiconductor device. FIG. 15B is a cross-sectional view illustrating the structure example of the semiconductor device. FIG. 15C is a circuit diagram illustrating a structure of the semiconductor device.

FIG. 16A and FIG. 16B are cross-sectional views each illustrating a structure example of a semiconductor device.

FIG. 17A is a cross-sectional view illustrating a structure example of a semiconductor device.

FIG. 17B is a circuit diagram illustrating a structure of the semiconductor device.

FIG. 18A is a top view illustrating a structure example of a semiconductor device. FIG. 18B is a cross-sectional view illustrating the structure example of the semiconductor device. FIG. 18C is a circuit diagram illustrating a structure of the semiconductor device.

FIG. 19 is a cross-sectional view illustrating a structure example of a semiconductor device.

FIG. 20A and FIG. 20D are top views each illustrating a structure example of a transistor. FIG. 20B and FIG. 20C are cross-sectional views each illustrating the structure example of the transistor.

FIG. 21 is a cross-sectional view illustrating a structure example of a transistor.

FIG. 22 is a cross-sectional view illustrating a structure example of a semiconductor device.

FIG. 23A and FIG. 23B are diagrams each illustrating an example of a memory device.

FIG. 24 is a circuit diagram illustrating an example of a memory layer.

FIG. 25 is a timing chart for showing an operation example of a memory cell.

FIG. 26A and FIG. 26B are circuit diagrams each illustrating an operation example of a memory cell

FIG. 27A and FIG. 27B are circuit diagrams each illustrating an operation example of a memory cell FIG. 28 is a circuit diagram illustrating a structure example of a semiconductor device.

FIG. 29A and FIG. 29B are cross-sectional views each illustrating an example of a semiconductor device.

FIG. 30A and FIG. 30B are diagrams each illustrating an example of an electronic device.

FIG. 31A to FIG. 31J are diagrams each illustrating an example of an electronic device.

FIG. 32A to FIG. 32E are diagrams each illustrating an example of an electronic device.

FIG. 33A to FIG. 33C are diagrams each illustrating an example of an electronic device.

FIG. 34 is a diagram illustrating an example of a device for space.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same reference numerals are commonly used for the same portions or portions having similar functions in different drawings, and a repeated description thereof is omitted. The same hatching pattern is used for portions having similar functions, and the portions are not denoted by specific reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or claims in some cases.

Note that the term “film” and the term “layer” can be used interchangeably depending on the case or the situation. For example, the term “conductive layer” can be replaced with the term “conductive film”. For another example, the term “insulating film” can be replaced with the term “insulating layer”.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

Note that in this specification and the like, an oxynitride refers to a material in which the oxygen content is higher than the nitrogen content, and a nitride oxide refers to a material in which the nitrogen content is higher than the oxygen content. For example, silicon oxynitride refers to a material in which the oxygen content is higher than the nitrogen content, and silicon nitride oxide refers to a material in which the nitrogen content is higher than the oxygen content.

In this specification and the like, terms for describing positioning, such as “over”, “under”, “above”, and “below”, are sometimes used for convenience to describe the positional relationship between components with reference to drawings. The positional relationship between components is changed as appropriate in accordance with a direction in which each component is described. Thus, the positional relationship is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

Note that in this specification and the like, the expression “level with” indicates a structure having the same level from a reference surface (e.g., a flat surface such as a substrate surface) in the cross-sectional view. For example, in a manufacturing process of a semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as “level with” in this specification and the like. For example, the expression “level with” includes the case where two layers (here, given as a first layer and a second layer) having different two levels with respect to the reference surface are included, and the difference between the top-surface level of the first layer and the top-surface level of the second layer is less than or equal to 20 nm.

Note that in this specification and the like, the expression “end portions are aligned” means that at least outlines of stacked layers partly overlap with each other in the top view. For example, the case of processing the upper layer and the lower layer with the use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

In general, it is difficult to clearly differentiate “perfectly aligned” from “substantially aligned”. In this specification, the expression “aligned” includes both “perfectly aligned” (where the angle between bright lines is 0°, for example) and “substantially aligned”.

### Embodiment 1

In this embodiment, a semiconductor device of one embodiment of the present invention is described with reference to drawings.

One embodiment of the present invention relates to a semiconductor device provided over a substrate. The semiconductor device includes a first transistor, a second transistor, and a capacitor, which can form a memory cell. The semiconductor device of one embodiment of the present invention includes the memory cell and thus has a function of storing data. Therefore, the semiconductor device of one embodiment of the present invention can be referred to as a memory device.

The semiconductor device of one embodiment of the present invention preferably includes a transistor containing a metal oxide semiconductor in a channel formation region (hereinafter referred to as an OS transistor). The OS transistor has a low off-state current. Thus, by including an OS transistor, the semiconductor device capable of serving as a memory device can retain stored contents for a long time. In other words, such a storage device does not require refresh operation or has extremely low frequency of the refresh operation, which leads to a sufficient reduction in power consumption of the semiconductor device. Thus, a semiconductor device with low power consumption can be provided. An OS transistor has high frequency characteristics and thus the semiconductor device can perform data reading and data writing at high speed. Thus, a semiconductor device with high operating speed can be provided.

The first transistor is provided in the same layer as the second transistor. Each of the first and second transistors includes first to third conductors, a metal oxide, and an insulator. The second conductor is provided over the first conductor and includes a region overlapping with the first conductor. The second conductor has an opening overlapping with the first conductor in the top view. The metal oxide includes a region in contact with each of the side surface of the opening included in the second conductor and the top surface of the first conductor. The insulator is provided in a concave portion of the metal oxide. The third conductor is provided in a concave portion of the insulator. The third conductor includes a region overlapping with the metal oxide with the insulator therebetween in a region between the first conductor and the second conductor in the cross-sectional view. In other words, the third conductor includes a region facing the metal oxide with the insulator therebetween in the region between the first conductor and the second conductor in the cross-sectional view.

In each of the first and second transistors, the metal oxide includes a region functioning as a channel formation region of the transistor. The first conductor includes a region functioning as one of a source electrode and a drain electrode of the transistor. The second conductor includes a region functioning as the other of the source electrode and the drain electrode of the transistor. The third conductor includes a region including a region functioning as a gate electrode of the transistor. The insulator includes a region functioning as a gate insulator of the transistor.

In each of the first and second transistors, one of the source electrode and the drain electrode is positioned below and the other is positioned above; thus, current flows in the vertical direction. In other words, the channel length direction of the first and second transistors is the vertical direction. That is, the first and second transistors have a vertical structure. A transistor having a vertical structure can be miniaturized as compared with a transistor having what is called a horizontal structure in which current flows in the horizontal direction. Accordingly, the first and second transistors having a vertical structure can be placed at high density and thus high integration of the semiconductor device can be achieved. In addition, in a transistor having a vertical structure, the electric field of the gate electrode is more likely to affect the entire channel formation region of the semiconductor layer than in a transistor having a horizontal structure. Thus, the density of current flowing through the transistor becomes high, so that the on-state current of the transistor can be increased and the frequency characteristics can be improved.

In the case where a memory cell is formed using the first and second transistors, one of the first and second transistors functions as a write transistor and the other of the first and second transistors functions as a read transistor. A read transistor preferably has high on-state current characteristics. A write transistor preferably has low off-state current characteristics. Thus, to manufacture a high-performance memory device, it is desired to form transistors having required different characteristics. In each of the first and second transistors having a vertical structure, the channel width related to the on-state current of the transistor can be adjusted by the size (also referred to as diameter) in the top view of the opening where part of components of the transistor is provided. Thus, the opening provided with part of components of the first transistor and the opening provided with part of components of the second transistor are different from each other, whereby a memory device with excellent performance can be manufactured.

### <Structure Example 1 of Semiconductor Device>

Structure examples of a semiconductor device according to one embodiment of the present invention will be described below.

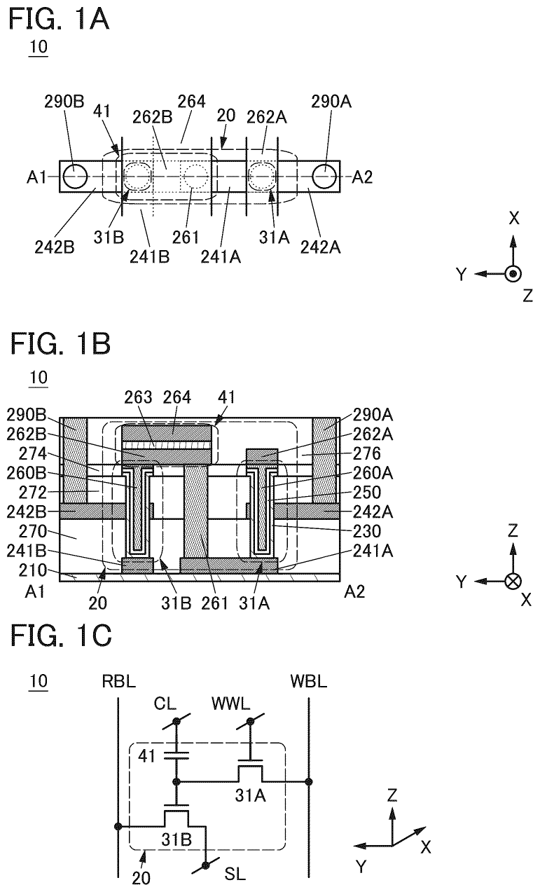

FIG. 1A and FIG. 1B are a top view and a cross-sectional view illustrating a structure example of the semiconductor device of one embodiment of the present invention. FIG. 1A is a top view of a semiconductor device 10. FIG. 1B is a cross-sectional view of the semiconductor device 10, and is a cross-sectional view of a portion indicated by the dashed-dotted line A1-A2 in FIG. 1A. Note that for clarity of the drawing, some components are omitted in the top view of FIG. 1A.

The semiconductor device 10 includes an insulator 210 over a substrate (not illustrated), a memory cell 20 over the insulator 210, a conductor 262A, a conductor 290A, a conductor 290B, an insulator 270 over the insulator 210, an insulator 272 over the insulator 270, an insulator 274 over the insulator 272, and an insulator 276 over the insulator 274. The memory cell 20 is electrically connected to each of the conductor 262A, the conductor 290A, and the conductor 290B.

The memory cell 20 includes a transistor 31A, a transistor 31B, a capacitor 41 over the transistor 31B, and a conductor 261. Note that the transistor 31A is provided in the same layer as the transistor 31B. Note that components of the semiconductor device of this embodiment may each have either a single-layer structure or a stacked-layer structure.

In the following description, as for other components that are distinguished from each other using letters of the alphabet, matters common to the components are sometimes described using reference numerals without the letters of the alphabet. For example, matters common to the transistor 31A and the transistor 31B are sometimes described using the term “transistor 31”.

In this specification and the like, a direction parallel to the channel length direction of a transistor illustrated in drawings is referred to as a Z direction, and a direction perpendicular to the Z direction is referred to as an X direction. Furthermore, a direction perpendicular to both the X direction and the Z direction is referred to as a Y direction. The X direction and the Y direction can be, for example, a direction parallel to the substrate surface, and the Z direction can be a direction perpendicular to the substrate surface.

The transistor 31A includes a conductor 241A, a conductor 242A, and a conductor 260A. The conductor 241A includes a region functioning as one of a source electrode and a drain electrode of the transistor 31A, the conductor 242A includes a region functioning as the other of the source electrode and the drain electrode of the transistor 31A, and the conductor 260A includes a region functioning as a gate electrode of the transistor 31A.

The transistor 31B includes a conductor 241B, a conductor 242B, and a conductor 260B. The conductor 241B includes a region functioning as one of a source electrode and a drain electrode of the transistor 31B, the conductor 242B includes a region functioning as the other of the source electrode and the drain electrode of the transistor 31B, and the conductor 260B includes a region functioning as a gate electrode of the transistor 31B.

The capacitor 41 includes a conductor 262B, an insulator 263, and a conductor 264. The conductor 262B includes a region functioning as one electrode of the capacitor 41, the conductor 264 includes a region functioning as the other electrode of the capacitor 41, and the insulator 263 includes a region functioning as a dielectric of the capacitor 41.

The conductor 262B is electrically connected to the conductor 260B and the conductor 261, and the conductor 241A is electrically connected to the conductor 261. That is, the conductor 261 has a function of electrically connecting the conductor 262B and the conductor 241A. In FIG. 1B, the conductor 262B includes a region in contact with each of the top surfaces of the conductor 260B and the conductor 261, and the conductor 241A includes a region in contact with the bottom surface of the conductor 261.

The conductor 262A is electrically connected to the conductor 260A, the conductor 290A is electrically connected to the conductor 242A, and the conductor 290B is electrically connected to the conductor 242B. In FIG. 1B, the conductor 262A includes a region in contact with the top surface of the conductor 260A, the conductor 290A includes a region in contact with the top surface of the conductor 242A, and the conductor 290B includes a region in contact with the top surface of the conductor 242B.

As described above, the transistor 31A is provided in the same layer as the transistor 31B. That is, the conductor 241A is provided in the same layer as the conductor 241B, and the conductor 242A is provided in the same layer as the conductor 242B. Specifically, the conductor 241A and the conductor 241B are provided over the insulator 210, and the conductor 242A and the conductor 242B are provided over the insulator 270.

The conductor 262A is preferably formed using the same material in the same step as those of the conductor 262B. When the conductor 262A is formed using the same material in the same step as the conductor 262B, the number of steps in the manufacturing process of the semiconductor device can be reduced. In that case, the conductor 262A and the conductor 262B include the same conductive material. The conductor 262A is provided in the same layer as the conductor 262B. In FIG. 1B, the conductor 262A and the conductor 262B are provided over the insulator 274.

FIG. 1A illustrates a structure in which the lengths of the conductor 241A, the conductor 242A, the conductor 242B, and the conductor 262B in the X direction are equal to each other. Note that the present invention is not limited thereto. For example, the length of the conductor 262B in the X direction may be larger than the length of the conductor 242B in the X direction. When the length of the conductor 262B in the X direction is increased, the area occupied by the conductor 262B is increased, so that the capacitance of the capacitor 41 can be increased.

Each of the conductor 241B, the conductor 262A, and the conductor 264 includes a region functioning as a wiring. Each of the conductor 290A and the conductor 290B includes a region functioning as a plug or a wiring. As described later, in the case where the semiconductor device 10 is used as a memory device, the direction in which the conductor 262A extends and the direction in which the conductor 290A extends are preferably different, and are further preferably orthogonal to each other. Furthermore, the direction in which the conductor 241B extends and the direction in which the conductor 290B extends are preferably different, and are further preferably orthogonal to each other.

In the semiconductor device 10, the conductor 241B, the conductor 262A, and the conductor 264 are provided to extend in the X direction as illustrated in FIG. 1A. In that case, the direction in which the conductor 241B extends is the same as the direction in which the conductor 262A extends. The direction in which the conductor 241B extends is the same as the direction in which the conductor 264 extends. The direction in which the conductor 262A extends is the same as the direction in which the conductor 264 extends. As illustrated in FIG. 1B, the conductor 290A and the conductor 290B are provided to extend in the Z direction. In that case, the direction in which the conductor 290A extends is the same as the direction in which the conductor 290B extends. With this structure, the direction in which the conductor 262A extends and the direction in which the conductor 290A extends are orthogonal to each other. The direction in which the conductor 241B extends and the direction in which the conductor 290B extends are orthogonal to each other. Note that in this specification and the like, the expression “the first direction is the same as the second direction” can be replaced with the expression “the first direction is parallel to the second direction”.

FIG. 1B illustrates a structure in which each of the conductor 290A and the conductor 290B have a single-layer structure. Note that each of the conductor 290A and the conductor 290B may have a stacked-layer structure. For example, in the case where the conductor 290A and the conductor 290B each have a stacked-layer structure of a first conductor and a second conductor, the first conductor is preferably provided in contact with an inner wall of an opening provided in the insulator 276, the insulator 274, and the insulator 272, and the second conductor is preferably provided on the inner side. The first conductor of the conductor 290A includes a region in contact with the top surface of the conductor 242A, the side surface of the insulator 272, the side surface of the insulator 274, and the side surface of the insulator 276. The first conductor of the conductor 290B includes a region in contact with the top surface of the conductor 242B, the side surface of the insulator 272, the side surface of the insulator 274, and the side surface of the insulator 276.

As the first conductor, a conductive material having a function of inhibiting passage of impurities such as water and hydrogen is preferably used. The first conductor can have a single-layer structure or a stacked-layer structure including one or more of tantalum, tantalum nitride, titanium, titanium nitride, ruthenium, and ruthenium oxide, for example. Thus, impurities such as water and hydrogen can be inhibited from entering the metal oxide 230 through the conductor 290A and the conductor 290B.

The conductor 290A and the conductor 290B also function as a wiring and thus is preferably formed using a conductor having high conductivity. For example, a conductive material containing tungsten, copper, or aluminum as its main component can be used for the second conductor.

For example, it is preferable to use titanium nitride for the first conductor and tungsten for the second conductor. In that case, the first conductor contains titanium and nitrogen, and the second conductor contains tungsten.

The insulator 210 preferably functions as a barrier insulating film that inhibits diffusion of impurities such as water and hydrogen into the transistor from the substrate side. Accordingly, the insulator 210 preferably includes an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the above impurities are less likely to pass). Alternatively, it is preferable to includes an insulating material having a function of inhibiting diffusion of oxygen (e.g., at least one of an oxygen atom, an oxygen molecule, and the like) (an insulating material through which the oxygen is less likely to pass).

The insulator 210 preferably includes an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride, which has a high hydrogen barrier property, is preferably used for the insulator 210. For example, the insulator 210 preferably contains aluminum oxide, magnesium oxide, or the like, which has a function of trapping and fixing hydrogen well. In this case, impurities such as water and hydrogen can be inhibited from diffusing to the transistor from the substrate side through the insulator 210. It is also possible to inhibit diffusion of oxygen contained in the insulator 270 and the like toward the substrate.

Note that in this specification and the like, a barrier insulating film refers to an insulating film having a barrier property. A barrier property in this specification and the like means a function of inhibiting diffusion of a targeted substance (also referred to as having low permeability). In addition, a barrier property in this specification means a function of capturing and fixing (also referred to as gettering) a targeted substance.

The insulator 270, the insulator 272, the insulator 274, and the insulator 276 function as interlayer films. The dielectric constant of the insulator 270, the insulator 272, the insulator 274, and the insulator 276 are preferably lower than that of the insulator 210. When a material with a low permittivity is used for an interlayer film, parasitic capacitance generated between wirings can be reduced.

For example, each of the insulator 270, the insulator 272, the insulator 274, and the insulator 276 preferably contains one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. In particular, materials such as silicon oxide, silicon oxynitride, and porous silicon oxide are preferably used, in which case a region containing oxygen released by heating can be easily formed.

Each of the top surfaces of the insulator 270, the insulator 272, the insulator 274, and the insulator 276 may be planarized.

Thus, the semiconductor device 10 can be used as a memory device. FIG. 1C illustrates a circuit diagram of the semiconductor device 10 used as a memory device. The semiconductor device 10 can be rephrased as a memory device including the memory cell 20. The memory cell 20 includes the transistor 31A, the transistor 31B, and the capacitor 41.

As illustrated in FIG. 1C, in the transistor 31A, the gate electrode is electrically connected to a wiring WWL, one of the source electrode and the drain electrode is electrically connected to the one electrode of the capacitor 41, and the other of the source electrode and the drain electrode is electrically connected to a wiring WBL. In the transistor 31B, the gate electrode is electrically connected to the one electrode of the capacitor 41, one of the source electrode and the drain electrode is electrically connected to a wiring SL, and the other of the source electrode and the drain electrode is electrically connected to a wiring RBL. The other electrode of the capacitor 41 is electrically connected to a wiring CL.

The wiring WWL functions as a write word line, the wiring WBL functions as a write bit line, the wiring RBL functions as a read bit line, the wiring SL functions as a selection line, and the wiring CL functions as a capacitor line.

The wiring WWL corresponds to the conductor 262A, the wiring WBL corresponds to the conductor 290A, the wiring RBL corresponds to the conductor 290B, the wiring SL corresponds to the conductor 241B, and the wiring CL corresponds to the conductor 264. That is, the conductor 262A includes a region functioning as a write word line, the conductor 290A includes a region functioning as a write bit line, the conductor 290B includes a region functioning as a read bit line, and the conductor 241B includes a region functioning as a selection line, and the conductor 264 includes a region functioning as a capacitor line.

The memory device including the memory cell will be described in detail in a subsequent embodiment.

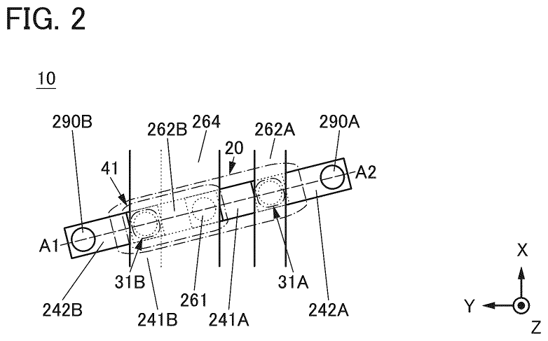

Note that FIG. 1A illustrates a structure in which a straight line that connects the conductor 290A and the conductor 290B is orthogonal to the X direction. In other words, a structure in which a straight line that connects the conductor 290A and the conductor 290B is parallel to the Y direction is illustrated. Note that the present invention is not limited thereto. For example, as illustrated in FIG. 2, a structure may be employed in which a straight line that connects the conductor 290A and the conductor 290B is inclined in the X direction. Note that since the conductor 241B, the conductor 262A, and the conductor 264 are provided to extend in the X direction, the straight line that connects the conductor 290A and the conductor 290B does not need to be orthogonal to the direction in which the conductor 241B, the conductor 262A, and the conductor 264 extend. With this structure, the memory density of the memory cell 20 can be further increased. Note that FIG. 1B can be referred to for a cross-sectional view of a portion indicated by the dashed-dotted line A1-A2 in FIG. 2.

### [Transistor 31]

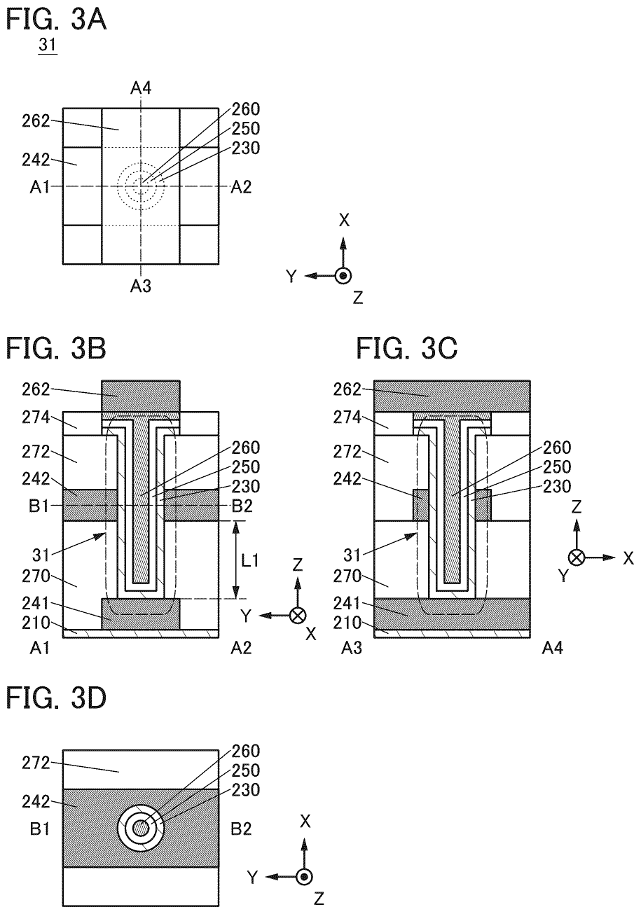

FIG. 3A to FIG. 3D are a top view and a cross-sectional view illustrating a structure example of a transistor included in the memory cell 20. FIG. 3A is a top view of a transistor 31. FIG. 3B is a cross-sectional view of a portion indicated by the dashed-dotted line A1-A2 in FIG. 3A, and FIG. 3C is a cross-sectional view of a portion indicated by the dashed-dotted line A3-A4 in FIG. 3A. FIG. 3D is a top view of a portion indicated by the dashed-dotted line B1-B2 in FIG. 3B. Note that for clarity of the drawing, some components are not illustrated in the top views of FIG. 3A and FIG. 3D.

The transistor 31 includes the conductor 241 and the insulator 270 over the insulator 210, the metal oxide 230 over the conductor 241, the insulator 250 over the metal oxide 230, the conductor 260 over the insulator 250, the conductor 242 over the insulator 270, and the insulator 272 over the insulator 270 and the conductor 242.

The conductor 241 includes a region functioning as one of a source electrode and a drain electrode of the transistor 31, the conductor 242 includes a region functioning as the other of the source electrode and the drain electrode of the transistor 31, and the conductor 260 includes a region functioning as a gate electrode of the transistor 31. The metal oxide 230 includes a region functioning as a channel formation region.

A metal oxide functioning as an oxide semiconductor (hereinafter also referred to as an oxide semiconductor) is preferably used as the metal oxide 230. Note that the metal oxide functioning as a semiconductor preferably has a band gap of 2.0 eV or higher, further preferably 2.5 eV or higher. With use of a metal oxide having a wide bandgap, the off-state current of the transistor can be reduced.

As the metal oxide 230, a metal oxide such as indium oxide, gallium oxide, or zinc oxide is preferably used, for example. As the metal oxide 230, a metal oxide containing two or three selected from indium, an element M, and zinc is preferably used, for example. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide containing indium, the element M, and zinc is referred to as In-M-Zn oxide in some cases.

Specifically, as the metal oxide 230, a metal oxide having a composition where In:M:Zn=1:1:1 [atomic ratio] or a neighborhood thereof, a metal oxide having a composition where In:M:Zn=1:1:1.2 [atomic ratio] or a neighborhood thereof, a metal oxide having a composition where In:M:Zn=1:1:2 [atomic ratio] or a neighborhood thereof, or a metal oxide having a composition where In:M:Zn=4:2:3 [atomic ratio] or a neighborhood thereof can be used. Note that a composition in the neighborhood includes the range of ±30% of an intended atomic ratio. Gallium is preferably used as the element M.

In the metal oxide 230, a channel formation region and a source region and a drain region provided to sandwich the channel formation region of the transistor 31 are included. At least part of the channel formation region overlaps with the conductor 260. In other words, at least part of the channel formation region faces the conductor 260. The source region overlaps with one of the conductor 241 and the conductor 242, and the drain region overlaps with the other of the conductor 241 and the conductor 242. Note that a region overlapping with the conductor 242 can also be referred to as a region facing the conductor 242.

If impurities and oxygen vacancies exist in a channel formation region in an oxide semiconductor, a transistor including the oxide semiconductor may have variable electrical characteristics and poor reliability. In some cases, hydrogen in the vicinity of an oxygen vacancy forms a defect that is the oxygen vacancy into which hydrogen enters (hereinafter sometimes referred to as V_{O}H), which generates an electron serving as a carrier. Thus, when the channel formation region in the oxide semiconductor includes oxygen vacancies, the transistor is likely to have normally-on characteristics (characteristics with which, even when no voltage is applied to the gate electrode, the channel exists and current flows through the transistor). Thus, impurities, oxygen vacancies, and V_{O}H are preferably reduced as much as possible in the channel formation region in the oxide semiconductor.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into a conductor such as the gate electrode, the source electrode, or the drain electrode, the conductor might be oxidized and the conductivity might be impaired, for example, so that electrical characteristics and reliability of the transistor might be adversely affected. Accordingly, supply of an excess amount of oxygen to the source region and the drain region and excessive reduction in the amount of V_{O}H in the source region and the drain region are preferably inhibited.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1× 10⁻⁹ cm⁻³.

Note that in order to reduce the carrier concentration in the metal oxide 230, the impurity concentration in the metal oxide 230 is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration (or metal oxide) may be referred to as a highly purified intrinsic or substantially highly purified intrinsic oxide semiconductor (metal oxide).

Note that an impurity in the metal oxide 230 refers to, for example, elements other than the main components of the metal oxide 230. For example, an element with a concentration lower than 0.1 atomic % can be regarded as an impurity. In the case where an oxide semiconductor is used as the metal oxide 230, examples of impurities in the metal oxide 230 include hydrogen, nitrogen, alkali metal, alkaline earth metal, iron, nickel, and silicon.

The source region and the drain region have a large amount of oxygen vacancies or a high concentration of an impurity, and thus are each a low-resistance region with a high carrier concentration. In other words, the source region and the drain region are each an n-type region (low-resistance region) having a higher carrier concentration than the channel formation region.

In the metal oxide 230, the boundaries between the regions are difficult to detect clearly in some cases. The concentration of a metal element and an impurity element, which is detected in each region, may be not only gradually changed between the regions but also continuously changed in each region. That is, the region closer to the channel formation region may have a lower concentration of an impurity element.

In order to stabilize the electrical characteristics of the transistor, it is effective to reduce the concentration of impurities in the metal oxide 230. In addition, in order to reduce the impurity concentration of the metal oxide 230, the impurity concentration of an adjacent film is also preferably reduced.

An opening reaching the conductor 241 is provided in the insulator 272, the conductor 242, and the insulator 270. In addition, the opening includes a region overlapping with the conductor 242 in the top view. At least part of the metal oxide 230, part of the insulator 250, and part of the conductor 260 are placed in the opening. Note that the opening can be regarded as including an opening included in the insulator 272, an opening included in the conductor 242, and an opening included in the insulator 270. It can be said that the conductor 242 has an opening overlapping with the conductor 241 in the top view.

The metal oxide 230 is provided in contact with the side surface and the bottom surface of the opening provided in the insulator 272, the conductor 242, and the insulator 270. In other words, the metal oxide 230 includes a region in contact with the side surface of the opening included in the conductor 242 and the top surface of the conductor 241. The metal oxide 230 includes a region in contact with the top surface of the insulator 272. The metal oxide 230 includes a concave portion. The concave portion includes a region overlapping with the opening included in the conductor 242 in the top view.

At least part of the insulator 250 is provided in a concave portion of the metal oxide 230. The insulator 250 includes a region in contact with the top surface of the metal oxide 230. The insulator 250 includes a concave portion. The concave portion is positioned inside the concave portion of the metal oxide 230.

The conductor 260 is provided to fill the concave portion of the insulator 250. The conductor 260 includes a region in contact with the top surface of the insulator 250. The conductor 260 includes a region overlapping with the metal oxide 230 with the insulator 250 therebetween in a region between the conductor 241 and the conductor 242 in the cross-sectional view. In other words, the conductor 260 includes a region facing the metal oxide 230 with the insulator 250 therebetween in the region between the conductor 241 and the conductor 242 in the cross-sectional view.

In the above structure, the channel length of the transistor 31 is the shortest distance from the top surface of the conductor 241 to the bottom surface of the conductor 242 (L1 illustrated in FIG. 3B) in the cross-sectional view, and is also the thickness of the insulator 270 in a region overlapping with the conductor 241. In other words, the channel length of the transistor 31 can be adjusted by the thickness of the insulator 270 in the region overlapping with the conductor 241. For example, when the thickness of the insulator 270 is made small, the transistor 31 having a short channel length can be manufactured.

In the above structure, the channel width of the transistor 31 is the length of a region where the insulator 270 and the metal oxide 230 are in contact with each other in the top view, and is also the length of the outline (outer periphery) of the metal oxide 230 in the top view. That is, the channel width of the transistor 31 can be adjusted by changing the diameter of the opening provided in the insulator 270. For example, when the diameter of the opening is made large, the transistor 31 having a large channel width can be manufactured. Note that the opening can be rephrased as an opening in which some components of the transistor 31 (here, the metal oxide 230, the insulator 250, and the conductor 260) are provided.

The transistor 31 has a structure in which the channel formation region surrounds the gate electrode. Thus, the transistor 31 can be referred to as a transistor having a CAA (Channel-All-Around) structure.

Although FIG. 3D illustrates a structure where the top surface of the opening included in the conductor 242 has a circular shape, the present invention is not limited thereto. For example, the top surface of the opening included in the conductor 242 may have an oval shape, a polygonal shape, or a polygonal shape with rounded corners. The polygonal shape here means a triangle, a quadrangle, a pentagon, a hexagon, and the like.

The insulator 274 is provided over the insulator 272, and the conductor 262 is provided over the insulator 274 and the conductor 260.

An oxide semiconductor having crystallinity is preferably used for the metal oxide 230. Examples of an oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. For the metal oxide 230, the CAAC-OS or the nc-OS is preferably used, and the CAAC-OS is particularly preferably used.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. As the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Thus, the metal oxide including a CAAC-OS is resistant to heat and has high reliability.

When an oxide having crystallinity, such as a CAAC-OS, is used as the metal oxide 230, oxygen extraction from the metal oxide 230 by the conductor 241 or the conductor 242 can be inhibited. This can suppress oxygen extraction from the metal oxide 230 even when heat treatment is performed; thus, the transistor is stable with respect to high temperatures in a manufacturing process (what is called thermal budget). Furthermore, it is possible to inhibit a reduction in the conductivity of the conductor 241 and the conductor 242.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal (also referred as nanocrystal). Further, there is no regularity of crystal orientation between different nanocrystal parts in the nc-OS film; thus, the orientation of the whole film is not observed. That is, in the case where the nc-OS is used as the metal oxide 230, the metal oxide 230 has uniform film characteristics regardless of the direction of carriers flowing in the metal oxide 230; thus, the transistor has stable electrical characteristics.

Note that an oxide semiconductor has various structures with different properties. The metal oxide 230 may include two or more of the CAAC-OS, the nc-OS, an amorphous-like oxide semiconductor (a-like OS), an amorphous oxide semiconductor, a polycrystalline oxide semiconductor, and a cloud-aligned composite oxide semiconductor (CAC-OS).

Note that when the CAAC-OS film is subjected to structural analysis by Out-of-plane XRD measurement with an XRD apparatus using q/2q scanning, for example, a peak indicating c-axis alignment is detected at 2q of 31° or around 31°. Note that the position of the peak indicating c-axis alignment (the value of 2q) may change depending on the kind, composition, or the like of the metal element contained in the CAAC-OS. For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

In some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter equivalent to or less than the diameter of a nanocrystal (e.g., greater than or equal to 1 nm and less than or equal to 30 nm).

The metal oxide 230 can be rephrased as a semiconductor layer including a channel formation region of the transistor 31. Note that a material that can be used for the semiconductor layer is not limited to a metal oxide functioning as a semiconductor (an oxide semiconductor). For example, a semiconductor such as single crystal silicon, polycrystalline silicon, or amorphous silicon may be used for the semiconductor layer, and low-temperature polysilicon (LTPS) may be used, for example.

As the semiconductor layer, the transition metal chalcogenide functioning as a semiconductor may be used; for example, molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), or zirconium selenide (typically ZrSe₂) may be used.

The insulator 250 may have either a single-layer structure or a stacked-layer structure.

As the insulator 250, for example, silicon oxide, silicon oxynitride, silicon oxide to which fluorine is added, silicon oxide to which carbon is added, silicon oxide to which carbon and nitrogen are added, porous silicon oxide, or the like. In particular, silicon oxide and silicon oxynitride, which are thermally stable, are preferable. The insulator 250 in this case is an insulator containing at least oxygen and silicon.

The concentration of impurities such as water and hydrogen in the insulator 250 is preferably reduced.

Note that an insulator having a barrier property against oxygen may be provided between the insulator 250 and the metal oxide 230. The insulator is provided in contact with the bottom surface of the insulator 250 and the concave portion of the metal oxide 230. When the insulator has a barrier property against oxygen, oxygen contained in the insulator 250 can be supplied to the channel formation region, while oxygen contained in the insulator 250 can be inhibited from being excessively supplied to the channel formation region. Thus, it is possible to inhibit release of oxygen from the metal oxide 230 when heat treatment or the like is performed and inhibit formation of oxygen vacancies in the metal oxide 230. Thus, the transistor 31 can have favorable electrical characteristics and higher reliability.

An insulator containing an oxide of one or both of aluminum and hafnium is preferably used as the above insulator. As the insulator, aluminum oxide, hafnium oxide, an oxide containing aluminum and hafnium (hafnium aluminate), an oxide containing hafnium and silicon (hafnium silicate), or the like can be used. As the above insulator, for example, aluminum oxide is further preferably used. In this case, the above insulator contains at least oxygen and aluminum. Note that oxygen is less likely to pass through the above insulator than the insulator 250, for example. For the above insulator, a material through which oxygen is less likely to pass than the insulator 250 is used, for example. For the above insulator, magnesium oxide, gallium oxide, gallium zinc oxide, or indium gallium zinc oxide may be used, for example.

FIG. 3B illustrates a structure in which the conductor 260 is a single layer. Note that the conductor 260 may have a stacked-layer structure. For example, the conductor 260 preferably includes a first conductor, and a second conductor over the first conductor. Specifically, the first conductor of the conductor 260 is preferably placed to cover the bottom surface and the side surface of the second conductor of the conductor 260.

For the first conductor of the conductor 260, a conductive material having a function of inhibiting diffusion of impurities such as a hydrogen atom, a hydrogen molecule, a water molecule, a nitrogen atom, a nitrogen molecule, a nitrogen oxide molecule, or a copper atom is preferably used. Alternatively, it is preferable to use a conductive material having a function of inhibiting diffusion of oxygen (e.g., at least one of an oxygen atom, an oxygen molecule, and the like). Alternatively, it is preferable to use a conductive material which is not easily oxidized.

When the first conductor of the conductor 260 has a function of inhibiting oxygen diffusion, for example, the conductivity of the second conductor of the conductor 260 can be inhibited from being lowered because of oxidation due to oxygen contained in the insulator 250. As the conductive material having a function of inhibiting diffusion of oxygen, for example, titanium, titanium nitride, tantalum, tantalum nitride, ruthenium, or ruthenium oxide is preferably used.

The conductor 260 functions as a wiring and thus is preferably formed using a conductor having high conductivity. For example, a conductive material containing tungsten, copper, or aluminum as its main component can be used for the second conductor of the conductor 260. The second conductor of the conductor 260 may have a stacked-layer structure; for example, a stacked layer structure of any of the above conductive materials and titanium or titanium nitride may be employed.

Note that an insulator having a barrier property against hydrogen may be provided between the insulator 250 and the conductor 260. With this structure, diffusion of impurities such as hydrogen contained in the conductor 260 into the insulator 250 and the metal oxide 230 can be inhibited. Silicon nitride is preferably used for the above insulator, for example. In this case, the above insulator contains at least nitrogen and silicon. For the above insulator, aluminum oxide, magnesium oxide, hafnium oxide, gallium oxide, indium gallium zinc oxide, silicon nitride oxide, or the like may be used, for example. Note that hydrogen is less likely to pass through the above insulator than the insulator 250, for example. For the above insulator, a material through which hydrogen is less likely to pass than the insulator 250 is used, for example.

The insulator having a barrier property against oxygen may be provided between the insulator 250 and the conductor 260. With this structure, oxygen contained in the insulator 250 can be inhibited from being diffused into the conductor 260. That is, a reduction in the amount of oxygen supplied to the metal oxide 230 can be inhibited. In addition, oxidation of the conductor 260 due to oxygen contained in the insulator 250 can be inhibited. For the above insulator, an insulator containing an oxide of one or both of aluminum and hafnium is preferably used. As the above insulator, aluminum oxide, hafnium oxide, an oxide containing aluminum and hafnium (hafnium aluminate), an oxide containing hafnium and silicon (hafnium silicate), or the like can be used. As the insulator, hafnium oxide is further preferably used. In this case, the above insulator contains at least oxygen and hafnium. Hafnium oxide is suitable because of its barrier property against hydrogen.

To form the metal oxide 230, the insulator 250, and the conductor 260 in the opening provided in the insulator 272, the conductor 242, and the insulator 270, the metal oxide 230, the insulator 250, and the conductor 260 are preferably formed using an atomic layer deposition (ALD) method. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because of enabling lower-temperature deposition.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Thus, the metal oxide 230, the insulator 250, and the conductor 260 can be deposited on the side surface of the opening portion provided in the insulator 272, the conductor 242, and the insulator 270 with good coverage.

Note that some of precursors usable in an ALD method contain carbon, for example. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

Note that after the metal oxide is deposited by an ALD method, microwave treatment is preferably performed, and further preferably the microwave treatment is performed in an oxygen-containing atmosphere.

The microwave treatment in an oxygen-containing atmosphere converts an oxygen gas into plasma using a high-frequency wave such as a microwave, RF, or the like, so that the oxygen plasma can be applied to the metal oxide. At this time, the metal oxide can be irradiated with the high-frequency wave such as a microwave or RF. In other words, the high-frequency wave such as a microwave or RF, the oxygen plasma, or the like can be applied to the metal oxide.

The effect of the high-frequency wave, the oxygen plasma, and the like can reduce the impurity concentration of the metal oxide. For example, hydrogen in the metal oxide can be released as a water molecule. Alternatively, carbon in the metal oxide can be released as a oxocarbon (CO and/or CO₂), for example. In addition, by supply of oxygen radicals generated by the oxygen plasma to the metal oxide, oxygen vacancies, VoH, or the like in the metal oxide can be reduced.

The effect of the high-frequency wave, the oxygen plasma, and the like can apply energy which is higher than or equal to the treatment temperature of the microwave treatment to the atom in the metal oxide. Thus, rearrangement of metal atoms and oxygen atoms in the metal oxide is promoted, so that the crystallinity of the metal oxide can be improved. Note that as the impurity concentration and the amount of defects (e.g., oxygen vacancies and VoH) in the metal oxide are reduced, the crystallinity of the metal oxide tends to be improved. That is, the microwave treatment in an oxygen-containing atmosphere reduces the impurity concentration and the amount of the defects in the metal oxide and improves the crystallinity of the metal oxide.

An insulator containing excess oxygen is preferably used as the insulator 270 that is in contact with the metal oxide 230. For the insulator 270, it is preferable to use an oxide containing silicon, such as silicon oxide, silicon oxynitride, silicon oxide to which fluorine is added, silicon oxide to which carbon is added, silicon oxide to which carbon and nitrogen are added, or porous silicon oxide. In particular, silicon oxide and silicon oxynitride, which are thermally stable, are preferable. A material such as silicon oxide, silicon oxynitride, or porous silicon oxide is preferable because a region containing excess oxygen can be easily formed. When an insulator containing excess oxygen is provided in the vicinity of the metal oxide 230 and heat treatment is performed, oxygen can be supplied from the insulator to the metal oxide 230 and oxygen vacancies and V_{O}H can be reduced. In particular, the metal oxide 230 in a region in contact with the insulator 270 functions as a channel formation region; thus, with this structure, oxygen vacancies and V_{O}H in the channel formation region can be reduced, so that the channel formation region can be an i-type or substantially i-type region.

The concentration of impurities such as water and hydrogen in the insulator 270 is preferably reduced. For example, the insulator 270 preferably contains an oxide containing silicon, such as silicon oxide or silicon oxynitride.

A conductive material that is not easily oxidized or a conductive material having a function of inhibiting oxygen diffusion is preferably used for each of the conductor 241 and the conductor 242. Examples of the conductive material include a conductive material containing nitrogen and a conductive material containing oxygen. With the use of the conductive material, a reduction in the conductivity of the conductor 241 and the conductor 242 can be inhibited. In the case where a conductive material containing metal and nitrogen is used for the conductor 241 and the conductor 242, each of the conductor 241 and the conductor 260 is a conductor that contains at least metal and nitrogen.

As each of the conductor 241 and the conductor 242, for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

In FIG. 3B, the conductor 241 and the conductor 242 have a single-layer structure. Note that each of the conductor 241 and the conductor 242 may have a stacked-layer structure. For example, each of the conductor 241 and the conductor 242 may have a two-layer structure of a first conductor and a second conductor. In that case, a conductive material that is less likely to be oxidized or a conductive material having a function of preventing diffusion of oxygen is preferably used for the first conductor that is in contact with the insulator 270. Thus, a decrease in conductivity of the conductor 241 and the conductor 242 can be inhibited.

The second conductor of the conductor 241 and the conductor 242 preferably has higher conductivity than the first conductor of the conductor 241 and the conductor 242. In addition, the second conductor of the conductor 241 and the conductor 242 preferably has a larger thickness than the first conductor of the conductor 241 and the conductor 242.

For example, tantalum nitride or titanium nitride can be used for the first conductor of the conductor 241 and the conductor 242, and tungsten can be used for the second conductor of the conductor 241 and the conductor 242.

Note that an insulator having a barrier property against oxygen is preferably provided between the conductor 241 and the insulator 270 in order to inhibit oxidation of the conductor 241 due to oxygen contained in the insulator 270. In order to inhibit oxidation of the conductor 242 due to oxygen contained in the insulator 270, an insulator having a barrier property against oxygen is preferably provided between the conductor 242 and the insulator 270. With this structure, diffusion of oxygen contained in the insulator 270 into the conductor 241 and the conductor 242 can be inhibited. As the above insulator, an insulator containing an oxide of one or both of aluminum and hafnium may be used. As the above insulator, aluminum oxide, hafnium oxide, an oxide containing aluminum and hafnium (hafnium aluminate), an oxide containing hafnium and silicon (hafnium silicate), or the like can be used.

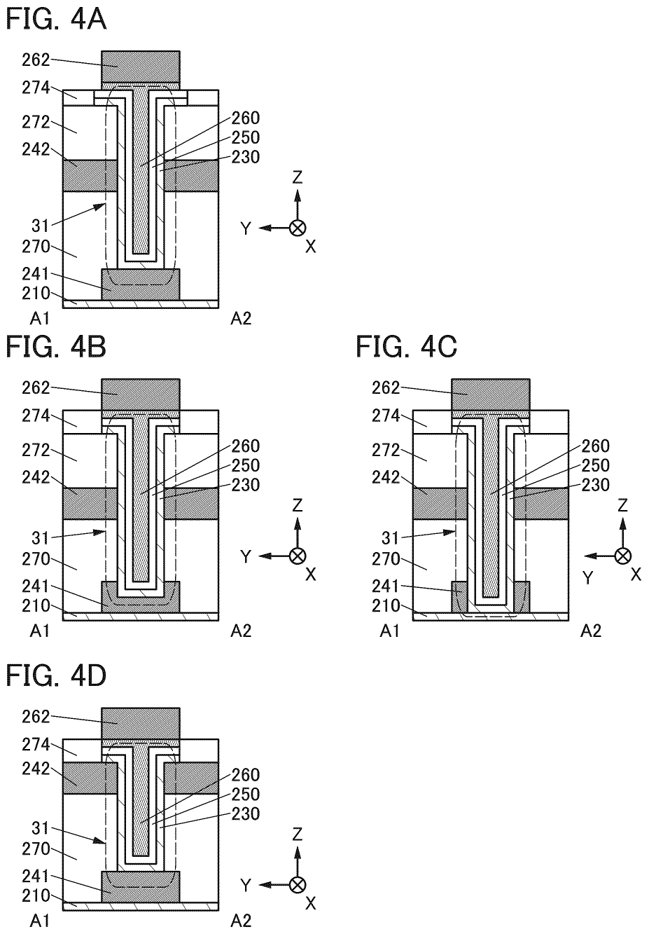

As illustrated in FIG. 3B, an end portion of the conductor 260 is aligned with end portions of the metal oxide 230 and the insulator 250 above the insulator 272. Note that in some cases, the end portion of the conductor 260 is not aligned with the end portions of the metal oxide 230 and the insulator 250. For example, it is the case when part of the conductor 260 is removed in formation of the conductor 262. In this case, as illustrated in FIG. 4A, the end portion of the conductor 260 is aligned with the end portion of the conductor 262.

FIG. 3B illustrates a structure where the conductor 241 does not include a concave portion in the region overlapping with the opening included in the insulator 270. Note that the present invention is not limited thereto. For example, as illustrated in FIG. 4B, the conductor 241 may include the concave portion in the region overlapping with the opening. In other words, the top surface of the conductor 241 in the region overlapping with the opening may be partly removed. When the conductor 241 includes the concave portion in the region overlapping with the above opening, an end portion of a region where the metal oxide 230 and the conductor 260 overlap with each other (a region where the metal oxide 230 and the conductor 260 face each other) with the insulator 250 therebetween can be made closer to the conductor 241. Alternatively, the conductor 260 can include the region overlapping with the conductor 241 (a region facing the conductor 241) with the metal oxide 230 and the insulator 250 therebetween. In other words, in the region between the conductor 241 and the conductor 242, a structure in which what is called a Loff region that is a region where the metal oxide 230 and the conductor 260 do not overlap with each other (a region where the metal oxide 230 and the conductor 260 do not face each other) with the insulator 250 therebetween is narrow or is not provided can be employed. Thus, the frequency characteristics of the transistor 31 can be improved. Accordingly, the memory cell 20 is capable of high-speed writing and high-speed reading and the operation speed of the semiconductor device 10 can be increased. Thus, a semiconductor device with high operating speed can be provided.

As another example, as illustrated in FIG. 4C, the conductor 241 may include an opening reaching the insulator 210 and overlapping with the opening included in the insulator 270. In other words, a region of the conductor 241 overlapping with the opening included in the insulator 270 may be removed. When the conductor 241 includes the opening reaching the insulator 210, the end portion of the region where the metal oxide 230 and the conductor 260 overlap with each other (a region where the metal oxide 230 and the conductor 260 face each other) with the insulator 250 therebetween can be made closer to the conductor 241. Alternatively, the conductor 260 can include the region overlapping with the conductor 241 (the region facing the conductor 241) with the metal oxide 230 and the insulator 250 therebetween. Thus, frequency characteristics of the transistor 31 can be improved.

FIG. 3B illustrates a structure in which the metal oxide 230 includes the region in contact with the top surface of the insulator 272. Note that the present invention is not limited thereto. For example, as illustrated in FIG. 4D, the insulator 272 is not necessarily provided. At this time, the metal oxide 230 includes a region in contact with part of the top surface of the conductor 242 and the side surface of the opening included in the conductor 242. With this structure, a contact area between the metal oxide 230 and the conductor 242 can be increased, so that the on-state current of the transistor 231 can be increased. Thus, a semiconductor device with high on-state current can be provided.

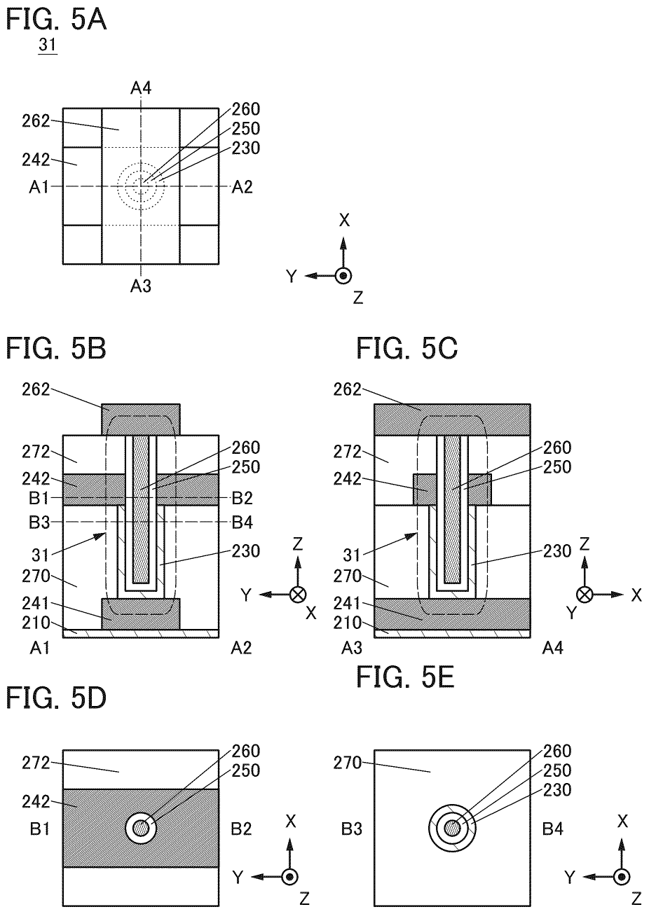

In the transistor 31 illustrated in FIG. 3A to FIG. 3D, the top surface of the metal oxide 230 is positioned above the top surface of the conductor 242. Note that the present invention is not limited thereto. FIG. 5A to FIG. 5E illustrate a transistor having a structure different from that of the transistor 31 illustrated in FIG. 3A to FIG. 3D.

FIG. 5A to FIG. 5E are top views and cross-sectional views illustrating another structure example of the transistor 31. FIG. 5A, FIG. 5D, and FIG. 5E are top views of the transistor 31. FIG. 5B is a cross-sectional view of a portion indicated by the dashed-dotted line A1-A2 in FIG. 5A, and FIG. 5C is a cross-sectional view of a portion indicated by the dashed-dotted line A3-A4 in FIG. 5A. FIG. 5D is a top view of a portion indicated by the dashed-dotted line B1-B2 in FIG. 5B, and FIG. 5E is a top view of a portion indicated by the dashed-dotted line B3-B4 in FIG. 5B. Note that for clarity of the drawings, some components are not illustrated in the top views of FIG. 5A, FIG. 5D, and FIG. 5E.

The transistor 31 illustrated in FIG. 5A to FIG. 5E is a variation example of the transistor 31 illustrated in FIG. 3A to FIG. 3D. The transistor 31 illustrated in FIG. 5A to FIG. 5E is different from the transistor 31 illustrated in FIG. 3A to FIG. 3D in the shapes of the metal oxide 230, the insulator 250, and the conductor 260. Differences from the transistor 31 illustrated in FIG. 3A to FIG. 3D will be mainly described below, and common portions are not described.

As illustrated in FIG. 5A to FIG. 5E, the diameter of the opening included in each of the insulator 272 and the conductor 242 is smaller than the diameter of the opening included in the insulator 270.

The metal oxide 230 is provided in contact with the side surface and the bottom surface of the opening included in the insulator 270. At this time, the top surface of the metal oxide 230 is aligned with the top surface of the insulator 270 and includes a region in contact with the bottom surface of the conductor 242.

The insulator 250 is provided in the opening included in each of the insulator 272 and the conductor 242 and in the concave portion of the metal oxide 230. The insulator 250 includes a region in contact with the side surface of the opening included in the insulator 272 and the side surface of the opening included in the conductor 242. The top surface of the insulator 250 is level with the top surfaces of the conductor 260 and the insulator 272.

The conductor 260 is provided to fill the concave portion of the insulator 250. The conductor 260 includes a region in contact with the bottom surface of the conductor 262.

The structure illustrated in FIG. 5A to FIG. 5E can be manufactured in the following manner: the metal oxide 230 is formed in the opening included in the insulator 270, an insulating film to be the insulator 250 and a conductive film to be the conductor 260 are formed in the opening included in the insulator 272, the opening included in the conductor 242, and the concave portion included in the metal oxide 230, and planarization is performed until the top surface of the insulator 272 is exposed. For example, as the planarization treatment, a chemical mechanical polishing (CMP) method or the like can be employed.

In the structure illustrated in FIG. 5A to FIG. 5E, the metal oxide 230 is provided below the insulator 272 and thus is not in contact with the conductor 262 over the insulator 272. Thus, the metal oxide 230 can function as the channel formation region of the transistor 31. Furthermore, in the transistor 31 illustrated in FIG. 5A to FIG. 5E, the insulator 250 and the conductor 260 can be formed without using a photolithography method unlike the transistor 31 illustrated in FIG. 3A to FIG. 3D; thus, the semiconductor device can be miniaturized or highly integrated. Since the insulator 274 need not be provided, the number of steps in the manufacturing process of the semiconductor device can be reduced.

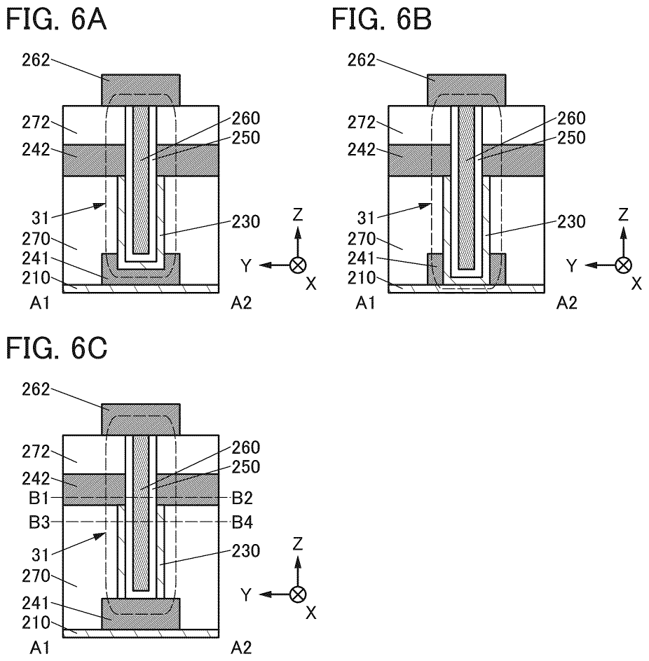

FIG. 5B illustrates a structure where the conductor 241 does not include the concave portion in the region overlapping with the opening included in the insulator 270. Note that the present invention is not limited thereto. For example, as illustrated in FIG. 6A, the conductor 241 may include a concave portion in the region overlapping with the opening. In other words, the top surface of the conductor 241 in the region overlapping with the opening may be partly removed. Alternatively, for example, as illustrated in FIG. 6B, the conductor 241 may include an opening overlapping with the opening and reaching the insulator 210. In other words, the region of the conductor 241 overlapping with the opening included the insulator 270 may be removed. When the conductor 241 includes a concave portion or an opening in the region overlapping with the opening included in the insulator 270, the end portion of the region where the metal oxide 230 and the conductor 260 overlap with each other (a region where the metal oxide 230 and the conductor 260 face each other) with the insulator 250 therebetween can be made closer to the conductor 241. Thus, the frequency characteristics of the transistor 31 can be improved.

FIG. 5B illustrates a structure in which the metal oxide 230 has a concave portion. Note that the present invention is not limited thereto. For example, as illustrated in FIG. 6C, the metal oxide 230 may include the opening reaching the conductor 241. In other words, the metal oxide 230 may have a cylindrical shape provided with a hollow portion. With this structure, the end portion of the region where the metal oxide 230 and the conductor 260 overlap with each other (the region where the metal oxide 230 and the conductor 260 face each other) with the insulator 250 therebetween can be made closer to the conductor 241.

Note that even in the case where the metal oxide 230 includes the opening reaching the conductor 241, the conductor 241 may include a concave portion or an opening in the region overlapping with the opening included in the insulator 270, as in FIG. 6A and FIG. 6B. With this structure, the contact area between the conductor 241 and the metal oxide 230 can be increased, so that the on-state current of the transistor 31 can be increased.

The above is the description of structure examples of the transistor 31.

### [Capacitor 41]

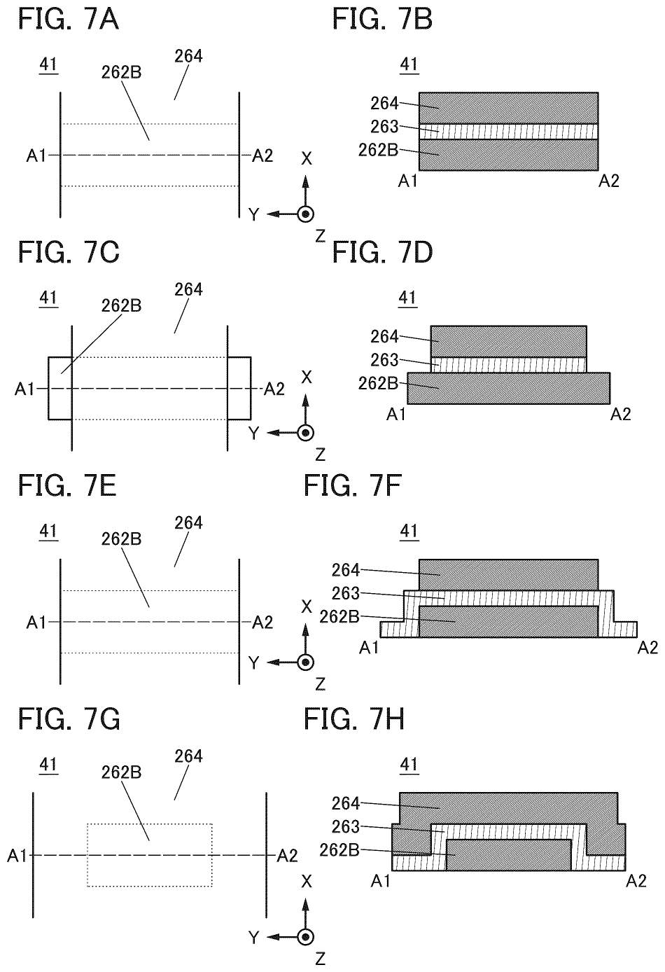

FIG. 7A and FIG. 7B are a top view and a cross-sectional view illustrating a structure example of the capacitor 41 included in the memory cell 20. FIG. 7A is a top view of the capacitor 41. FIG. 7B is a cross-sectional view of a portion indicated by the dashed-dotted line A1-A2 in FIG. 7A. Note that for clarity of the drawing, some components are not illustrated in the top view of FIG. 7A.

The capacitor 41 includes the conductor 262B, the insulator 263 over the conductor 262B, and the conductor 264 over the insulator 263.

The conductor 262B includes the region functioning as the one electrode of the capacitor 41, the conductor 264 includes the region functioning as the other electrode of the capacitor 41, and the insulator 263 includes the region functioning as the dielectric of the capacitor 41. The capacitor 41 forms a MIM (Metal-Insulator-Metal) capacitor.

As illustrated in FIG. 7A, the conductor 264 is provided to extend beyond an end portion of the conductor 262B in the X direction. As illustrated in FIG. 7A and FIG. 7B, the end portion of the conductor 262B in the Y direction are aligned with end portions of the insulator 263 and the conductor 264 in the Y direction.

Each of the conductor 262B and the conductor 264 may have a single-layer structure or a stacked-layer structure.

Each of the conductor 262B and the conductor 264 may include a first conductor, and a second conductor over the first conductor. Note that the stacking order of one or both of the conductor 262B and the conductor 264 may be reversed. For example, for the first conductor of the conductor 262B and the conductor 264, a conductor that can be used for the first conductor of the conductor 241 and the conductor 242 is used. For the second conductor of the conductor 262B and the conductor 264, a conductor that can be used for the second conductor of the conductor 241 and the conductor 242 can be used. Specifically, titanium nitride can be used for the first conductor of the conductor 262B and the conductor 264, and tungsten can be used for the second conductor of the conductor 262B and the conductor 264.

For the insulator 263, a high dielectric constant (high-k) material (material with a high relative permittivity) is preferably used. The insulator 263 is preferably formed by a deposition method that offers good coverage, such as an ALD method or a CVD method.

Examples of the high dielectric constant (high-k) material include an oxide, an oxynitride, a nitride oxide, and a nitride containing one or more kinds of metal elements selected from aluminum, hafnium, zirconium, gallium, and the like. The above oxide, oxynitride, nitride oxide, and nitride may contain silicon. Stacked insulators formed of any of the above materials can also be used.

Specifically, as the high dielectric constant (high-k) material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, and an oxynitride containing hafnium and zirconium are given. When an insulator formed of such a high-k material is used, the insulator 263 can be made thick enough to inhibit leakage current and a sufficiently high capacitance of the capacitor 41 can be ensured.

It is preferable to use stacked insulators formed of any of the above-described materials, and it is preferable to use a stacked-layer structure of a high dielectric constant (high-k) material and a material having a higher dielectric strength than the high dielectric constant (high-k) material. As the insulator 263, an insulator in which zirconium oxide, aluminum oxide, and zirconium oxide are stacked in this order can be used, for example. As another example, an insulator in which zirconium oxide, aluminum oxide, zirconium oxide, and aluminum oxide are stacked in this order can be used. As another example, an insulating film in which hafnium zirconium oxide, aluminum oxide, hafnium zirconium oxide, and aluminum oxide are stacked in this order can be used. The use of such stacked insulators with relatively high dielectric strength, such as aluminum oxide, can increase the dielectric strength and inhibit electrostatic breakdown of the capacitor 41.

FIG. 7A and FIG. 7B illustrate a structure in which the end portion of the conductor 262B in the Y direction are aligned with the end portions of the insulator 263 and the conductor 264 in the Y direction. Note that the present invention is not limited thereto.

FIG. 7C and FIG. 7D are a top view and a cross-sectional view illustrating another structure example of the capacitor 41. FIG. 7C is a top view of the capacitor 41. FIG. 7D is a cross-sectional view of a portion indicated by the dashed-dotted line A1-A2 in FIG. 7C. As illustrated in FIG. 7C and FIG. 7D, the end portion of the conductor 262B in the Y direction may be positioned outside the end portions of the conductor 264 and the insulator 263 in the Y direction. Although FIG. 7D illustrates the structure in which the end portion of the conductor 264 in the Y direction is aligned with the end portion of the insulator 263 in the Y direction, the present invention is not limited thereto. The end portion of the conductor 264 in the Y direction may be positioned inside the end portion of the insulator 263 in the Y direction.

FIG. 7E and FIG. 7F are a top view and a cross-sectional view illustrating another structure example of the capacitor 41. FIG. 7E is a top view of the capacitor 41. FIG. 7F is a cross-sectional view of a portion indicated by the dashed-dotted line A1-A2 in FIG. 7E. As illustrated in FIG. 7F, the insulator 263 may be provided to cover the top surface and the side surface of the conductor 262B. FIG. 7F illustrates a structure in which the insulator 263 is in contact with the side surface and the top surface of the conductor 262B. With this structure, the conductor 264 and the conductor 262B can be sufficiently isolated from each other by the insulator 263.

Note that FIG. 7F illustrates a structure in which the end portion of the conductor 264 in the Y direction is aligned with the end portion of the conductor 262B in the Y direction. Note that the present invention is not limited thereto.

FIG. 7G and FIG. 7H are a top view and a cross-sectional view illustrating another structure example of the capacitor 41. FIG. 7G is a top view of the capacitor 41. FIG. 7H is a cross-sectional view of a portion indicated by the dashed-dotted line A1-A2 in FIG. 7G. As illustrated in FIG. 7H, the end portion of the conductor 264 in the Y direction may be positioned outside the end portion of the conductor 262B in the Y direction. In this case, the periphery of the conductor 262B is positioned inside the periphery of the conductor 264 in the top view.

Alternatively, as in FIG. 7D, the end portion of the conductor 264 in the Y direction may be positioned inside the end portion of the conductor 262B in the Y direction.

FIG. 1B illustrates a structure in which the capacitor 41 has a planar shape, that is, in which the capacitor 41 is provided over the insulator 274. Note that the present invention is not limited thereto.

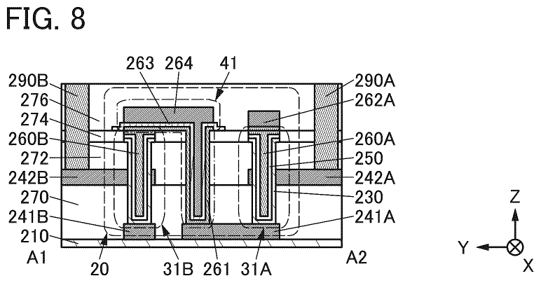

FIG. 8 is a cross-sectional view of a semiconductor device different from the semiconductor device 10 illustrated in FIG. 1B. Note that FIG. 1A can be referred to for the top view of the semiconductor device illustrated in FIG. 8. The structure and shape of the capacitor 41 of the semiconductor device illustrated in FIG. 8 are different from those of the semiconductor device 10 illustrated in FIG. 1B. The semiconductor device illustrated in FIG. 8 is different from the semiconductor device 10 illustrated in FIG. 1B in not including the conductor 262B.

For example, as illustrated in FIG. 8, part of the capacitor 41 may be positioned in an opening provided in the insulator 274, the insulator 272, and the insulator 270. Specifically, the capacitor 41 includes the conductor 261, the insulator 263 over the conductor 261, and the conductor 264 over the insulator 263. The conductor 261 includes a region in contact with the side surface and the bottom surface of the opening, a region in contact with the top surface of the conductor 260B, and a region in contact with part of the top surface of the insulator 274. The conductor 264 includes a region embedded in the opening with the conductor 261 and the insulator 263 therebetween. With this structure, the capacitance per unit area of the capacitor 41 can be increased.

The above is the description of capacitor 41.

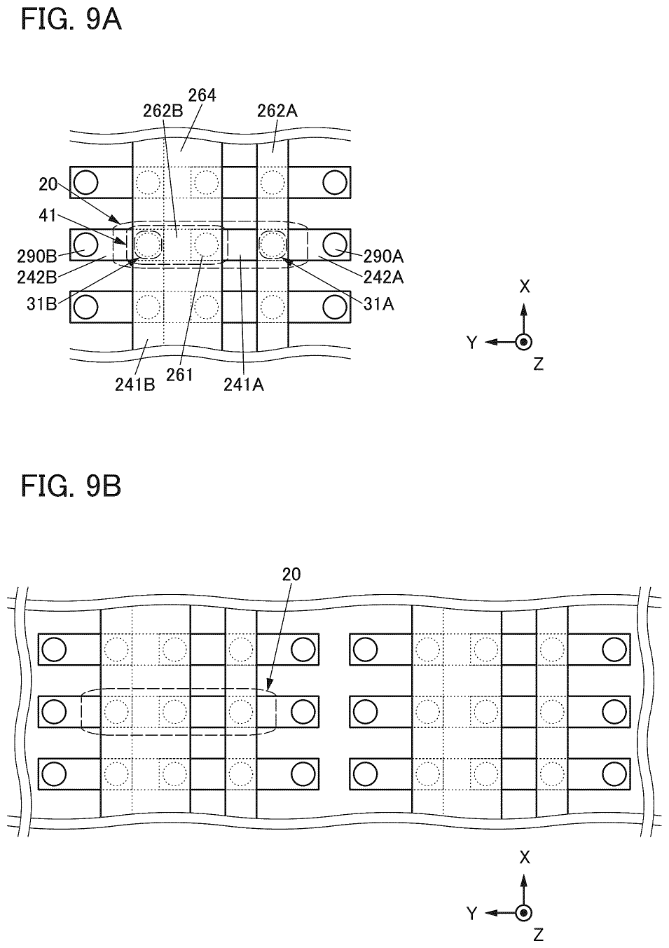

As described above, the semiconductor device 10 can be used as a memory device including the memory cell 20. A memory cell array can be formed when the memory cells 20 are arranged in a matrix. As an example of the memory cell array, FIG. 9A illustrates a memory cell array in which a plurality of memory cells 20 are arranged in the X direction.

FIG. 9A is a top view of the memory cell array. The memory cell array illustrated in FIG. 9A includes the plurality of memory cells 20, and the plurality of memory cells 20 are arranged in the X direction. Note that FIG. 9A illustrates a region including three memory cells 20. As described above, the conductor 241B, the conductor 262A, and the conductor 264 are provided to extend in the X direction. In that case, the conductor 241B, the conductor 262A, and the conductor 264 are shared by the plurality of memory cells 20. With this structure, the semiconductor device can be miniaturized or highly integrated.

Furthermore, when a plurality of memory cell arrays illustrated in FIG. 9A are arranged in the Y direction, the memory cell arrays in which the memory cells 20 are arranged in a matrix can be formed. FIG. 9B is a top view of the memory cell array where the plurality of memory cells 20 are arranged in the X direction and the Y direction. Note that FIG. 9B illustrates a region including six memory cells 20.

### <Variation Example 1 of Semiconductor Device>

An example of a semiconductor device different from <Variation example 1 of the semiconductor device> is described below. Note that in the semiconductor device described below, components having the same functions as the components included in the semiconductor device described in <Structure example 1 of semiconductor device> above are denoted by the same reference numerals. Differences from the semiconductor device described in <Structure example 1 of semiconductor device> above will be mainly described below, and common portions are not described.

### Variation Example 1-1

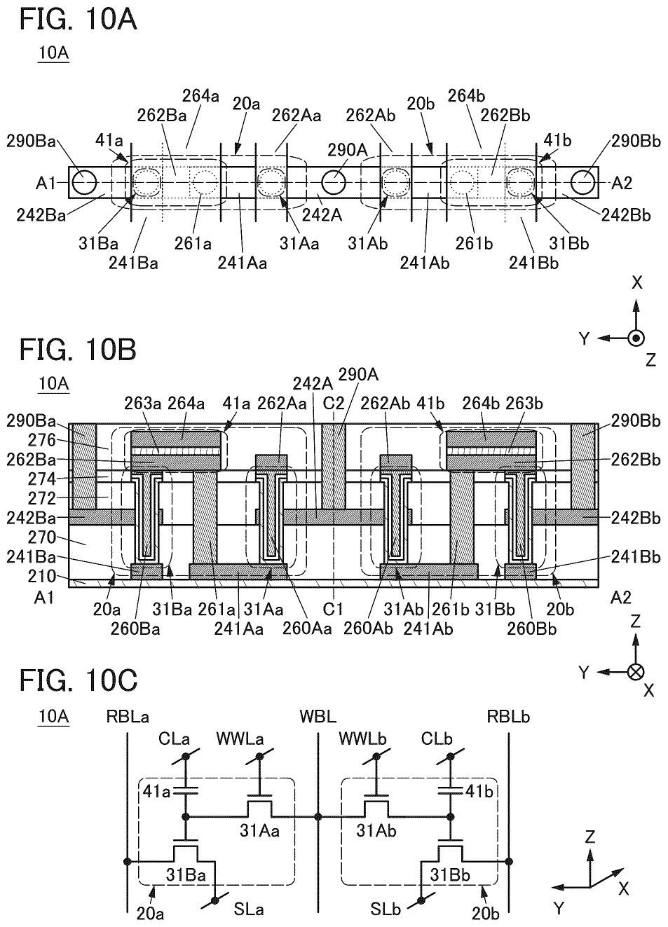

A structure example of a semiconductor device including two memory cells is described below with reference to FIG. 10A and FIG. 10B.

FIG. 10A and FIG. 10B are a top view and a cross-sectional view illustrating structure examples of a semiconductor device 10A. FIG. 10A is a top view of the semiconductor device 10A. FIG. 10B is a cross-sectional view of a portion indicated by the dashed-dotted line A1-A2 in FIG. 10A. Note that for clarity of the drawing, some components are not illustrated in the top view of FIG. 10A.

The semiconductor device 10A includes a memory cell 20a, a memory cell 20b, a conductor 262Aa, a conductor 262Ab, a conductor 290A, a conductor 290Ba, and a conductor 290Bb. The memory cell 20a is provided in the same layer as the memory cell 20b.

The memory cell 20a includes a transistor 31Aa, a transistor 31Ba, a capacitor 41a, and a conductor 261a. The transistor 31Aa includes a conductor 241Aa, a conductor 242A, and a conductor 260Aa. The transistor 31Ba includes a conductor 241Ba, a conductor 242Ba, and a conductor 260Ba. The capacitor 41a includes a conductor 262Ba, an insulator 263a, and a conductor 264a.

The memory cell 20b includes a transistor 31Ab, a transistor 31Bb, a capacitor 41b, and a conductor 261b. The transistor 31Ab includes a conductor 241Ab, the conductor 242A, and a conductor 260Ab. The transistor 31Bb includes a conductor 241Bb, a conductor 242Bb, and a conductor 260Bb. The capacitor 41b includes a conductor 262Bb, an insulator 263b, and a conductor 264b.

The conductor 290A is electrically connected to the conductor 242A.

As illustrated in FIG. 10B, the semiconductor device 10A has a line-symmetric structure with respect to the dashed-dotted line C1-C2 as the symmetric axis. In other words, the memory cell 20b is placed to be line-symmetric with respect to the memory cell 20a using the conductor 290A as the symmetric axis. Thus, the memory cell 20a and the memory cell 20b can be collectively referred to as a pair of memory cells.

The conductor 242A has a region functioning as the other of the source electrode and the drain electrode of the transistor 31Aa and a region functioning as the other of the source electrode and the drain electrode of the transistor 31Ab.

The description of [Transistor 31] above can be referred to for the details of the structure examples of the transistor 31Aa, the transistor 31Ba, the transistor 31Ab, and the transistor 31Bb. The description of [Capacitor 41] above can be referred to for the details of the structure examples of the capacitor 41a and the capacitor 41b.

The semiconductor device 10A can be used as a memory device. FIG. 10C illustrates a circuit diagram of the semiconductor device 10A used as a memory device. The semiconductor device 10A can be rephrased as a memory device including the memory cell 20a and the memory cell 20b. The memory cell 20a includes the transistor 31Aa, the transistor 31Ba, and the capacitor 41a. The memory cell 20b includes the transistor 31Ab, the transistor 31Bb, and the capacitor 41b.

In the transistor 31Aa, a gate electrode is electrically connected to a wiring WWLa, one of a source electrode and a drain electrode is electrically connected to one electrode of the capacitor 41a, and the other of the source electrode and the drain electrode is electrically connected to the wiring WBL. In the transistor 31Ba, a gate electrode is electrically connected to one electrode of the capacitor 41a, one of a source electrode and a drain electrode is electrically connected to a wiring SLa, and the other of the source electrode and the drain electrode is electrically connected to a wiring RBLa. The other electrode of the capacitor 41a is connected to a wiring CLa.

In the transistor 31Ab, a gate electrode is electrically connected to a wiring WWLb, one of a source electrode and a drain electrode is electrically connected to one electrode of the capacitor 41b, and the other of the source electrode and the drain electrode is electrically connected to the wiring WBL. In the transistor 31Bb, a gate electrode is electrically connected to one electrode of the capacitor 41b, one of a source electrode and a drain electrode is electrically connected to a wiring SLb, and the other of the source electrode and the drain electrode is electrically connected to a wiring RBLb. The other electrode of the capacitor 41b is connected to a wiring CLb.

The wiring WWLa corresponds to the conductor 262Aa, the wiring WBL corresponds to the conductor 290A, the wiring SLa corresponds to the conductor 241Ba, the wiring RBLa corresponds to the conductor 290Ba, and the wiring CLa corresponds to the conductor 264a. The wiring WWLb corresponds to the conductor 262Ab, the wiring SLb corresponds to the conductor 241Bb, the wiring RBLb corresponds to the conductor 290Bb, and the wiring CLb corresponds to the conductor 264b.

The wiring WBL is shared by the memory cell 20a and the memory cell 20b. That is, the write bit line is shared by the memory cell 20a and the memory cell 20b. In other words, the conductor 290A has a function of a write bit line of the memory cell 20a and a function of a write bit line of the memory cell 20b.

When the memory cell 20a, the memory cell 20b, and the wirings are connected to each other in the above-described manner, a semiconductor device that can be miniaturized or highly integrated can be provided.

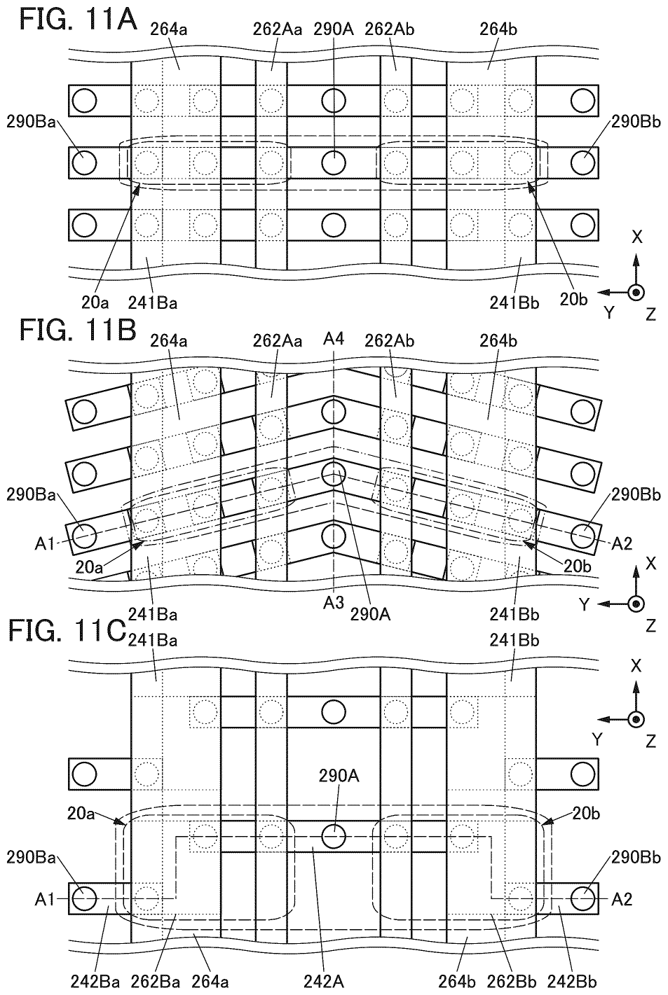

As described above, the semiconductor device 10A can be used as a memory device including a pair of memory cells. A memory cell array can be formed when the pair of memory cells are arranged in a matrix. FIG. 11A illustrates an example of a memory cell array in which a plurality of the pair of memory cells are arranged in the X direction. Note that FIG. 11A illustrates a region including three pairs of memory cells.

In FIG. 11A, the memory cell 20a and the memory cell 20b included in a region surrounded by a dashed double-dotted line form the pair of memory cells. FIG. 11A illustrates a structure in which the conductor 290Ba, the conductor 290A, and the conductor 290Bb are aligned on the same straight line in the pair of memory cells. Specifically, in the pair of memory cells, a straight line that connects the conductor 290Ba, the conductor 290A, and the conductor 290Bb is parallel to the Y direction. That is, in the pair of memory cells, the straight line that connects the conductor 290Ba, the conductor 290A, and the conductor 290Bb is orthogonal to the X direction. Note that the present invention is not limited thereto.

FIG. 11B is a cross-sectional view illustrating another example of a memory cell array. Note that FIG. 10B can be referred to for a cross-sectional view of a portion indicated by the dashed-dotted line A1-A2 in FIG. 11B.

In FIG. 11B, the memory cell 20a and the memory cell 20b included in a region surrounded by a dashed double-dotted line form a pair of memory cells. As in the pair of memory cells illustrated in FIG. 11A, the conductor 290A is shared by the memory cell 20a and the memory cell 20b.

As illustrated in FIG. 11B, a straight line that connects the conductor 290A and the conductor 290Ba electrically connected to the memory cell 20a is inclined in the X direction. Note that since the conductor 262Aa, the conductor 264a, and the conductor 241Ba are provided to extend in the X direction, the straight line is not orthogonal to the direction in which the conductor 262Aa, the conductor 264a, and the conductor 241Ba extend.

Similarly, a straight line that connects the conductor 290A and the conductor 290Bb electrically connected to the memory cell 20b is inclined in the X direction. Note that since the conductor 262Ab, the conductor 264b, and the conductor 241Bb are provided to extend in the X direction, the straight line is not orthogonal to the direction in which the conductor 262Ab, the conductor 264b, and the conductor 241Bb extend.

With the above structure, the memory density of the memory cell array can be further increased in some cases.

Note that although the pair of memory cells has a line-symmetric structure with respect to the dashed-dotted line A3-A4 in FIG. 11B as the symmetric axis, the present invention is not limited thereto. The pair of memory cells is not necessarily line symmetric.

FIG. 11C is a top view illustrating another example of a memory cell array. Note that FIG. 10B can be referred to for a cross-sectional view of a portion indicated by the dashed-dotted line A1-A2 in FIG. 11C.

In FIG. 11C, the memory cell 20a and the memory cell 20b included in a region surrounded by a dashed double-dotted line form a pair of memory cells. As in the pair of memory cells illustrated in FIG. 11A, the conductor 290A is shared by the memory cell 20a and the memory cell 20b.

As illustrated in FIG. 11C, in the pair of memory cells, the conductor 290A is not necessarily positioned on a straight line connecting the conductor 290Ba and the conductor 290Bb. In other words, the conductor 242Ba and the conductor 242Bb are not necessarily positioned on an extended line of the conductor 242A in the Y direction. With this structure, the area occupied by the conductor 262B can be increased, and the capacitance of the capacitor 41 can be increased. Furthermore, the design flexibility of the memory cell array can be increased.

Note that in the structure illustrated in FIG. 11C, the conductor 242Ba and the conductor 242Bb may be provided to extend in the Y direction without providing the conductor 290Ba and the conductor 290Bb. In that case, the conductor 242Ba and the conductor 242Bb include regions functioning as the wiring RBLa and the wiring RBLb, respectively. In this structure, the direction in which the conductor 242Ba extends is orthogonal to the direction in which the conductor 241Ba extends, and the direction in which the conductor 242Bb extends is orthogonal to the direction in which the conductor 241Bb extends.

Note that as in FIG. 9B, the plurality of the memory cell arrays illustrated in any one of FIG. 11A to FIG. 11C may be arranged in the Y direction to form a memory cell array in which memory cells are arranged in a matrix.

Note that in the case where a plurality of pair of memory cells are arranged in the Y direction as in FIG. 9B, the conductor 242Ba included in the memory cell 20a may also serve as the conductor 242Bb included in the memory cell 20b adjacent to the A1 side of the memory cell 20a. The conductor 290Ba electrically connected to the conductor 242Ba of the memory cell 20a may also serve as the conductor 290Bb electrically connected to the conductor 242Bb of the memory cell 20b adjacent to the A1 side of the memory cell 20a. With this structure, the read bit line is shared by the memory cell 20a and the memory cell 20b adjacent in the Y direction. Thus, a semiconductor device that can be miniaturized or highly integrated can be provided. Note that the read bit line may also be shared by the memory cell 20b and the memory cell 20a adjacent to the A2 side of the memory cell 20b.

### Variation Example 1-2

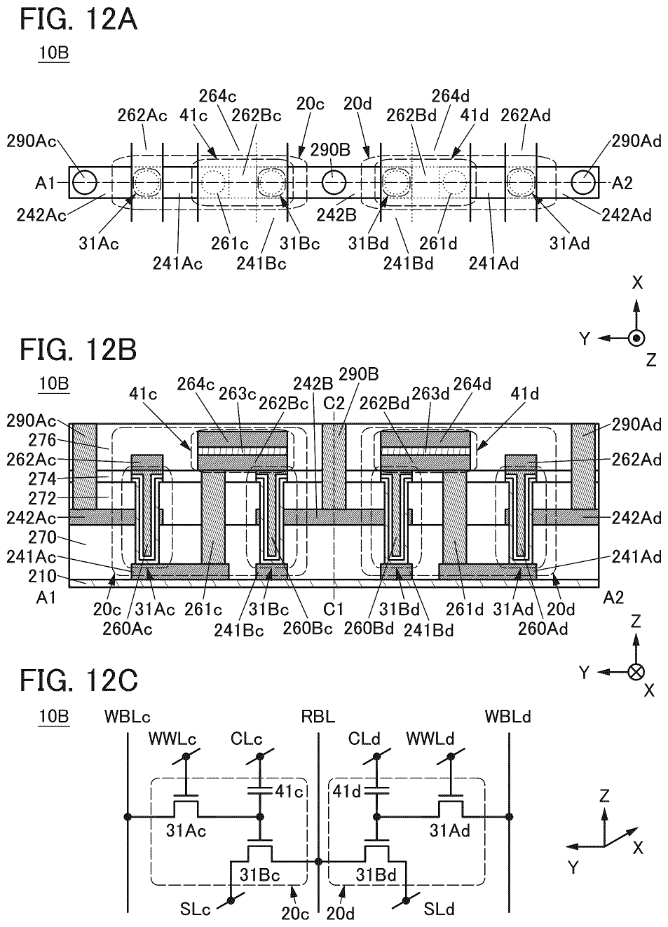

Another structure example of a semiconductor device including two memory cells is described below with reference to FIG. 12A and FIG. 12B.

FIG. 12A and FIG. 12B are a top view and a cross-sectional view illustrating a structure example of the semiconductor device 10B. FIG. 12A is a top view of the semiconductor device 10B. FIG. 12B is a cross-sectional view of a portion indicated by the dashed-dotted line A1-A2 in FIG. 12A. Note that for clarity of the drawing, some components are omitted in the top view of FIG. 12A.

The semiconductor device 10B includes a memory cell 20c, a memory cell 20d, a conductor 262Ac, a conductor 262Ad, a conductor 290Ac, a conductor 290Ad, and a conductor 290B. The memory cell 20c is provided in the same layer as the memory cell 20d.

The memory cell 20c includes a transistor 31Ac, a transistor 31Bc, a capacitor 41c, and a conductor 261c. The transistor 31Ac includes a conductor 241Ac, a conductor 242Ac, and a conductor 260Ac. The transistor 31Bc includes a conductor 241Bc, a conductor 242B, and a conductor 260Bc. The capacitor 41c includes a conductor 262Bc, an insulator 263c, and a conductor 264c.

The memory cell 20d includes a transistor 31Ad, a transistor 31Bd, a capacitor 41d, and a conductor 261d. The transistor 31Ad includes a conductor 241Ad, a conductor 242Ad, and a conductor 260Ad. The transistor 31Bd includes a conductor 241Bd, the conductor 242B, and a conductor 260Bd. The capacitor 41d includes a conductor 262Bd, an insulator 263d, and a conductor 264d.

The conductor 290B is electrically connected to the conductor 242B.

As illustrated in FIG. 12B, the semiconductor device 10B has a line-symmetric structure with respect to the dashed-dotted line C1-C2 as the symmetric axis. In other words, the memory cell 20d is placed to be line-symmetric with respect to the memory cell 20c using the conductor 290B as the symmetric axis. Thus, the memory cell 20c and the memory cell 20d can be collectively referred to as a pair of memory cells.

The conductor 242B includes a region functioning as the other of the source electrode and the drain electrode of the transistor 31Ac and a region functioning as the other of the source electrode and the drain electrode of the transistor 31Ad.

The description of [Transistor 31] above can be referred to for the details of the structure examples of the transistor 31Ac, the transistor 31Bc, the transistor 31Ad, and the transistor 31Bd. The description of [Capacitor 41] above can be referred to for the details of the structure examples of the capacitor 41c and the capacitor 41d.

The semiconductor device 10B can be used as a memory device. FIG. 12C illustrates a circuit diagram of the semiconductor device 10B used as a memory device. The semiconductor device 10B can be rephrased as a memory device including the memory cell 20c and the memory cell 20d. The memory cell 20c includes the transistor 31Ac, the transistor 31Bc, and the capacitor 41c. The memory cell 20d includes the transistor 31Ad, the transistor 31Bd, and the capacitor 41d.

In the transistor 31Ac, a gate electrode is electrically connected to a wiring WWLc, one of a source electrode and a drain electrode is electrically connected to one electrode of the capacitor 41c, and the other of the source electrode and the drain electrode is electrically connected to a wiring WBLc. In the transistor 31Bc, a gate electrode is electrically connected to one electrode of the capacitor 41c, one of a source electrode and a drain electrode is electrically connected to a wiring SLc, and the other of the source electrode and the drain electrode is electrically connected to the wiring RBL. The other electrode of the capacitor 41c is connected to a wiring CLc.

In the transistor 31Ad, a gate electrode is electrically connected to a wiring WWLd, one of a source electrode and a drain electrode is electrically connected to one electrode of the capacitor 41d, and the other of the source electrode and the drain electrode is electrically connected to a wiring WBLd. In the transistor 31Bd, a gate electrode is electrically connected to one electrode of the capacitor 41d, one of a source electrode and a drain electrode is electrically connected to a wiring SLd, and the other of the source electrode and the drain electrode is electrically connected to the wiring RBL. The other electrode of the capacitor 41d is connected to a wiring CLd.

The wiring WWLc corresponds to the conductor 262Ac, the wiring WBLc corresponds to the conductor 290Ac, the wiring SLc corresponds to the conductor 241Bc, the wiring RBL corresponds to the conductor 290B, and the wiring CLc corresponds to the conductor 264c. The wiring WWLd corresponds to the conductor 262Ad, the wiring WBLd corresponds to the conductor 290Ad, the wiring SLd corresponds to the conductor 241Bd, and the wiring CLd corresponds to the conductor 264d.

The wiring RBL is shared by the memory cell 20c and the memory cell 20d. That is, the read bit line is shared by the memory cell 20c and the memory cell 20d. In other words, the conductor 290B has a function of a read bit line of the memory cell 20c and a function of a read bit line of the memory cell 20d.

When the memory cell 20c, the memory cell 20d, and the wirings are connected to each other in the above-described manner, a semiconductor device that can be miniaturized or highly integrated can be provided.

As described above, the semiconductor device 10B can be used as a memory device including a pair of memory cells. A memory cell array can be formed when the pair of memory cells are arranged in a matrix.

Note that in the case where a plurality of pair of memory cells are arranged in the Y direction as in FIG. 9B, the conductor 242Ac included in the memory cell 20c may also serve as the conductor 242Ad included in the memory cell 20d adjacent to the A1 side of the memory cell 20c. The conductor 290Ac electrically connected to the conductor 242Ac of the memory cell 20c may also serve as the conductor 290Ad electrically connected to the conductor 242Ad of the memory cell 20d adjacent to the A1 side of the memory cell 20c. With this structure, the write bit line is shared by the memory cell 20c and the memory cell 20d adjacent in the Y direction. Thus, a semiconductor device that can be miniaturized or highly integrated can be provided. Note that the write bit line may also be shared by the memory cell 20d and the memory cell 20c adjacent to the A2 side of the memory cell 20d.

### Variation Example 1-3

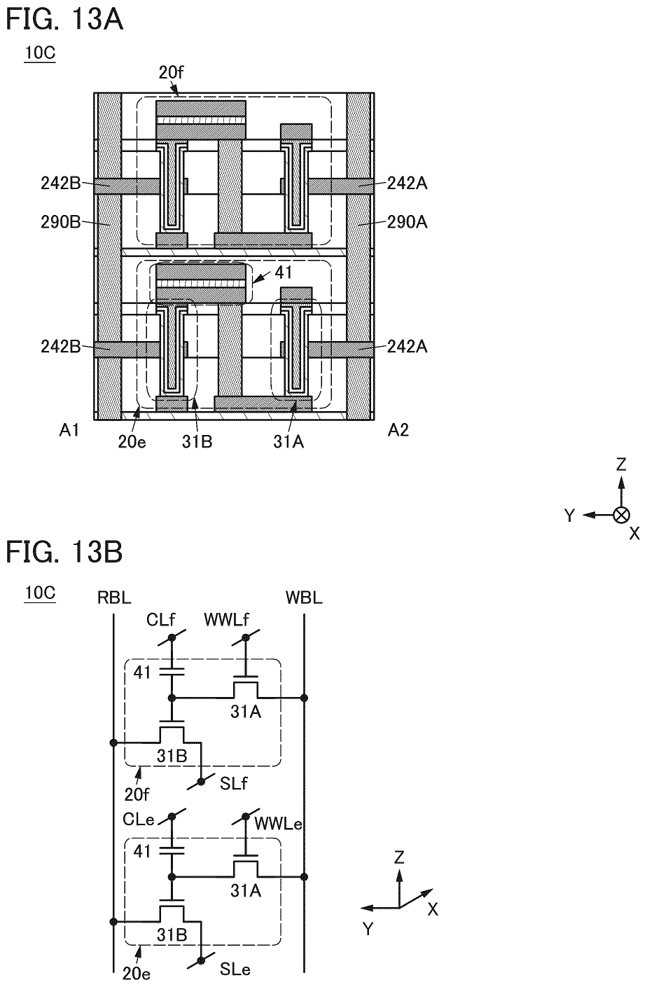

Another structure example of a semiconductor device including two memory cells is described below with reference to FIG. 13A.

FIG. 13A a cross-sectional view of a semiconductor device 10C. Note that FIG. 1A can be referred to for the top view of the semiconductor device 10C.

The semiconductor device 10C includes a memory cell 20e and a memory cell 20f over the memory cell 20e. That is, the semiconductor device 10C has a structure in which two memory cells are arranged in the Z direction. In other words, the semiconductor device 10C has a structure in which two memory cells are stacked. Alternatively, the semiconductor device 10C has a structure in which two layers including memory cells (also referred to as memory layers) are stacked. The semiconductor device 10C includes the conductor 290A and the conductor 290B.

Each of the memory cell 20e and the memory cell 20f has the same structure as the memory cell 20 illustrated in FIG. 1A and FIG. 1B. Thus, the description of <Structure example 1 of semiconductor device> above can be referred to for the details of the structure examples of the memory cell 20e and the memory cell 20f.

The conductor 290A is electrically connected to each of the conductor 242A included in the memory cell 20e and the conductor 242A included in the memory cell 20f. Similarly, the conductor 290B is electrically connected to each of the conductor 242B included in the memory cell 20e and the conductor 242B included in the memory cell 20f.

Thus, the semiconductor device 10C can be used as a memory device. FIG. 13B illustrates a circuit diagram of the semiconductor device 10C used as a memory device. The semiconductor device 10C can be rephrased as a memory device including the memory cell 20e and the memory cell 20f. Each of the memory cell 20f and the memory cell 20f includes the transistor 31A, the transistor 31B, and the capacitor 41.

In the transistor 31A included in the memory cell 20e, a gate electrode is electrically connected to a wiring WWLe, one of a source electrode and a drain electrode is electrically connected to one electrode of the capacitor 41 included in the memory cell 20e, and the other of the source electrode and the drain electrode is electrically connected to the wiring WBL. In the transistor 31B included in the memory cell 20e, a gate electrode is electrically connected to one electrode of the capacitor 41 included in the memory cell 20e, one of a source electrode and a drain electrode is electrically connected to a wiring SLe, and the other of the source electrode and the drain electrode is electrically connected to the wiring RBL. The other electrode of the capacitor 41 included in the memory cell 20e is connected to a wiring CLe.

In the transistor 31A included in the memory cell 20f, a gate electrode is electrically connected to a wiring WWLf, one of a source electrode and a drain electrode is electrically connected to one electrode of the capacitor 41 included in the memory cell 20f, and the other of the source electrode and the drain electrode is electrically connected to the wiring WBL. In the transistor 31B included in the memory cell 20f, a gate electrode is electrically connected to one electrode of the capacitor 41 included in the memory cell 20f, one of a source electrode and a drain electrode is electrically connected to a wiring SLf, and the other of the source electrode and the drain electrode is electrically connected to the wiring RBL. The other electrode of the capacitor 41 included in the memory cell 20f is connected to a wiring CLf.

The wiring WBL corresponds to the conductor 290A, and the wiring RBL corresponds to the conductor 290B.

The wiring WBL is shared by the memory cell 20e and the memory cell 20f. That is, the write bit line is shared by the memory cell 20e and the memory cell 20f. In other words, the conductor 290A has a function of a write bit line of the memory cell 20e and a function of a write bit line of the memory cell 20f.

The wiring RBL is shared by the memory cell 20e and the memory cell 20f. That is, the read bit line is shared by the memory cell 20e and the memory cell 20f. In other words, the conductor 290B has a function of a read bit line of the memory cell 20e and a function of a read bit line of the memory cell 20f.

With the above structure, the memory capacity of the memory device can be increased without an increase in the area occupied by the memory cell. Thus, the area occupied per bit is reduced, so that a small semiconductor device with large memory capacity can be achieved.

Note that FIG. 13A illustrates a structure in which the conductor 290A is in contact with the top surface of the conductor 242A included in the memory cell 20e and the bottom surface of the conductor 242A included in the memory cell 20f. In addition, the conductor 290B is in contact with the top surface of the conductor 242B included in the memory cell 20e and the bottom surface of the conductor 242B included in the memory cell 20f. Note that the present invention is not limited thereto.

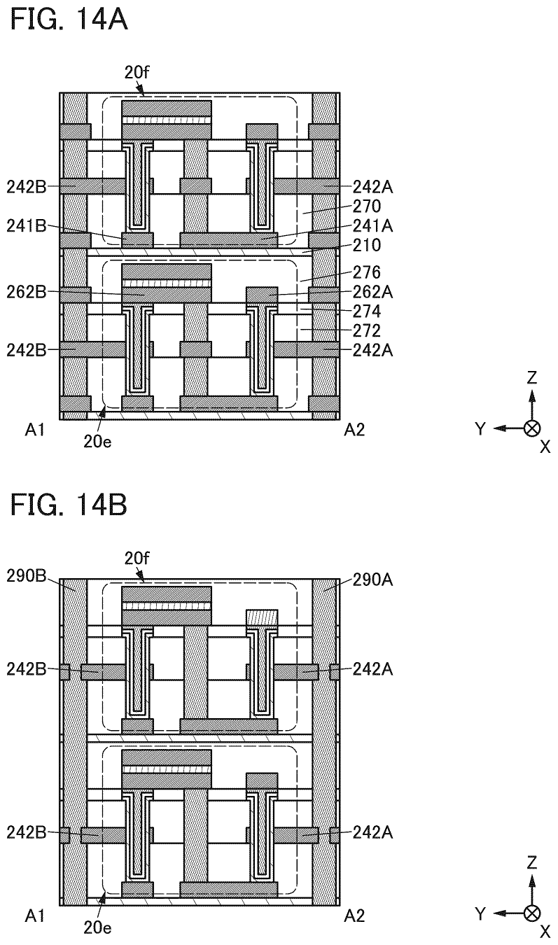

For example, the conductor 242A included in the memory cell 20e and the conductor 242A included in the memory cell 20f may be electrically connected to each other through a structure body formed of a plurality of conductors. Specifically, as illustrated in FIG. 14A, the conductor 242A included in the memory cell 20e and the conductor 242A included in the memory cell 20f may be electrically connected to each other through a structure body formed of a conductor provided in the opening included in the insulator 270, a conductor provided in the same layer as the conductor 241A and the conductor 241B, a conductor provided in the opening included in the insulator 210 and the insulator 276, a conductor provided in the same layer as the conductor 262A and the conductor 262B, and a conductor provided in the opening included in the insulator 274 and the insulator 272. The same applies to the electrical connection between the conductor 242B included in the memory cell 20e and the conductor 242B included in the memory cell 20f.

Alternatively, for example, the conductor 242A included in the memory cell 20e and the conductor 242A included in the memory cell 20f may be electrically connected to each other by a conductor provided to extend in the Z direction. Similarly, the conductor 242B included in the memory cell 20e and the conductor 242B included in the memory cell 20f may be electrically connected to each other by a conductor provided to extend in the Z direction. Specifically, as illustrated in FIG. 14B, the conductor 290A may be provided to extend in the Z direction and include a region in contact with the top surface and the side surface of the conductor 242A. The conductor 290B may be provided to extend in the Z direction and include a region in contact with the top surface and the side surface of the conductor 242B. With this structure, an electrode for connection does not need to be provided additionally between the conductor 242A and the conductor 290A. In addition, an electrode for connection does not need to be provided additionally between the conductor 242B and the conductor 290B. Accordingly, a semiconductor device having a high degree of integration of memory cells can be provided.

Note that in this specification and the like, the contact between the conductor 290A and the conductor 242A is referred to as a top-side contact in some cases. The conductor 290A may be in contact with part of the bottom surface of the conductor 242A. With this structure, the area of a region where the conductor 290A and the conductor 242A are in contact with each other can be further increased. Note that the same applies to the contact between the conductor 290B and the conductor 242B.

FIG. 13A illustrates a structure in which the two memory cells 20 illustrated in FIG. 1B are stacked. Note that there is no particular limitation on the stacked memory cells as long as the memory cell positioned below and the memory cell positioned above share the write bit line and the read bit line. For example, two pairs of memory cells included in the semiconductor device 10A may be stacked, or two pairs of memory cells included in the semiconductor device 10B may be stacked. Alternatively, two memory cell arrays in which the plurality of memory cells are arranged in at least one of the X direction and the Y direction may be stacked. In this case, the memory layer can be regarded as a layer including memory cell arrays.

Although FIG. 13A illustrates the structure in which two memory layers are stacked, the present invention is not limited thereto. A stack including three or more memory layers may be employed. When the number of stacked memory layers is increased, the memory capacity of the memory device can be increased without increasing the area occupied by the memory cells. Thus, the area occupied per bit is reduced, so that a small semiconductor device with large memory capacity can be achieved.

### <Structure Example 2 of Semiconductor>

An example of a semiconductor device different from <Structure example 1 of semiconductor device> above is described below. Note that in the semiconductor device described below, components having the same functions as the components included in the semiconductor device described in <Structure example 1 of semiconductor device> above are denoted by the same reference numerals. Differences from the semiconductor device described in <Structure example 1 of semiconductor device> above will be mainly described below, and common portions are not described.

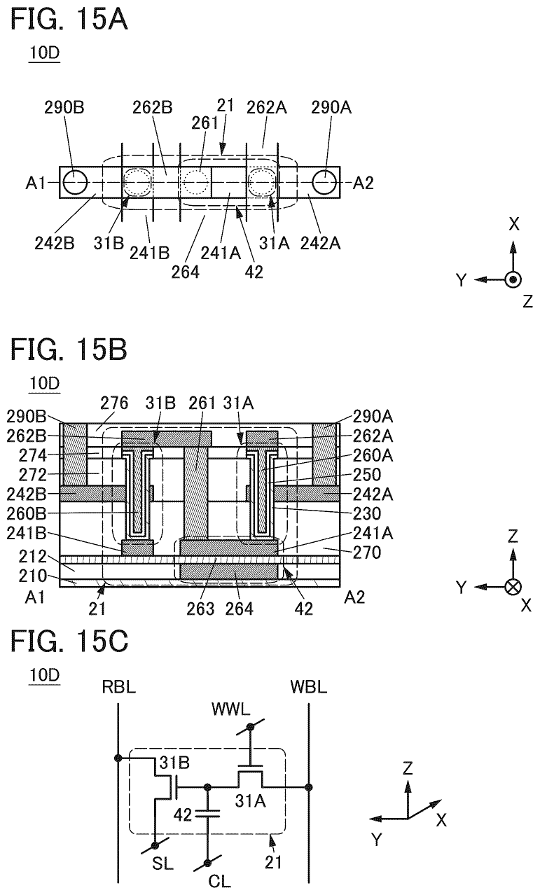

FIG. 15A and FIG. 15B are a top view and a cross-sectional view illustrating another structure example of the semiconductor device of one embodiment of the present invention. FIG. 15A is a top view of a semiconductor device 10D. FIG. 15B is a cross-sectional view of the semiconductor device 10D, and is a cross-sectional view of a portion indicated by dashed-dotted line A1-A2 in FIG. 15A. Note that for clarity of the drawing, some components are omitted in the top view of FIG. 15A.

The semiconductor device 10D includes the insulator 210 over a substrate (not illustrated), the memory cell 21 over the insulator 210, the conductor 262A, the conductor 290A, the conductor 290B, the insulator 212 over the insulator 210, the insulator 263 over the insulator 212, the insulator 270 over the insulator 263, the insulator 272 over the insulator 270, the insulator 274 over the insulator 272, and the insulator 276 over the insulator 274. The memory cell 21 is electrically connected to each of the conductor 262A, the conductor 290A, and the conductor 290B.

The memory cell 21 includes a capacitor 42, the transistor 31A over the capacitor 42, the transistor 31B, the conductor 261, and the conductor 262B. Note that the transistor 31A is provided in the same layer as the transistor 31B. That is, it can be said that the memory cell 21 has a structure in which the capacitor 41 is replaced with the capacitor 42 in the memory cell 20 illustrated in FIG. 1B.

The description of [Transistor 31] above can be referred to for the details of the structure examples of the transistor 31A and the transistor 31B.

The capacitor 42 includes the conductor 264, the insulator 263 over the conductor 264, and the conductor 241A over the insulator 263. The conductor 241A includes a region functioning as one electrode of the capacitor 42, the conductor 264 includes a region functioning as the other electrode of the capacitor 42, and the insulator 263 includes a region functioning as a dielectric of the capacitor 42.

As in the structure illustrated in FIG. 1A and FIG. 1B, in the semiconductor device 10D, the conductor 241B, the conductor 262A, and the conductor 264 are provided to extend in the X direction (FIG. 15A). The conductor 290A and the conductor 290B are provided to extend in the Z direction (FIG. 15B). With this structure, the direction in which the conductor 262A extends and the direction in which the conductor 290A extends are orthogonal to each other. The direction in which the conductor 241B extends is orthogonal to the direction in which the conductor 290B extends.

Although the capacitor 42 of the semiconductor device 10D illustrated in FIG. 15B has a planar shape, the present invention is not limited thereto. For example, the capacitor 42 may have a cylindrical shape.

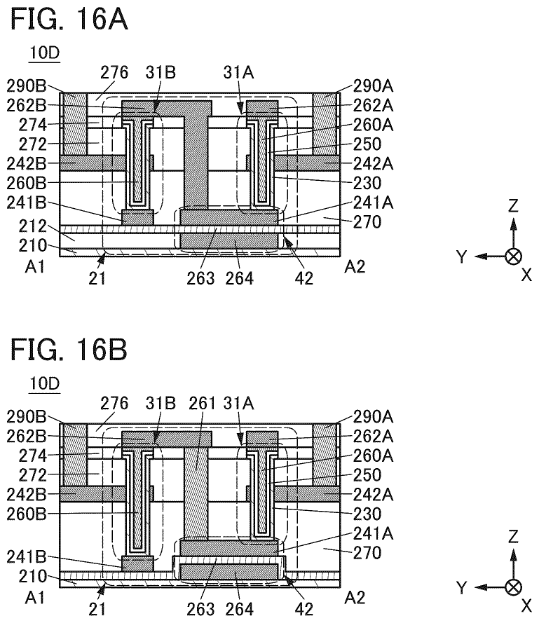

FIG. 15B illustrates a structure in which the conductor 261 and the conductor 262B are provided. Note that the present invention is not limited thereto. For example, as illustrated in FIG. 16A, the conductor 261 may be omitted and part of the conductor 262B may be provided in the opening provided in the insulator 274, the insulator 272, and the insulator 270. At this time, the conductor 262B can also function as the conductor 261. With this structure, the number of steps in the manufacturing process of the semiconductor device can be reduced. Note that FIG. 15A can be referred to for the top view of the semiconductor device illustrated in FIG. 16A. The structure of the semiconductor device 10D illustrated in FIG. 15B can be regarded as a structure in which the conductor 262B included in the semiconductor device 10D illustrated in FIG. 16B is replaced with a structure body formed of the conductor 261 and the conductor 262B over the conductor 261.

FIG. 15B illustrates a structure in which the insulator 212 is provided. Note that the present invention is not limited thereto. For example, a structure in which the insulator 212 is not provided as illustrated in FIG. 16B may be employed. At this time, the insulator 263 includes a region in contact with the top surface and the side surface of the conductor 264 and the top surface of the insulator 210. Since the insulator 212 is not provided in the structure illustrated in FIG. 16B, the number of steps in the manufacturing process of the semiconductor device can be reduced. Note that FIG. 15A can be referred to for the top view of the semiconductor device illustrated in FIG. 16B.

In the structure illustrated in FIG. 16B, the conductor 241A and the conductor 241B are provided over the insulator 263. That is, it can be said that the conductor 241B is provided in the same layer as the conductor 241A. At this time, the shortest distance from the top surface of the conductor 241B to the bottom surface of the conductor 242B is larger than the shortest distance from the top surface of the conductor 241A to the bottom surface of the conductor 242A. That is, the channel length of the transistor 31B is longer than the channel length of the transistor 31A. Thus, the channel capacitance (capacitance between the gate electrode and the channel formation region) of the transistor 31B functioning as a read transistor is increased, and the capacitance of the capacitor 42 can be reduced in some cases. Thus, the area occupied by the capacitor 42 can be reduced, and the memory cell can be miniaturized or highly integrated.

An increase in the channel length can reduce Vth variations of transistors. Thus, the transistor 31B functioning as a read transistor has a long channel length, so that a memory cell that allows highly accurate reading can be provided. Note that the transistor 31A and the transistor 31B have a vertical structure and thus the channel length can be relatively easily shortened. When the channel length of the transistor 31A functioning as a writing transistor is made short and the channel length of the transistor 31B functioning as a reading transistor is made long, a memory cell with high writing speed and high reading accuracy can be achieved.

Note that in the structure illustrated in FIG. 16B, the channel length of the transistor 31B is longer than the channel length of the transistor 31A; thus, the semiconductor device 10D is preferably manufactured with adjusted channel widths of the transistor 31A and the transistor 31B. For example, when the diameter of the opening in which the metal oxide 230, the insulator 250, and the conductor 260 are provided is increased in the transistor 31B functioning as a reading transistor, a memory cell with high reading accuracy and high reading speed can be achieved. At this time, the channel width of the transistor 31B is larger than the channel width of the transistor 31A. In other words, the diameter of the opening provided in the conductor 242B is larger than the diameter of the opening provided in the conductor 242A.

The semiconductor device 10D can be used as a memory device. FIG. 15C illustrates a circuit diagram of the semiconductor device 10D used as a memory device. The semiconductor device 10D can be rephrased as a memory device including the memory cell 21. The memory cell 21 includes the transistor 31A, the transistor 31B, and the capacitor 42.

As illustrated in FIG. 15C, in the transistor 31A, the gate electrode is electrically connected to the wiring WWL, one of the source electrode and the drain electrode is electrically connected to the one electrode of the capacitor 42, and the other of the source electrode and the drain electrode is electrically connected to the wiring WBL. In the transistor 31B, the gate electrode is electrically connected to one electrode of the capacitor 42, one of the source electrode and the drain electrode is electrically connected to the wiring SL, and the other of the source electrode and the drain electrode is electrically connected to the wiring RBL. The other electrode of the capacitor 42 is connected to the wiring CL.

When the transistor 31A and the transistor 31B are provided above the capacitor 42, the transistor 31A and the transistor 31B are not affected by thermal budget in manufacturing the capacitor 42. Thus, in the transistor 31A and the transistor 31B, degradation of the electrical characteristics of the transistors such as variation in threshold voltage and an increase in parasitic resistance, and an increase in variation in electrical characteristics due to the degradation of the electrical characteristics can be inhibited. Thus, a semiconductor device with favorable electrical characteristics can be provided. Alternatively, a semiconductor device with a small variation in electrical characteristics can be provided. Alternatively, a highly reliable semiconductor device can be provided.

As described above, the semiconductor device 10D can be used as a memory device including the memory cell 21. A memory cell array can be formed when the memory cells 21 are arranged in a matrix. For example, as in the structure illustrated in FIG. 9A, a plurality of memory cells 21 may be arranged in the X direction to form a memory cell array, or as in the structure illustrated in FIG. 9B, the plurality of memory cells 21 may be arranged in the X direction and the Y direction to form the memory cell array. A plurality of layers including the memory cells 21 or the memory cell array may be stacked.

As described in [Variation example 1-1] above, two adjacent memory cells 21 may share a write bit line; as described in [Variation example 1-2] above, two adjacent memory cells 21 may share a read bit line; or as described in [Variation example 1-3] above, two stacked memory cells 21 may share a write bit line and a read bit line.

### <Structure Example 3 of Semiconductor Device>

Although FIG. 13A illustrates a structure in which memory cells having the same structure are stacked, the present invention is not limited thereto. As long as the structure of the transistor included in the memory cell positioned above is the same as that of the transistor included in the memory cell positioned below, memory cells having different structures may be stacked.

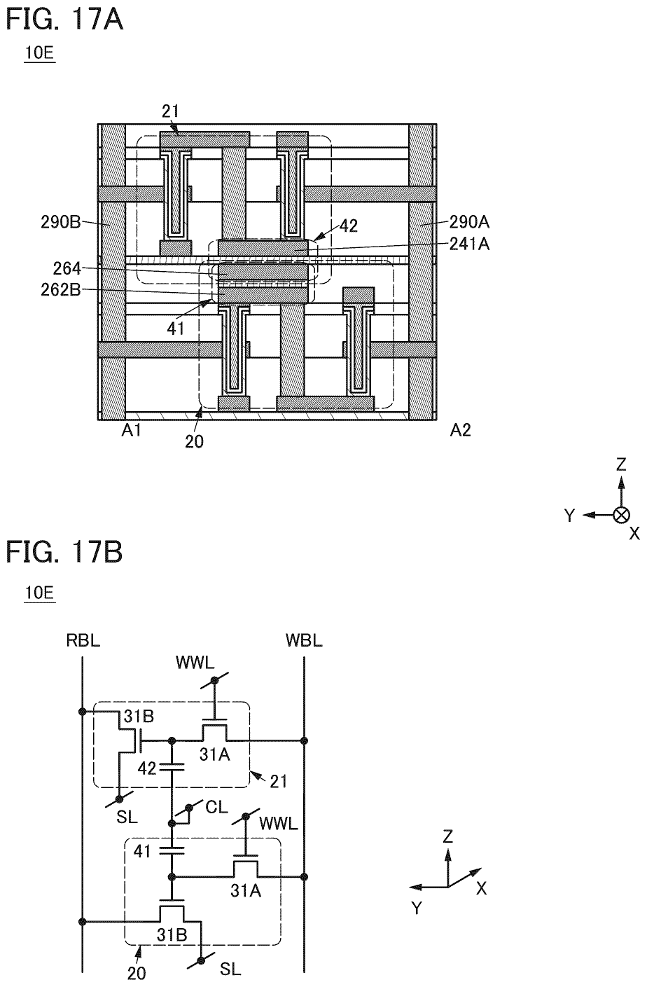

FIG. 17A is a schematic cross-sectional view of a semiconductor device 10E.

The semiconductor device 10E includes the memory cell 20, the memory cell 21 over the memory cell 20, the conductor 290A, and the conductor 290B.

The memory cell 20 has the same structure as the memory cell 20 illustrated in FIG. 1A and FIG. 1B. Thus, the description of <Structure example 1 of semiconductor device> above can be referred to for the details of the structure example of the memory cell 20. The memory cell 21 has the same structure as the memory cell 21 illustrated in FIG. 15A and FIG. 15B. Thus, for the details of the structure example of the memory cell 21, the description of <Structure example 2 of semiconductor device> above can be referred to.

That is, the semiconductor device 10E has a structure in which memory cells with different structures are arranged in the Z direction. In other words, the semiconductor device 10E has a structure in which memory cells with different structures are stacked.

Furthermore, the conductor 264 also functions as the other electrode of the capacitor 41 included in the memory cell 20 and the other electrode of the capacitor 42 included in the memory cell 21. With this structure, the manufacturing steps of the memory device can be reduced and the productivity can be improved.

The semiconductor device 10E can be used as a memory device. FIG. 17B illustrates a circuit diagram of the semiconductor device 10E used as a memory device. The semiconductor device 10E can be rephrased as a memory device including the memory cell 20 and the memory cell 21.

As illustrated in FIG. 17B, the wiring CL is shared by the memory cell 20 and the memory cell 21. That is, the capacitor line is shared by the memory cell 20 and the memory cell 21. In other words, the conductor 264 has a function of a capacitor line of the memory cell 20 and a function of a capacitor line of the memory cell 21.

Furthermore, the wiring WBL and the wiring RBL are shared by the memory cell 20 and the memory cell 21. That is, the write bit line and the read bit line are shared by the memory cell 20 and the memory cell 21. In other words, the conductor 290A has a function of a write bit line of the memory cell 20 and a function of a write bit line of the memory cell 21. The conductor 290B has a function of a read bit line of the memory cell 20 and a function of a read bit line of the memory cell 21.

With the above structure, the memory capacity of the memory device can be increased without an increase in the area occupied by the memory cell. Thus, the area occupied per bit is reduced, so that a small semiconductor device with large memory capacity can be achieved.

As described above, the semiconductor device 10E can be used as a memory device including a pair of memory cells sharing the wiring CL. A memory cell array can be formed when the pair of memory cells are arranged in at least one of the X direction and the Y direction.

### <Structure Example of Semiconductor Device 4>

An example of a semiconductor device different from the above-described semiconductor device is described below. Note that in the semiconductor device described below, components having the same functions as the components included in the semiconductor device described above are denoted by the same reference numerals. Differences from the semiconductor device described above will be mainly described below, and common portions are not described.

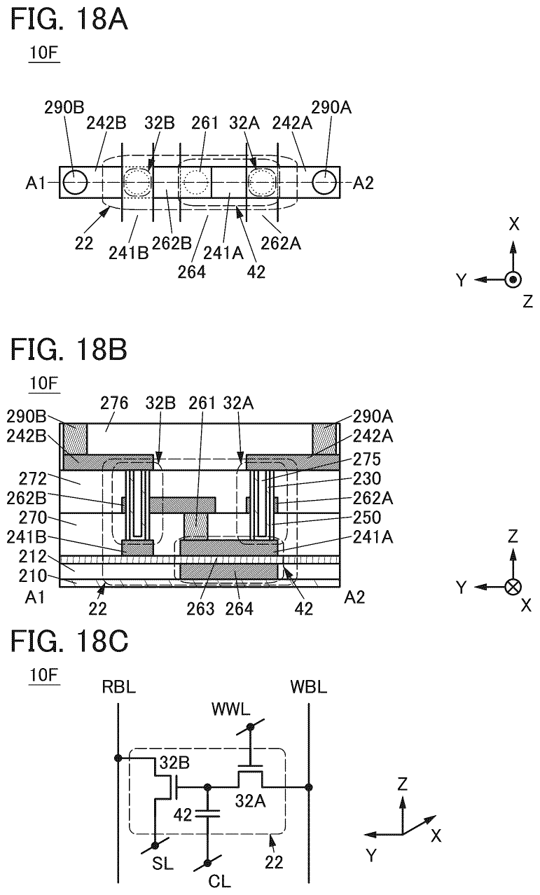

FIG. 18A and FIG. 18B are a top view and a cross-sectional view illustrating another structure example of the semiconductor device of one embodiment of the present invention. FIG. 18A is a top view of a semiconductor device 10F. FIG. 18B is a cross-sectional view of the semiconductor device 10F, and is a cross-sectional view of a portion indicated by the dashed-dotted line A1-A2 in FIG. 18A. Note that for clarity of the drawing, some components are not illustrated in the top view of FIG. 18A.

The semiconductor device 10F includes the insulator 210 over a substrate (not illustrated), a memory cell 22 over the insulator 210, the conductor 290A, the conductor 290B, the insulator 212 over the insulator 210, the insulator 263 over the insulator 212, the insulator 270 over the insulator 263, the insulator 272 over the insulator 270, and the insulator 276 over the insulator 272. The memory cell 22 is electrically connected to each of the conductor 290A and the conductor 290B.

The memory cell 22 includes the capacitor 42, a transistor 32A over the capacitor 42, a transistor 32B, and the conductor 261. Note that the transistor 32A is provided in the same layer as the transistor 32B. That is, in the memory cell 21 illustrated in FIG. 15B, the transistor 31A and the transistor 31B are replaced with the transistor 32A and the transistor 32B, respectively.

The transistor 32A includes the conductor 241A, the conductor 262A over the conductor 241A, and the conductor 242A over the conductor 262A. The conductor 241A includes a region functioning as one of a source electrode and a drain electrode of the transistor 32A, the conductor 242A includes a region functioning as the other of the source electrode and the drain electrode of the transistor 32A, and the conductor 262A includes a region functioning as a gate electrode of the transistor 32A.

The transistor 32B includes the conductor 241B, the conductor 262B over the conductor 241B, and the conductor 242B over the conductor 262B. The conductor 241B includes a region functioning as one of a source electrode and a drain electrode of the transistor 32B, the conductor 242B includes a region functioning as the other of the source electrode and the drain electrode of the transistor 32B, and the conductor 262B includes a region functioning as a gate electrode of the transistor 32B.

As described above, the transistor 32A is provided in the same layer as the transistor 32B. That is, the conductor 241A is provided in the same layer as the conductor 241B, the conductor 262A is provided in the same layer as the conductor 262B, and the conductor 242A is provided in the same layer as the conductor 242B. Specifically, the conductor 241A and the conductor 241B are provided over the insulator 263, the conductor 262A and the conductor 262B are provided over the insulator 270, and the conductor 242A and the conductor 242B are provided over the insulator 272.

For the details of the structure example of the capacitor 42, the description of <Structure example 2 of semiconductor device> above can be referred to.

The conductor 241A is electrically connected to the conductor 261, and the conductor 261 is electrically connected to the conductor 262B. That is, the conductor 261 has a function of electrically connecting the conductor 262B and the conductor 241A. The conductor 290A is electrically connected to the conductor 242A, and the conductor 290B is electrically connected to the conductor 242B.

As in the structure illustrated in FIG. 1A and FIG. 1B, in the semiconductor device 10F, the conductor 241B, the conductor 262A, and the conductor 264 are provided to extend in the X direction (FIG. 18A). The conductor 290A and the conductor 290B are provided to extend in the Z direction (FIG. 18B). With this structure, the direction in which the conductor 262A extends and the direction in which the conductor 290A extends are orthogonal to each other. The direction in which the conductor 241B extends and the direction in which the conductor 290B extends are orthogonal to each other.

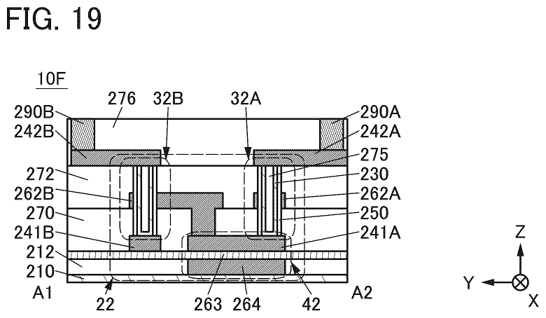

FIG. 18B illustrates a structure in which the conductor 261 and the conductor 262B are provided. Note that the present invention is not limited thereto. For example, as illustrated in FIG. 19, a structure may be employed in which part of the conductor 262B is provided in the opening included in the insulator 270 and the conductor 261 is not provided. At this time, the conductor 262B can also have the function of the conductor 261. With this structure, the number of steps in the manufacturing process of the semiconductor device can be reduced.

Thus, the semiconductor device 10F can be used as a memory device. FIG. 18C illustrates a circuit diagram of the semiconductor device 10F used as a memory device. The semiconductor device 10F can be rephrased as a memory device including the memory cell 22. The memory cell 22 includes the transistor 32A, the transistor 32B, and the capacitor 42.

As illustrated in FIG. 18C, in the transistor 32A, the gate electrode is electrically connected to the wiring WWL, one of the source electrode and the drain electrode is electrically connected to the one electrode of the capacitor 42, and the other of the source electrode and the drain electrode is electrically connected to the wiring WBL. In the transistor 32B, the gate electrode is electrically connected to the one electrode of the capacitor 42, one of a source electrode and a drain electrode is electrically connected to the wiring SL, and the other of the source electrode and the drain electrode is electrically connected to the wiring RBL. The other electrode of the capacitor 42 is connected to the wiring CL.

### [Transistor 32]

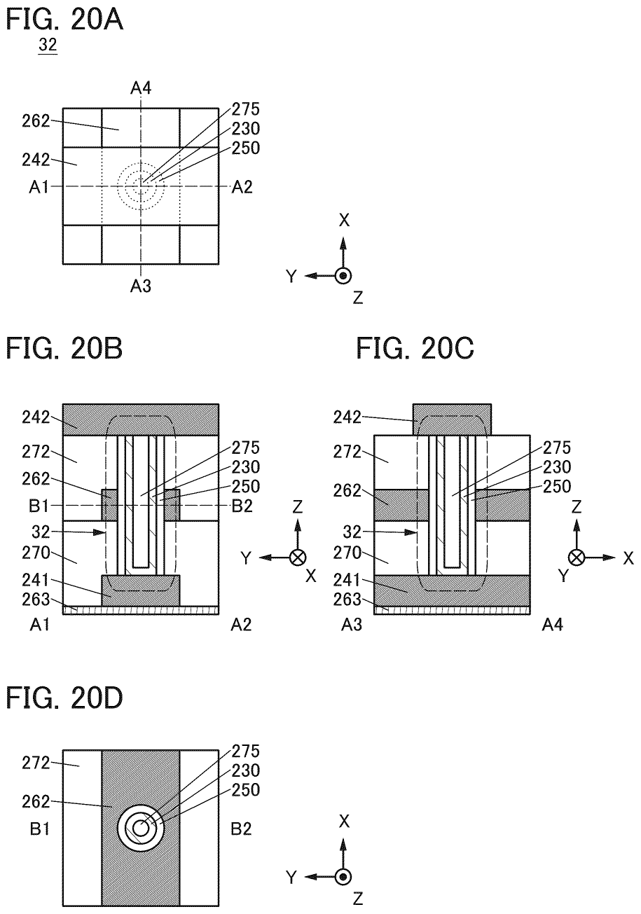

FIG. 20A to FIG. 20D are top views and cross-sectional views illustrating a structure example of a transistor included in the memory cell 22. FIG. 20A is a top view of the transistor 32. FIG. 20B is a cross-sectional view of a portion indicated by the dashed-dotted line A1-A2 in FIG. 20A, and FIG. 20C is a cross-sectional view of a portion indicated by the dashed-dotted line A3-A4 in FIG. 20A. FIG. 20D is a top view of a portion indicated by the dashed-sotted line B1-B2 in FIG. 20D. Note that for clarity of the drawing, some components are not illustrated in the top views of FIG. 20A and FIG. 20D.

The transistor 32 includes the conductor 241 and the insulator 270 over the insulator 263, the insulator 250 and the metal oxide 230 over the conductor 241, the insulator 275 over the metal oxide 230, the conductor 262 and the insulator 272 over the insulator 270, and the conductor 242 over the insulator 272, the insulator 250, the metal oxide 230, and the insulator 275.

The conductor 241 includes a region functioning as one of a source electrode and a drain electrode of the transistor 32, the conductor 242 includes a region functioning as the other of the source electrode and the drain electrode of the transistor 32, and the conductor 262 includes a region functioning as a gate electrode of the transistor 32. The metal oxide 230 includes a region functioning as a channel formation region. The insulator 250 includes a region functioning as a gate insulator of the transistor 32.

An opening reaching the conductor 241 is provided in the insulator 272, the conductor 262, and the insulator 270. In addition, the opening includes a region overlapping with the conductor 241 in the top view. The insulator 250, the metal oxide 230, and the insulator 275 are placed in the opening. Note that it can be said that the opening has an opening included in the insulator 272, an opening included in the conductor 262, and an opening included in the insulator 270. It can be said that the conductor 262 has an opening overlapping with the conductor 241 in the top view.

The insulator 250 is provided in contact with the side surface and part of the bottom surface of the opening provided in the insulator 272, the conductor 262, and the insulator 270. In other words, the insulator 250 includes a region in contact with the side surface of the opening included in the conductor 262 and part of the top surface of the conductor 241. It can be said that the insulator 250 has a cylindrical shape provided with a hollow portion.

The metal oxide 230 is provided in an opening provided in the insulator 272, the conductor 262, and the insulator 270 with the insulator 250 therebetween. The metal oxide 230 includes regions in contact with the conductor 241 and the conductor 242 and regions overlapping with the conductor 262 with the insulator 250 therebetween. In other words, the metal oxide 230 includes the region in contact with the conductor 241 and the conductor 242 and a region facing the conductor 262 with the insulator 250 therebetween. The metal oxide 230 includes a concave portion. In the case where the diameter of the opening provided in the insulator 272, the conductor 262, and the insulator 270 is small, the metal oxide 230 does not include a concave portion in some cases. Alternatively, the metal oxide 230 includes a concave portion with a small diameter in some cases.

The insulator 275 is provided to fill the concave portion of the metal oxide 230. In the case where the metal oxide 230 does not include a concave portion, the insulator 275 is not necessarily provided. In the case where the metal oxide 230 includes a concave portion with a small diameter, a gap may be provided instead of the insulator 275. In this case, the gap is provided between the metal oxide 230 and the conductor 242. The gap contains, for example, any one or more selected from air, nitrogen, oxygen, carbon dioxide, and a Group 18 element.

In the above structure, the channel length of the transistor 32 is the height (depth) of the opening provided in the insulator 272, the conductor 262, and the insulator 270. Thus, the channel length of the transistor 32 can be adjusted by the height (depth) of the opening. Note that in the case where the conductor 241 does not include a concave portion in a region overlapping with the opening, the channel length of the transistor 32 can be regarded as the shortest distance from the top surface of the conductor 241 to the bottom surface of the conductor 242 in the cross-sectional view. That is, in order to adjust the height (depth) of the opening, the thickness of the insulator 270 in a region overlapping with the conductor 241, the thickness of the conductor 262, and the thickness of the insulator 272 in the region overlapping with the conductor 262 are preferably adjusted. For example, when the thicknesses of the insulator 270 and the insulator 272 are made small, the transistor 32 having a short channel length can be manufactured.

In the above structure, the channel width of the transistor 32 is the length of a region where the insulator 250 and the metal oxide 230 are in contact with each other in the top view, and is also the length of the outline (outer periphery) of the metal oxide 230 in the top view. In other words, the channel width of the transistor 32 can be adjusted by the size (also referred to as diameter) of the opening provided in the insulator 270 in the top view. For example, when the diameter of the opening is made large, the transistor 32 can have a large channel width.

The transistor 32 has a structure in which the channel formation region is surrounded by the gate electrode. Thus, the transistor 32 can be referred to as a transistor having a GAA (Gate-All-Around) structure.

Although FIG. 20D illustrates a structure where the top surface of the opening of the conductor 262 has a circular shape, the present invention is not limited thereto. For example, the top surface of the opening included in the conductor 262 may have an oval shape, a polygonal shape, or a polygonal shape with rounded corners.

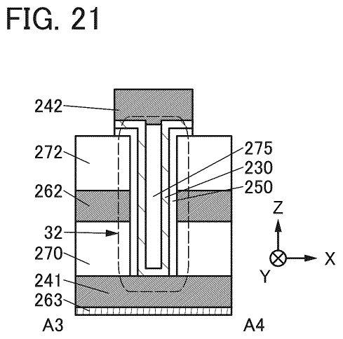

As illustrated in FIG. 20B and FIG. 20C, the top surface of the metal oxide 230 is aligned with the top surfaces of the insulator 272, the insulator 250, and the insulator 275. Note that the present invention is not limited thereto. For example, as illustrated in FIG. 21, the insulator 250 may be in contact with part of the top surface of the insulator 272, and the metal oxide 230 may be in contact with the top surface of the insulator 250. At this time, the insulator 250 is not in contact with the conductor 242. With this structure, a contact area between the metal oxide 230 and the conductor 242 can be increased, so that the on-state current of the transistor 32 can be increased. Note that an end portion of the metal oxide 230 is preferably aligned with an end portion of the insulator 250 above the insulator 272.

The conductor 242 includes a region in contact with at least the metal oxide 230. In FIG. 20B and FIG. 20C, the conductor 242 includes a region in contact with each of the top surfaces of the insulator 272, the insulator 250, the metal oxide 230, and the insulator 275. Note that the present invention is not limited thereto. For example, as illustrated in FIG. 21, the conductor 242 may include a region in contact with the side surface of the metal oxide 230 in a region overlapping with the insulator 275. With this structure, a contact area between the metal oxide 230 and the conductor 242 can be increased, so that the on-state current of the transistor 31 can be increased.

FIG. 20B and FIG. 20C illustrate a structure where the conductor 241 does not include a concave portion in a region overlapping with the opening included in the insulator 270. Note that there is no particular limitation on the shape of the conductor 241 as long as the conductor 241 and the metal oxide 230 are in contact with each other in the region overlapping with the opening. For example, as in FIG. 6A, the conductor 241 may include a concave portion in the region overlapping with the opening. In other words, part of the top surface of the conductor 241 which overlaps with the opening may be removed.

The above is the description of the transistor 32.

As in the structure illustrated in FIG. 16B, the semiconductor device 10F may have a structure where the insulator 212 is not necessarily included. At this time, the insulator 263 includes the region in contact with the top surface and the side surface of the conductor 264 and the top surface of the insulator 210. Accordingly, the number of steps in the manufacturing process of the semiconductor device can be reduced.

In the structure where the insulator 212 is not provided, the conductor 241A and the conductor 241B are provided over the insulator 263. That is, it can be said that the conductor 241B is provided in the same layer as the conductor 241A. At this time, the height (depth) of the opening provided in the insulator 272, the conductor 262B, and the insulator 270 is larger (deeper) than the height (depth) of the opening provided in the insulator 272, the conductor 262A, and the insulator 270. That is, the channel length of the transistor 32B is longer than the channel length of the transistor 32A. Accordingly, the area occupied by the capacitor 42 can be reduced, and the memory cell can be miniaturized or highly integrated. In addition, a memory cell with high reading accuracy can be obtained. In addition, a memory cell with high writing speed and high reading accuracy can be achieved.

Note that in the structure where the insulator 212 is not provided, the channel length of the transistor 32B is longer than the channel length of the transistor 32A; thus, the semiconductor device 10F is preferably manufactured with adjusted channel widths of the transistor 32A and the transistor 32B. For example, when the diameter of the opening in which the metal oxide 230 and the insulator 250 are provided is increased in the transistor 32B functioning as a reading transistor, a memory cell with high reading accuracy and high reading speed can be achieved. At this time, the channel width of the transistor 32B is larger than the channel width of the transistor 32A. In other words, the diameter of the opening included in the conductor 262B is larger than the diameter of the opening included in the conductor 262A.

For example, as in the structure illustrated in FIG. 9A, a plurality of memory cells 22 may be arranged in the X direction to form the memory cell array, or as in the structure illustrated in FIG. 9B, the plurality of memory cells 22 may be arranged in the X direction and the Y direction to form the memory cell array. A plurality of layers including the memory cells 22 or the memory cell array may be stacked.

As described in [Variation example 1-1] above, two adjacent memory cells 22 may share a write bit line; as described in [Variation example 1-2] above, two adjacent memory cells 22 may share a read bit line; or as described in [Variation example 1-3] above, two stacked memory cells 22 may share a write bit line and a read bit line.

### <Structure Example 5 of Semiconductor Device>

An example of a semiconductor device different from the above-described semiconductor device is described below. Note that in the semiconductor device illustrated below, components having the same functions as the components included in the semiconductor device described above are denoted by the same reference numerals. Differences from the semiconductor device described above will be mainly described below, and common portions are not described.

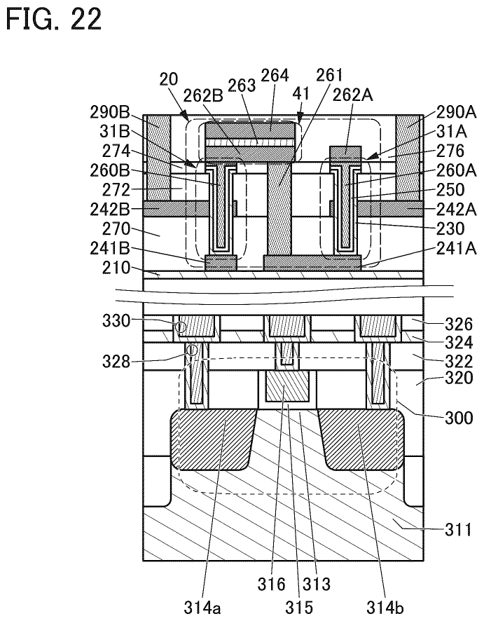

FIG. 22 is a cross-sectional view illustrating a structure example of a semiconductor device of one embodiment of the present invention. The semiconductor device illustrated in FIG. 22 is an example in which a layer including a transistor 300 is provided under the structure illustrated in FIG. 1B, for example. The transistor 300 can be provided in a driver circuit of a memory cell formed above the insulator 210, for example. Note that the structure of the layer above the insulator 210 in FIG. 22 is similar to that in FIG. 1B; thus, the detailed description thereof is omitted.

FIG. 22 illustrates an example of the transistor 300. The transistor 300 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 300 may be a p-channel transistor or an n-channel transistor. As the substrate 311, a single crystal silicon substrate can be used, for example.

Here, in the transistor 300 illustrated in FIG. 22, the semiconductor region 313 (part of the substrate 311) in which a channel is formed has a protruding shape. The conductor 316 is provided to cover the side surface and the top surface of the semiconductor region 313 with the insulator 315 therebetween. Note that a material for adjusting the work function may be used as the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon on Insulator) substrate.

Note that the transistor 300 illustrated in FIG. 22 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 300 as an interlayer film. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as the interlayer film may also function as a planarization film that covers an uneven shape thereunder. For example, the top surface of the insulator 322 may be planarized by planarization treatment using a CMP method or the like to have improved planarity.

This embodiment can be combined with the other embodiments as appropriate. In this specification, in the case where a plurality of structure examples are illustrated in one embodiment, the structure examples can be combined as appropriate.

### Embodiment 2

In this embodiment, a memory device of one embodiment of the present invention will be described with reference to drawings.

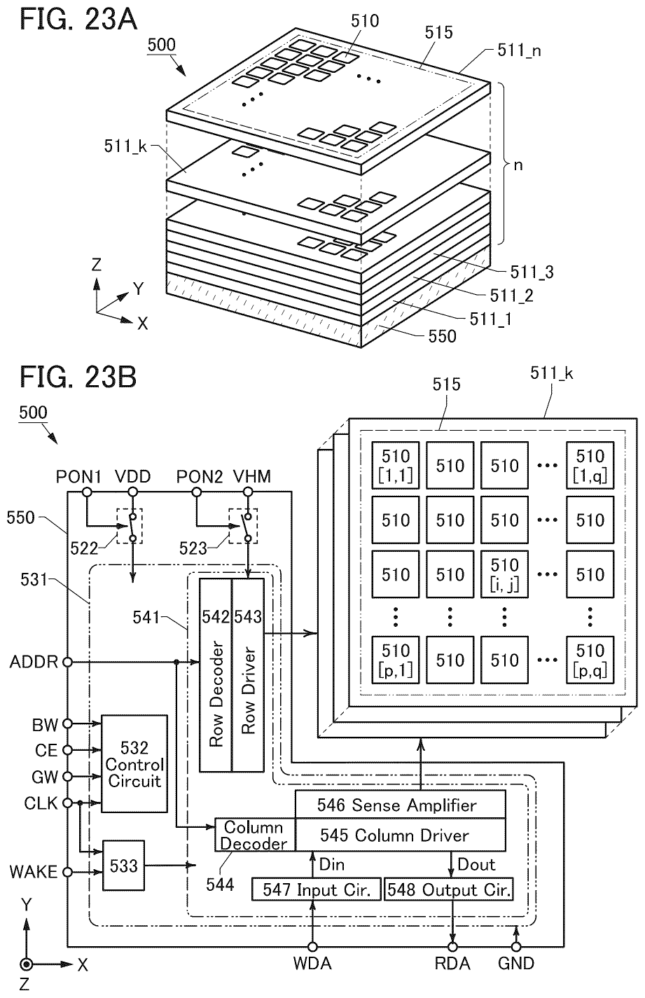

FIG. 23A is a schematic perspective view of a memory device of one embodiment of the present invention. FIG. 23B is a block diagram of a memory device of one embodiment of the present invention.

A memory device 500 illustrated in FIG. 23A and FIG. 23B includes a driver circuit layer 550 and n memory layers 511 (n is an integer greater than or equal to 1). The memory layers 511 each include a memory cell array 515. The memory cell array 515 includes a plurality of memory cells 510.

The n memory layers 511 are provided over the driver circuit layer 550. Provision of the n memory layers 511 over the driver circuit layer 550 can reduce the area occupied by the memory device 500. Furthermore, memory capacity per unit area can be increased.

In this embodiment, the first memory layer 511 is denoted by a memory layer 511_1, the second memory layer 511 is denoted by a memory layer 511_2, and the third memory layer 511 is denoted by a memory layer 511_3. Furthermore, the k-th (k is an integer greater than or equal to 1 and less than or equal to n) memory layer 511 is denoted by a memory layer 511_k, and the n-th memory layer 511 is denoted by a memory layer 511_n. Note that in this embodiment and the like, the simple term “memory layer 511” is sometimes used in the case of describing matters related to all the n memory layers 511 or matters common to the n memory layers 511.

### <Structure Example of Driver Circuit Layer 550>

The driver circuit layer 550 includes a PSW 522 (power switch), a PSW 523, and a peripheral circuit 531. The peripheral circuit 531 includes a peripheral circuit 541, a control circuit 532, and a voltage generation circuit 533.

In the memory device 500, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 532.

The control circuit 532 is a logic circuit having a function of controlling the entire operation of the storage device 500. For example, the control circuit performs a logical operation on the signal CE, the signal GW, and the signal BW to determine an operation mode (e.g., a writing operation or a reading operation) of the memory device 500. Alternatively, the control circuit 532 generates a control signal for the peripheral circuit 541 so that the operation mode is executed.

The voltage generation circuit 533 has a function of generating a negative voltage. The signal WAKE has a function of controlling the input of the signal CLK to the voltage generation circuit 533. For example, when an H-level signal is supplied as the signal WAKE, the signal CLK is input to the voltage generation circuit 533 and the voltage generation circuit 533 generates a negative voltage.

The peripheral circuit 541 is a circuit for writing and reading data to/from the memory cells 510. The peripheral circuit 541 includes a row decoder 542, a column decoder 544, a row driver 543, a column driver 545, an input circuit 547 (Input Cir.), an output circuit 548 (Output Cir.), and a sense amplifier 546.

The row decoder 542 and the column decoder 544 have a function of decoding the signal ADDR. The row decoder 542 is a circuit for specifying a row to be accessed, and the column decoder 544 is a circuit for specifying a column to be accessed. The row driver 543 has a function of selecting a wiring WWL (write word line) specified by the row decoder 542. The column driver 545 has a function of writing data to the memory cells 510, a function of reading data from the memory cells 510, a function of retaining the read data, and the like. The column driver 545 has a function of selecting a wiring WBL (write bit line) or a wiring RBL (read bit line) specified by the column decoder 544.

The input circuit 547 has a function of retaining the signal WDA. Data retained by the input circuit 547 is output to the column driver 545. Data output from the input circuit 547 is data (Din) to be written to the memory cells 510. Data (Dout) read from the memory cells 510 by the column driver 545 is output to the output circuit 548. The output circuit 548 has a function of retaining Dout. In addition, the output circuit 548 has a function of outputting Dout to the outside of the memory device 500. Data output from the output circuit 548 is the signal RDA.

The PSW 522 has a function of controlling supply of VDD to the peripheral circuit 531. The PSW 523 has a function of controlling supply of VHM to the row driver 543. Here, in the memory device 500, a high power supply voltage is VDD and a low power supply voltage is GND (a ground potential). In addition, VHM is a high power supply voltage used to set a word line at a high level and is higher than VDD. The on/off of the PSW 522 is controlled by the signal PON1, and the on/off of the PSW 523 is controlled by the signal PON2. The number of power domains to which VDD is supplied is one in the peripheral circuit 531 in FIG. 23B but can be more than one. In that case, a power switch is provided for each power domain.

### <Structure Example of Memory Layer 511>

A structure example of the n memory layers 511 is described. Each of the n memory layers 511 includes the memory cell array 515. The memory cell array 515 includes the plurality of memory cells 510. FIG. 23A and FIG. 23B illustrate an example in which the memory cell array 515 includes the plurality of memory cells 510 arranged in a matrix of p rows and q columns (each of p and q is independently an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 23B, the memory cell 510 provided in the first row and the first column is referred to as a memory cell 510[1,1], and the memory cell 510 provided in the p-th row and the q-th column is referred to as a memory cell 510[p,q]. The memory cell 510 provided in the i-th row and the j-th column (i is an integer greater than or equal to 1 and less than or equal to p, and j is an integer greater than or equal to 1 and less than or equal to q) is referred to as a memory cell 510[i,j].

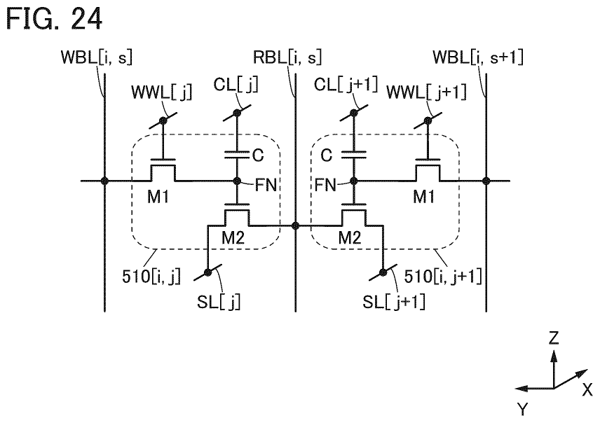

FIG. 24 illustrates a circuit structure example of the memory cell. Embodiment 1 can be referred to for a cross-sectional structure example of the memory cell 510 corresponding to the circuit configuration.

The memory cell 510 includes a transistor M1, a transistor M2, and a capacitor C. A memory cell composed of two transistors and one capacitor is also referred to as a 2Tr1C memory cell. Thus, the memory cell 510 illustrated in this embodiment is a 2Tr1C memory cell.

The transistor M1 corresponds to the transistor 31A or the transistor 32A described in Embodiment 1. The transistor M2 corresponds to the transistor 31B or the transistor 32B described in Embodiment 1. The capacitor C corresponds to the capacitor 41 or the capacitor 42 described in Embodiment 1. The wiring WBL corresponds to the conductor 290A described in Embodiment 1. The wiring RBL corresponds to the conductor 290B described in Embodiment 1. The wiring WWL corresponds to the conductor 262A described in Embodiment 1. The wiring CL corresponds to the conductor 264 described in Embodiment 1. The wiring SL corresponds to the conductor 241B described in Embodiment 1.

In the memory cell 510[i,j], a gate of the transistor M1 is electrically connected to a wiring WWL[j], one of a source and a drain of the transistor M1 is electrically connected to one electrode of the capacitor C, and the other of the source and the drain of the transistor M1 is electrically connected to a wiring WBL[i,s]. Note that FIG. 24 illustrates a structure example in which part of the wiring WWL[j] functions as the gate of the transistor M1. The other electrode of the capacitor C is electrically connected to a wiring CL[j]. Note that FIG. 24 illustrates a structure example in which part of the wiring CL[j] functions as the other electrode of the capacitor C, for example. A gate of the transistor M2 is electrically connected to the one electrode of the capacitor C, one of a source and a drain of the transistor M2 is electrically connected to a wiring SL[j], and the other of the source and the drain of the transistor M2 is electrically connected to a wiring RBL[i,s].

In the memory cell 510[i,j], a region where the one electrode of the capacitor C, the other of the source and the drain of the transistor M1, and the gate of the transistor M2 are electrically connected to one another and always have the same potential is referred to as a “node FN”.

In a memory cell 510[i,j+1] a gate of the transistor M1 is electrically connected to a wiring WWL[j+1], one of a source and a drain of the transistor M1 is electrically connected to one electrode of the capacitor C, and the other of the source and the drain of the transistor M1 is electrically connected to a wiring WBL[i,s+1]. FIG. 24 illustrates a structure example in which part of the wiring WWL[j+1] functions as the gate of the transistor M1. The other electrode of the capacitor Cis electrically connected to a wiring [j+1]. Note that FIG. 24 illustrates a structure example in which part of a wiring CL[j+1] functions as the other electrode of the capacitor C, for example. A gate of the transistor M2 is electrically connected to the one electrode of the capacitor C, one of a source and a drain of the transistor M2 is electrically connected to a wiring SL[j+1], and the other of the source and the drain of the transistor M2 is electrically connected to the wiring RBL[i,s].

In the memory cell 510[i,j+1], a region where the one electrode of the capacitor C, one of the source and the drain of the transistor M1, and the gate of the transistor M2 are electrically connected to one another and always have the same potential is referred to as the node FN.

Thus, the wiring RBL[i,s] is electrically connected to the other of the source and the drain of the transistor M2 included in the memory cell 510[i,j] and other of the source and the drain of the transistor M2 included in the memory cell 510[i,j+1]. Accordingly, the wiring RBL[i,s] is shared by the memory cell 510[i,j] and the memory cell 510[i,j+1]. Accordingly, the wiring WBL[i,s] is shared by a memory cell 510[i,j−1] (not illustrated) and the memory cell 510[i,j]. Specifically, the wiring WBL[i,s] is electrically connected to the other of the source and the drain of the transistor M1 included in the memory cell 510[i,j−1] and the other of the source and the drain of the transistor M1 included in the memory cell 510[i,j].

Accordingly, there is a following relation between j and s indicating the positions of the columns. When j is an even number, s is an integer j/2 and is greater than or equal to 1 and less than or equal to q/2. When j is an odd number, s is an integer (j+1)/2 and is greater than or equal to 1 and less than or equal to (q+1)/2.

As a semiconductor layer in which the channel of each of the transistor M1 and the transistor M2 is formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, an oxide semiconductor, or a nitride semiconductor may be used.

Note that each of the transistor M1 and the transistor M2 is preferably a transistor using an oxide semiconductor, which is a kind of metal oxide, in a semiconductor layer in which a channel is formed (also referred to as an “OS transistor”). An oxide semiconductor has a band gap of 2 eV or more and thus has an extremely low off-state current. Thus, the power consumption of the memory cells 510 can be reduced. Accordingly, the power consumption of the memory device 500 including the memory cells 510 can be reduced.

A memory cell including an OS transistor can be referred to as an “OS memory”. The memory device 500 including the memory cell can also be referred to as an “OS memory”.

The OS transistor operates stably even in a high-temperature environment and has a small variation in electrical characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment. Thus, the OS memory can operate stably and have high reliability even in the high-temperature environment.

### <Operation Example of Memory Cell 510>

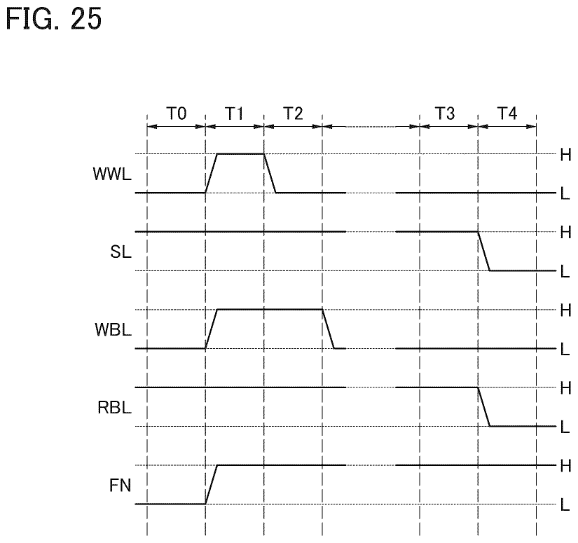

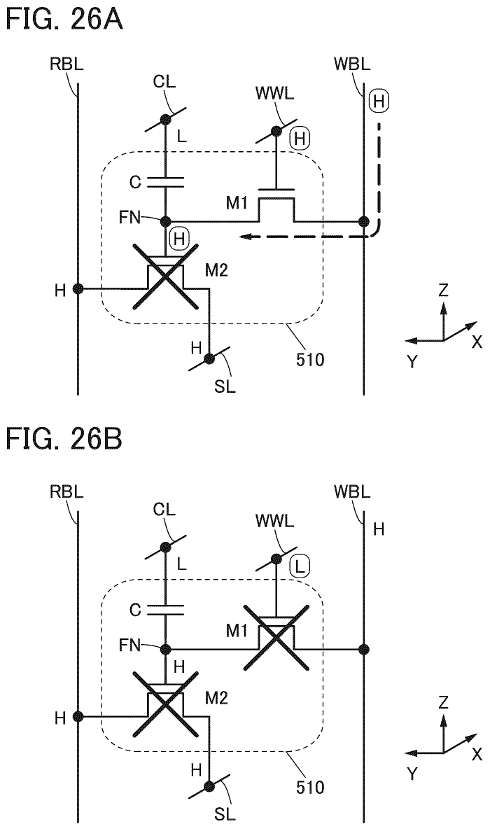

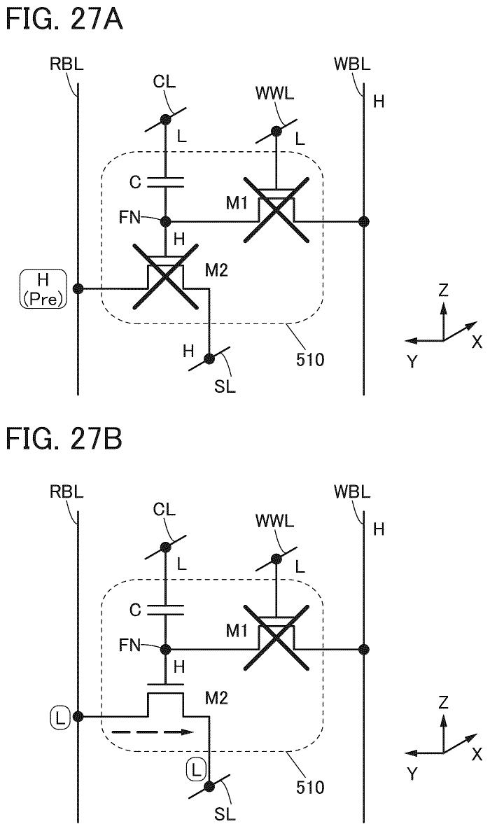

Data writing and reading operation examples of the memory cell 510 will be described. In this embodiment, normally-off n-channel transistors are used as the transistor M1 and the transistor M2. FIG. 25 is a timing chart for describing an operation example of the memory cell 510. FIG. 26A to FIG. 27B are circuit diagrams for describing an operation example of the memory cell 510.

In the following drawings and the like, for showing the potentials of a wiring and an electrode, “H” representing a potential H or “L” representing a potential L is sometimes written near the wiring and the electrode. In addition, enclosed “H” or “L” is sometimes written near a wiring or an electrode whose potential changes. Moreover, in the case where a transistor is in an off state, a symbol “x” is sometimes written on the transistor.

When the potential H is supplied to a gate of an n-channel transistor, the transistor is turned on. When the potential L is supplied to a gate of an n-channel transistor, the transistor is turned off. Thus, the potential His a potential higher than the potential L. The potential H may be a potential equal to the high power supply potential VDD. The potential L is a potential lower than the potential H. The potential L may be a potential equal to the ground potential GND.

First, in Period TO, the potentials of the wiring WWL, the wiring WBL, and the node FN are the potential L, and the wiring SL and the wiring RBL are set to the potential H (FIG. 25).

### [Data Writing Operation]

In Period T1, the potential H is supplied to the wiring WWL and the wiring WBL. Accordingly, the transistor M1 is brought into an on state and the potential His written to the node FN as data including “1”. More accurately, the amount of charge that makes the potential of the node FN be the potential H is supplied to the node FN (FIG. 25 and FIG. 26A).

Since all of the gate, source, and drain of the transistor M2 have the potential H, the transistor M2 is brought into an off state.

### [Retention Operation]

In Period T2, the potential L is supplied to the wiring WWL. Then, the transistor M1 is brought into an off state and the node FN is brought into a floating state. Thus, data (potential H) written to the node FN is retained (FIG. 25 and FIG. 26B).

As described above, the OS transistor is a transistor having an extremely low off-state current. The use of the OS transistor as the transistor M1 enables data written to the node FN to be retained for a long period. Thus, it becomes unnecessary to refresh the potential of the node FN and the power consumption of the memory cell 510 can be reduced. Thus, the power consumption of the memory device 500 can be reduced.

In addition, the OS transistor has a higher withstand voltage between a source and a drain than a transistor whose channel formation region includes silicon (also referred to as a Si transistor). When the OS transistor is used as the transistor M1, a higher potential can be supplied to the node FN. This increases the range of a potential retained at the node FN. An increase in the range of the potential retained at the node FN makes it easy to retain multilevel data or to retain analog data.

### [Reading Operation]

In Period T3, the potential His precharged (Pre) to the wiring RBL. That is, the potential of the wiring RBL is set to the potential H and then the wiring RBL is brought into a floating state (FIG. 25 and FIG. 27A).

Next, in Period T4, a potential L is supplied to the wiring SL. At this time, it the case where the potential of the node FN is the potential H, the transistor M2 is brought into an on state; thus, electrical continuity is established between the wiring RBL and the wiring SL through the transistor M2. When electrical continuity is established between the wiring RBL and the wiring SL, the potential of the wiring RBL, which is in a floating state, changes from the potential H to the potential L (FIG. 25 and FIG. 27B).

Note that the transistor M2 is in an off state in the case where the potential L is written to the node FN as data indicating “0”.

By detecting a change in the potential of the wiring RBL at the time of supplying the potential L to the wiring SL in this manner, data written to the memory cell 510 can be read.

The memory cell 510 using the OS transistor employs a method in which charge is written to the node FN through the OS transistor; hence, a high voltage, which is required for a conventional flash memory, is unnecessary and a high-speed writing operation is possible. Furthermore, unlike in a flash memory, the number of times of data writing and reading in the memory cell 510 using the OS transistor is substantially unlimited because charge injection and extraction into/from a floating gate or a charge-trap layer are not performed. Unlike in a flash memory, unstableness due to an increase of electron trap centers is not observed in the memory cell 510 using the OS transistor even when a rewriting operation is repeated. The memory cell 510 using the OS transistor is less likely to degrade than a conventional flash memory and can have high reliability.

Unlike a magnetic memory, a resistive random access memory, or the like, the memory cell 510 using the OS transistor has no change in the structure at the atomic level. Thus, the memory cell 510 using the OS transistor has higher rewrite endurance than a magnetic memory and a resistive random access memory.

### <Structure Example of Sense Amplifier 546>

Next, a structure example of the sense amplifier 546 will be described. Specifically, a structure example of a write read circuit that includes the sense amplifier 546 and performs writing or reading of a data signal will be described.

FIG. 28 is a circuit diagram illustrating a structure example of a circuit 600 that includes the sense amplifier 546 and performs writing or reading of a data signal. The circuit 600 is provided for every wiring WBL and every wiring RBL.

The circuit 600 includes a transistor 661 to a transistor 666, the sense amplifier 546, an AND circuit 652, an analog switch 653, and an analog switch 654.

The circuit 600 operates in accordance with a signal SEN, a signal SEP, a signal BPR, a signal RSEL, a signal WSEL, a signal GRSEL, and a signal GWSEL.

Data DIN input to the circuit 600 is written to the memory cell 510 through the wiring WBL electrically connected to a node NS through the AND circuit 652. Data DOUT written to the memory cell 510 is transmitted to the wiring RBL electrically connected to a node NSB through the analog switch 653 and output from the circuit 600 as the data DOUT.

Note that the data DIN and the data DOUT are internal signals and respectively correspond to the signal WDA and the signal RDA.

The transistor 661 is included in a precharge circuit. The wiring RBL is precharged to a precharge potential Vpre by the transistor 661. Note that in this embodiment, the case where a potential Vdd (high level) is used as the precharge potential Vpre will be described (denoted by Vdd (Vpre) in FIG. 28). The signal BPR is a precharge signal, and the conduction state of the transistor 661 is controlled by the signal BPR.

In a reading operation, the sense amplifier 546 determines whether data input to the wiring RBL is at a high level or a low level. In a writing operation, the sense amplifier 546 functions as a latch circuit that temporarily retains the data DIN input to the circuit 600.

The sense amplifier 546 illustrated in FIG. 28 is a latch sense amplifier. The sense amplifier 546 includes two inverter circuits, and an input node of one of the inverter circuits is connected to an output node of the other of the inverter circuits. When the input node of the one of the inverter circuits is the node NS and the output node is the node NSB, complementary data is retained at the node NS and the node NSB.

The signal SEN and the signal SEP are each a sense amplifier enable signal for activating the sense amplifier 546, and a reference potential Vref is a read judge potential. The sense amplifier 546 determines whether the potential of the node NSB at the time of the activation is at a high level or a low level on the basis of the reference potential Vref.

The AND circuit 652 controls electrical continuity between the node NS and the wiring WBL. The analog switch 653 controls electrical continuity between the node NSB and the wiring RBL. The analog switch 654 controls electrical continuity between the node NS and a wiring supplying the reference potential Vref.

In data reading, the potential of the wiring RBL is transmitted to the node NSB by the analog switch 653. When the potential of the wiring RBL is lower than the reference potential Vref, the sense amplifier 546 determines that the wiring RBL is at a low level. The sense amplifier 546 determines that the wiring RBL is at a high level when the potential of the wiring RBL does not become lower than the reference potential Vref.

The signal WSEL is a write selection signal and controls the AND circuit 652. The signal RSEL is a read selection signal and controls the analog switch 653 and the analog switch 654.

The transistor 662 and the transistor 663 are included in an output MUX (multiplexer) circuit. The signal GRSEL is a global read selection signal and controls the output MUX circuit. The output MUX circuit has a function of selecting the wiring RBL from which data is to be read.

The output MUX circuit has a function of outputting the data DOUT read from the sense amplifier 546.

The transistor 664 to the transistor 666 are included in a write driver circuit. The signal GWSEL is a global write selection signal and controls the write driver circuit. The write driver circuit has a function of writing the data DIN to the sense amplifier 546.

The write driver circuit has a function of selecting a column to which the data DIN is to be written. The write driver circuit writes data in byte units, half-word units, or word units in response to the signal GWSEL.

In a gain-cell memory cell, at least two transistors are required for one memory cell, which makes it difficult to increase the number of memory cells that can be placed per unit area. However, when an OS transistor is used as a transistor included in the memory cell 510, the plurality of memory cell arrays 515 can be stacked. That is, the amount of data that can be stored per unit area can be increased. A gain-cell memory cell can operate as a memory by amplifying accumulated charge by the closest transistor even when the capacitance of accumulated charge is small. When an OS transistor with an extremely low off-state current is used as a transistor included in the memory cell 510, the capacitance of the capacitor can be made small. Furthermore, one or both of the gate capacitance of a transistor and the parasitic capacitance of a wiring can be used as the capacitor, so that the capacitor can be omitted. That is, the area of the memory cell 510 can be made small.

This embodiment can be combined with any of the other embodiments as appropriate.

### Embodiment 3

In this embodiment, an example of a chip on which the memory device of one embodiment of the present invention is mounted will be described with reference to drawings.

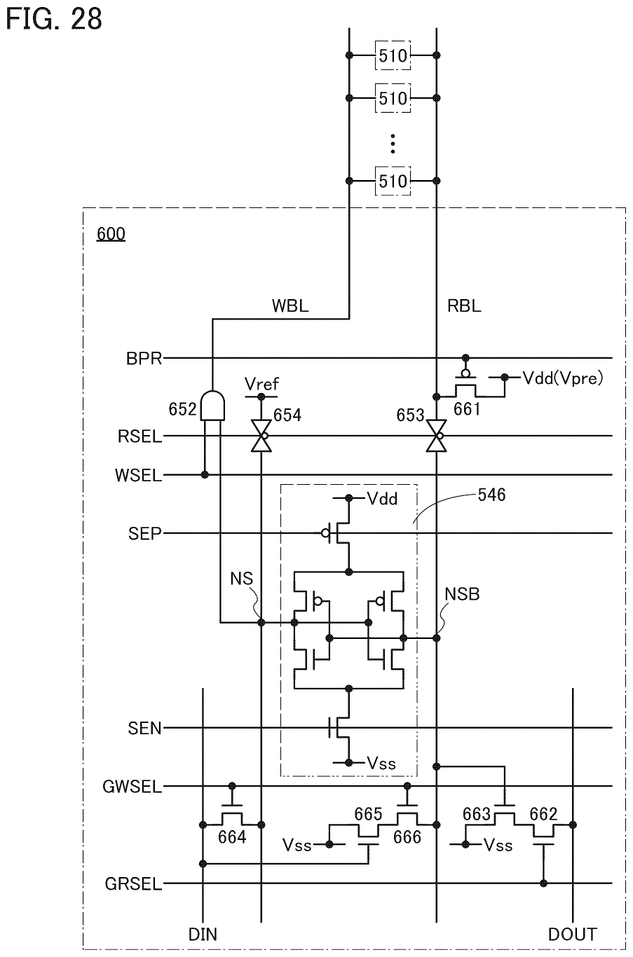

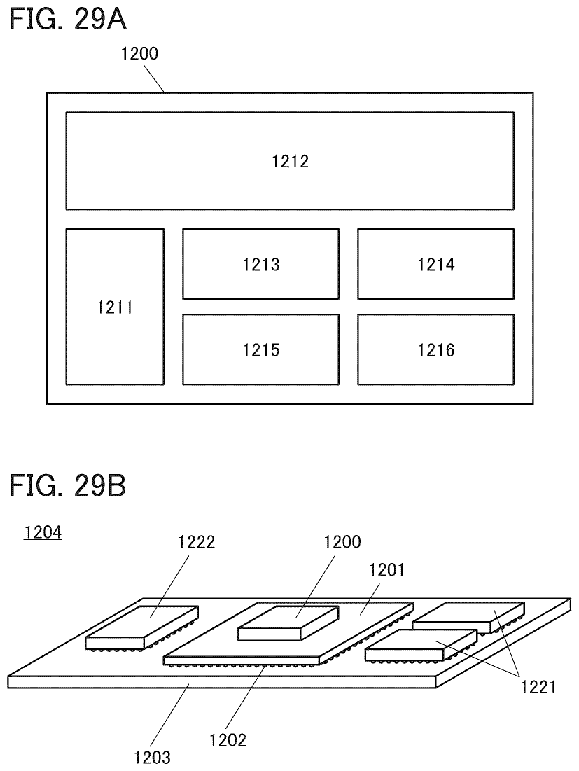

A plurality of circuits (systems) are mounted on a chip 1200 illustrated in FIG. 29A and FIG. 29B. A technique for integrating a plurality of circuits (systems) into one chip is referred to as system on chip (SoC) in some cases.

As illustrated in FIG. 29A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 29B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Memory devices such as DRAMs 1221 and a flash memory 1222 may be provided over the motherboard 1203. For example, the NOSRAM described in the above embodiment can be used as the DRAM 1221. This can make the DRAM 1221 have low power consumption, operate at high speed, and have a large capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM described above can be used as the memory. Moreover, the GPU 1212 is suitable for parallel computation of a large amount of data and thus can be used for image processing or a product-sum operation. When an image processing circuit or a product-sum operation circuit using an OS transistor is provided in the GPU 1212, image processing or a product-sum operation can be performed with low power consumption.

In addition, since the CPU 1211 and the GPU 1212 are provided on the same chip, a wiring between the CPU 1211 and the GPU 1212 can be shortened, and data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at a high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with any of the other embodiments as appropriate.

### Embodiment 4

In this embodiment, examples of electronic components incorporating the memory device of one embodiment of the present invention are described.

### [Electronic Component]

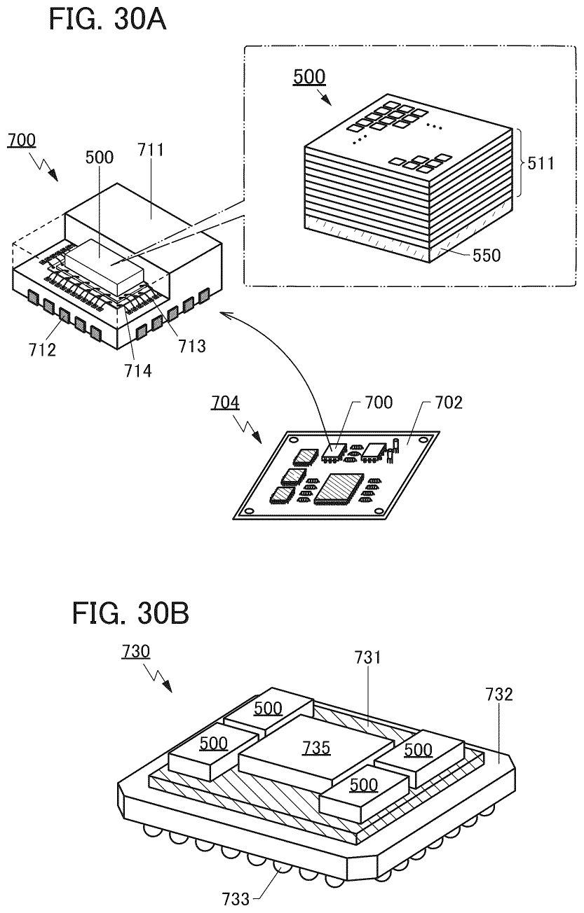

FIG. 30A is a perspective view of an electronic component 700 and a substrate (circuit board 704) on which the electronic component 700 is mounted. The electronic component 700 illustrated in FIG. 30A includes the memory device 500 that is the memory device of one embodiment of the present invention in a mold 711. FIG. 30A omits part of the electronic component to illustrate the inside of the electronic component 700. The electronic component 700 includes a land 712 outside the mold 711. The land 712 is electrically connected to an electrode pad 713, and the electrode pad 713 is electrically connected to the memory device 500 through a wire 714. The electronic component 700 is mounted on a printed circuit board 702, for example. A plurality of such electronic components are combined and electrically connected to each other on the printed circuit board 702, so that the circuit board 704 is completed.

As described in the above embodiment, the memory device 500 includes the driver circuit layer 550 and the memory layers 511 (each including the memory cell array 515).

FIG. 30B is a perspective view of an electronic component 730. The electronic component 730 is an example of a SiP (System in package) or an MCM (Multi Chip Module). In the electronic component 730, an interposer 731 is provided over a package substrate 732 (printed circuit board), and a semiconductor device 735 and a plurality of the memory devices 500 are provided over the interposer 731.

The electronic component 730 using the memory devices 500 as high bandwidth memory (HBM) is illustrated as an example. An integrated circuit (a semiconductor device) such as a CPU, a GPU, or an FPGA (Field Programmable Gate Array) can be used as the semiconductor device 735.

As the package substrate 732, for example, a ceramic substrate, a plastic substrate, or a glass epoxy substrate can be used. As the interposer 731, for example, a silicon interposer or a resin interposer can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided over the interposer 731 to an electrode provided over the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Moreover, since wirings of a silicon interposer can be formed through a semiconductor process, formation of minute wirings, which is difficult for a resin interposer, is easily achieved.

In order to achieve a wide memory bandwidth, many wirings need to be connected to an HBM. Therefore, formation of minute and high-density wirings is required for an interposer on which an HBM is mounted. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, so that a poor connection between the silicon interposer and an integrated circuit provided over the silicon interposer is less likely to occur. It is particularly preferable to use a silicon interposer for a 2.5D package (2.5-dimensional mounting) in which a plurality of integrated circuits are arranged side by side over the interposer.

A heat sink (radiator plate) may be provided to overlap with the electronic component 730. In the case of providing a heat sink, the heights of integrated circuits provided over the interposer 731 are preferably the same. In the electronic component 730 described in this embodiment, the heights of the memory devices 500 and the semiconductor device 735 are preferably the same, for example.

An electrode 733 may be provided on the bottom portion of the package substrate 732 to mount the electronic component 730 on another substrate. FIG. 30B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

This embodiment can be combined with the other embodiments as appropriate.

### Embodiment 5

In this embodiment, application examples of the memory device of one embodiment of the present invention will be described.

The memory device of one embodiment of the present invention can be used as memory devices of a variety of electronic devices (e.g., information terminals, computers, smartphones, e-book readers, digital still cameras, video cameras, video recording/reproducing devices, navigation systems, and game machines). The memory device can also be used for image sensors, IoT (Internet of Things), healthcare-related devices, and the like. Note that here, the computers refer not only to tablet computers, laptop computers, and desktop computers, but also to large computers such as server systems.

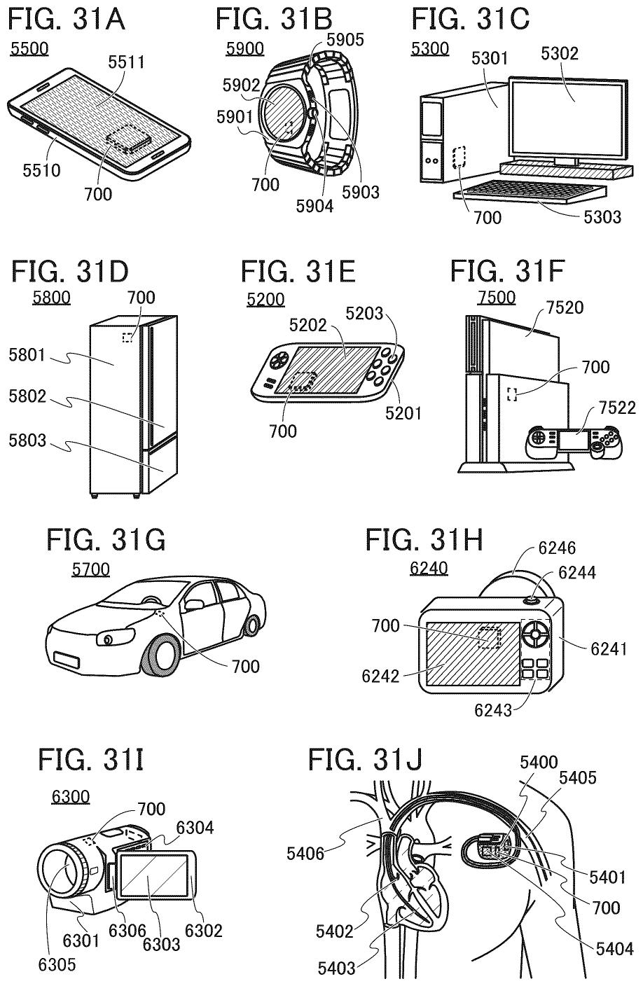

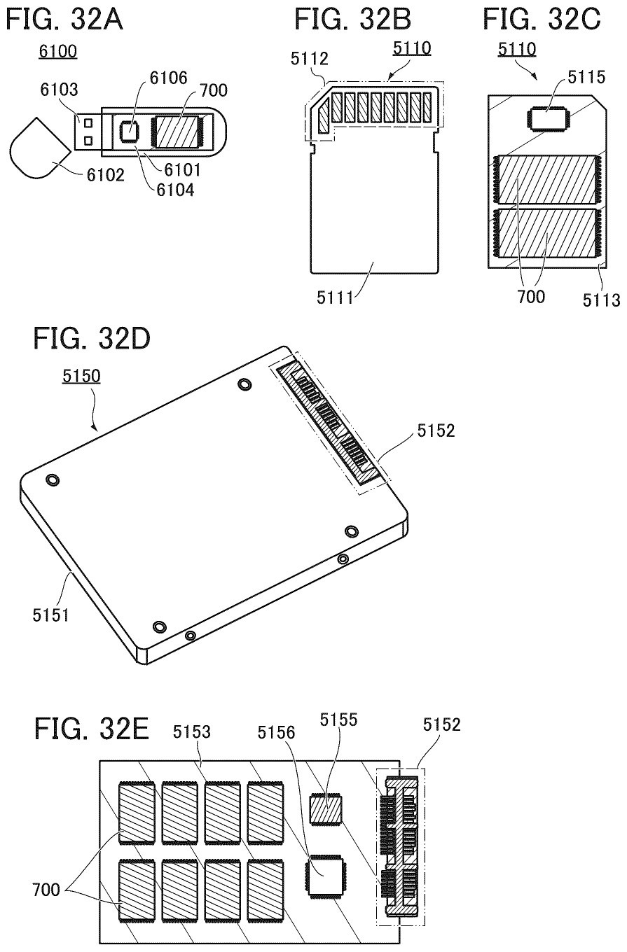

Examples of an electronic device including the memory device of one embodiment of the present invention will be described. Note that FIG. 31A to FIG. 31J and FIG. 32A to FIG. 32E each illustrate a state where the electronic component 700 or the electronic component 730 that includes the memory device described in the above embodiments is included in an electronic device.

### [Mobile Phone]

An information terminal 5500 illustrated in FIG. 31A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device of one embodiment of the present invention, the information terminal 5500 can retain a temporary file generated at the time of executing an application (e.g., a web browser's cache).

### [Wearable Terminal]

FIG. 31B illustrates an information terminal 5900 as an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by using the memory device of one embodiment of the present invention.

### [Information Terminal]

FIG. 31C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by using the memory device of one embodiment of the present invention.

FIG. 31A to FIG. 31C illustrate the smartphone, the wearable terminal, and the desktop information terminal as electronic devices, and examples of other information terminals include a PDA (Personal Digital Assistant), a laptop information terminal, and a workstation.

### [Household Appliance]

FIG. 31D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device of one embodiment of the present invention can be used in the electric refrigerator-freezer 5800. The electric refrigerator-freezer 5800 can transmit and receive information on food stored in the electric refrigerator-freezer 5800 and food expiration dates, for example, to and from an information terminal via the Internet. In the electric refrigerator-freezer 5800, the memory device of one embodiment of the present invention can retain a temporary file generated at the time of transmitting the information.

FIG. 31D illustrates the electric refrigerator-freezer as a household appliance, and examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 31E illustrates a portable game machine 5200 as an example of a game machine. The portable game machine 5200 includes a housing 5201, a display portion 5202, a button 5203, and the like.

FIG. 31F illustrates a stationary game machine 7500 as an example of a game machine. The stationary game machine 7500 can be especially referred to as a home-use stationary game machine. The stationary game machine 7500 includes a main body 7520 and a controller 7522. Note that the controller 7522 can be connected to the main body 7520 with or without a wire. Although not illustrated in FIG. 31F, the controller 7522 can include a display portion that displays a game image, and an input interface besides the button, such as a touch panel, a stick, a rotating knob, and a sliding knob. The shape of the controller 7522 is not limited to that illustrated in FIG. 31F, and the shape of the controller 7522 may be changed in various ways in accordance with the genres of games. For example, for a shooting game such as an FPS (First Person Shooter) game, a gun-shaped controller having a trigger button can be used. For another example, for a music game, a controller having a shape of a musical instrument, audio equipment, or the like can be used. Furthermore, the stationary game machine may include one or more of a camera, a depth sensor, and a microphone so that the game player can play a game using a gesture or a voice instead of a controller.

Videos displayed on the game machine can be output with a display device such as a television device, a personal computer display, a game display, or a head-mounted display.

By using the memory device of one embodiment of the present invention in the portable game machine 5200 or the stationary game machine 7500, power consumption can be reduced. Moreover, heat generation from a circuit can be reduced owing to low power consumption; thus, the influence of heat generation on the circuit itself, a peripheral circuit, and a module can be reduced.

Moreover, by using the memory device of one embodiment of the present invention, the portable game machine 5200 or the stationary game machine 7500 can retain a temporary file or the like necessary for an arithmetic operation that occurs during game play.

FIG. 31E and FIG. 31F illustrate the portable game machine and the home-use stationary game machine as examples of game machines, and examples of other game machines include an arcade game machine installed in an entertainment facility (e.g., a game center and an amusement park) and a throwing machine for batting practice, installed in sports facilities.

### [Moving Vehicle]

The memory device of one embodiment of the present invention can be used in an automobile, which is a moving vehicle, and the periphery of a driver's seat in the automobile.

FIG. 31G illustrates an automobile 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a display device showing the above information may be provided around the driver's seat.

In particular, the display device can compensate for the view obstructed by a pillar, blind areas for the driver's seat, and the like by displaying a video from an imaging device (not illustrated) provided for the automobile 5700, which can improve safety. That is, displaying an image taken by the imaging device provided on the exterior of the automobile 5700 can compensate for blind areas and improve safety.

The memory device of one embodiment of the present invention can temporarily retain information; thus, the memory device can be used to retain temporary information necessary in a system conducting automatic driving, navigation, risk prediction, or the like for the automobile 5700, for example. Moreover, the memory device of one embodiment of the present invention may be configured to retain a video of a driving recorder provided in the automobile 5700.

Although the automobile is described above as an example of a moving vehicle, the moving vehicle is not limited to the automobile. Examples of the moving vehicle include a train, a monorail train, a ship, and a flying object (a helicopter, an unmanned aircraft (drone), an airplane, or a rocket).

### [Camera]

The memory device of one embodiment of the present invention can be used in a camera.

FIG. 31H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that the digital camera 6240 is configured here such that the lens 6246 is detachable from the housing 6241 for replacement; alternatively, the lens 6246 may be integrated with the housing 6241. Moreover, the digital camera 6240 may be configured to be additionally equipped with a stroboscope, a viewfinder, or the like.

By using the memory device of one embodiment of the present invention, the digital camera 6240 can have low power consumption. Moreover, heat generation from a circuit can be reduced owing to low power consumption; thus, the influence of heat generation on the circuit itself, a peripheral circuit, and a module can be reduced.

### [Video Camera]

The memory device of one embodiment of the present invention can be used in a video camera.

FIG. 31I illustrates a video camera 6300 as an example of an imaging device. The video camera 6300 includes a first housing 6301, a second housing 6302, a display portion 6303, an operation switch 6304, a lens 6305, a connection portion 6306, and the like. The operation switch 6304 and the lens 6305 are provided in the first housing 6301, and the display portion 6303 is provided in the second housing 6302. The first housing 6301 and the second housing 6302 are connected to each other with the connection portion 6306, and the angle between the first housing 6301 and the second housing 6302 can be changed with the connection portion 6306. Videos displayed on the display portion 6303 may be switched in accordance with the angle at the connection portion 6306 between the first housing 6301 and the second housing 6302.

When a video taken by the video camera 6300 is recorded, the video needs to be encoded in accordance with a data recording format. With the use of the memory device of one embodiment of the present invention, the video camera 6300 can retain a temporary file generated at the time of encoding.

### [ICD]

The memory device of one embodiment of the present invention can be used in an implantable cardioverter-defibrillator (ICD).

FIG. 31J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with the end of one of the wires placed in the right ventricle and the end of the other wire placed in the right atrium.

The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor, the number of times the treatment with pacing is performed, and the time taken for the treatment, for example, can be stored in the electronic component 700.

The antenna 5404 can receive electric power, and the battery 5401 is charged with the electric power. When the ICD main unit 5400 includes a plurality of batteries, the safety can be improved. Specifically, even when some of the batteries in the ICD main unit 5400 are dead, the other batteries can work properly; hence, the batteries also function as an auxiliary power source.

In addition to the antenna 5404 that can receive electric power, an antenna that can transmit a physiological signal may be included to construct, for example, a system that monitors cardiac activity by checking physiological signals such as a pulse, a respiratory rate, a heart rate, and body temperature with an external monitoring device.

### [Expansion Device for PC]

The memory device of one embodiment of the present invention can be used in a computer such as a PC (Personal Computer) and an expansion device for an information terminal.

FIG. 32A illustrates, as an example of the expansion device, a portable expansion device 6100 that is externally attached to a PC and includes a chip capable of storing information. The expansion device 6100 can store information using the chip when connected to a PC with a USB, for example. Note that FIG. 32A illustrates the portable expansion device 6100; however, the expansion device of one embodiment of the present invention is not limited thereto and may be a relatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the memory device of one embodiment of the present invention, for example. The substrate 6104 is provided with the electronic component 700 and a controller chip 6106, for example. The USB connector 6103 functions as an interface for connection to an external device.

### [SD Card]

The memory device of one embodiment of the present invention can be used in an SD card that can be attached to an electronic device such as an information terminal or a digital camera.

FIG. 32B is a schematic external view of an SD card, and FIG. 32C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the substrate 5113 is provided with the electronic component 700 and a controller chip 5115. Note that the circuit structures of the electronic component 700 and the controller chip 5115 are not limited to those described above, and the circuit structures may be changed as appropriate depending on circumstances. For example, a write circuit, a row driver, a read circuit, or the like provided in an electronic component may be incorporated into the controller chip 5115 instead of the electronic component 700.

When the electronic component 700 is also provided on the back surface side of the substrate 5113, the capacity of the SD card 5110 can be increased. In addition, a wireless chip with a wireless communication function may be provided on the substrate 5113. This enables wireless communication between an external device and the SD card 5110, making it possible to write and read data to/from the electronic component 700.

### [SSD]

The memory device of one embodiment of the present invention can be used in an SSD (Solid State Drive) that can be attached to an electronic device such as an information terminal.

FIG. 32D is a schematic external view of an SSD, and FIG. 32E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the substrate 5153 is provided with the electronic component 700, a memory chip 5155, and a controller chip 5156. When the electronic component 700 is also provided on the back surface side of the substrate 5153, the capacity of the SSD 5150 can be increased. A work memory is incorporated into the memory chip 5155. For example, a DRAM chip is used as the memory chip 5155. A processor, an ECC (Error-Correcting Code) circuit, and the like are incorporated into the controller chip 5156. Note that the circuit structures of the electronic component 700, the memory chip 5155, and the controller chip 5115 are not limited to those described above, and the circuit structures may be changed as appropriate depending on circumstances. For example, a memory functioning as a work memory may also be provided in the controller chip 5156.

### [Computer]

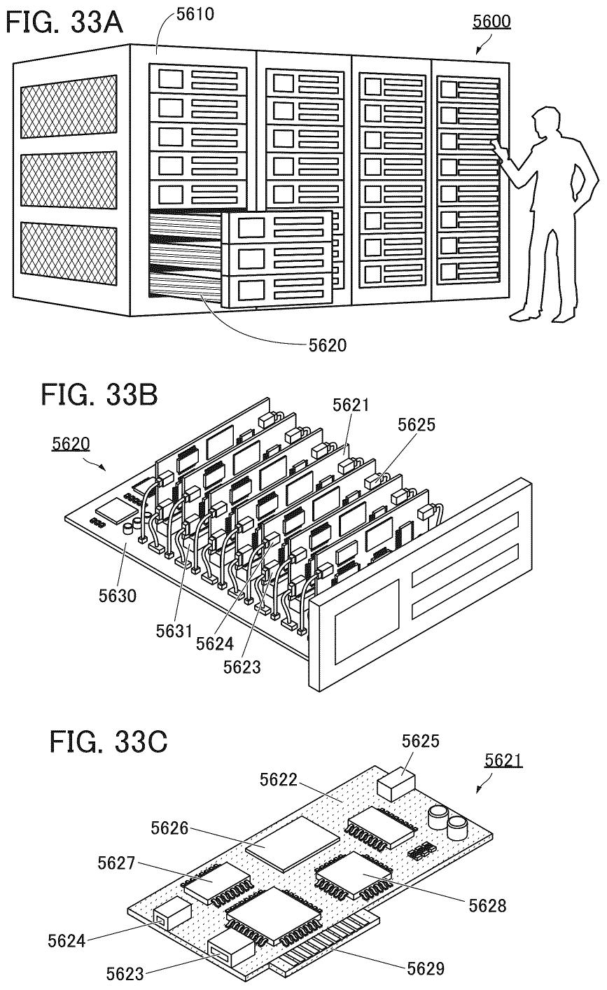

A computer 5600 illustrated in FIG. 33A is an example of a large computer. In the computer 5600, a plurality of rack mount computers 5620 are stored in a rack 5610.

The computer 5620 can have a structure in a perspective view illustrated in FIG. 33B, for example. In FIG. 33B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 33C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 33C also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve, for example, as an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices and the like described above, whereby a reduction in size and a reduction in power consumption of the electronic devices can be achieved. In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention can achieve an electronic device that operates stably even in a high-temperature environment. Thus, the reliability of the electronic device can be improved.

This embodiment can be combined with the other embodiments as appropriate.

### Embodiment 6

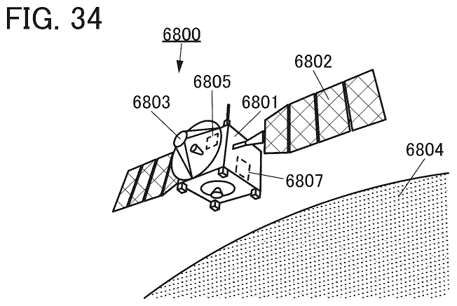

In this embodiment, specific examples of the case where the semiconductor device of one embodiment of the present invention is used in a device for space will be described with reference to FIG. 34.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space.

FIG. 34 illustrates an artificial satellite 6800 as an example of a device for space. The artificial satellite 6800 includes a body 6801, a solar panel 6802, an antenna 6803, a secondary battery 6805, and a control device 6807. Note that in FIG. 34, a planet 6804 in outer space is illustrated as an example. Note that outer space refers to, for example, space at an altitude greater than or equal to 100 km, and outer space described in this specification may include one or more of thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, meson beams, and the like.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

### REFERENCE NUMERALS

10A: semiconductor device, 10B: semiconductor device, 10C: semiconductor device, 10D: semiconductor device, 10E: semiconductor device, 10F: semiconductor device, 10: semiconductor device, 20a: memory cell, 20b: memory cell, 20c: memory cell, 20d: memory cell, 20e: memory cell, 20f: memory cell, 20: memory cell, 21: memory cell, 22: memory cell, 31A: transistor, 31Aa: transistor, 31Ab: transistor, 31Ac: transistor, 31Ad: transistor, 31B: transistor, 31Ba: transistor, 31Bb: transistor, 31Bc: transistor, 31Bd: transistor, 31: transistor, 32A: transistor, 32B: transistor, 32: transistor, 41a: capacitor, 41b: capacitor, 41c: capacitor, 41d: capacitor, 41: capacitor, 42: capacitor, 210: insulator, 212: insulator, 230: metal oxide, 241A: conductor, 241Aa: conductor, 241Ab: conductor, 241Ac: conductor, 241Ad: conductor, 241B: conductor, 241Ba: conductor, 241Bb: conductor, 241Bc: conductor, 241Bd: conductor, 241: conductor, 242A: conductor, 242Ac: conductor, 242Ad: conductor, 242B: conductor, 242Ba: conductor, 242Bb: conductor, 242: conductor, 250: insulator, 260A: conductor, 260Aa: conductor, 260Ab: conductor, 260Ac: conductor, 260Ad: conductor, 260B: conductor, 260Ba: conductor, 260Bb: conductor, 260Bc: conductor, 260Bd: conductor, 260: conductor, 261a: conductor, 261b: conductor, 261c: conductor, 261d: conductor, 261: conductor, 262A: conductor, 262Aa: conductor, 262Ab: conductor, 262Ac: conductor, 262Ad: conductor, 262B: conductor, 262Ba: conductor, 262Bb: conductor, 262Bc: conductor, 262Bd: conductor, 262: conductor, 263a: insulator, 263b: insulator, 263c: insulator, 263d: insulator, 263: insulator, 264a: conductor, 264b: conductor, 264c: conductor, 264d: conductor, 264: conductor, 270: insulator, 272: insulator, 274: insulator, 275: insulator, 276: insulator, 290A: conductor, 290Ac: conductor, 290Ad: conductor, 290B: conductor, 290Ba: conductor, 290Bb: conductor, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 500: memory device, 510: memory cell, 511: memory layer, 515: memory cell array, 522: PSW, 523: PSW, 531: peripheral circuit, 532: control circuit, 533: voltage generation circuit, 541: peripheral circuit, 542: row decoder, 543: row driver, 544: column decoder, 545: column driver, 546: sense amplifier, 547: input circuit, 548: output circuit, 550: driver circuit layer, 600: circuit, 652: AND circuit, 653: analog switch, 654: analog switch, 661: transistor, 662: transistor, 663: transistor, 664: transistor, 666: transistor, 700: electronic component, 702: printed circuit board, 704: circuit board, 711: mold, 712: land, 713: electrode pad, 714: wire, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: connection portion, 6800: artificial satellite, 6801: body, 6802: solar panel, 6803: antenna, 6804: planet, 6805: secondary battery, 6807: control device, 7500: stationary game machine, 7520: main body, 7522: controller

1. A semiconductor device comprising:
a first transistor and a second transistor over a substrate;
a capacitor over the first transistor and the second transistor; and
a first conductor for electrically connecting the capacitor to the first transistor or the second transistor,
wherein each of the first transistor and the second transistor comprises:
a second conductor;
a third conductor over the second conductor and comprising an opening overlapping with the second conductor;
a metal oxide in contact with a top surface of the second conductor through the opening of the third conductor;
a first insulator in contact with the metal oxide; and
a fourth conductor overlapping with the metal oxide with the first insulator therebetween,
wherein the first insulator is in a concave portion of the metal oxide,
wherein the fourth conductor is in a concave portion of the first insulator,
wherein the capacitor comprises a fifth conductor, a second insulator over the fifth conductor, and a sixth conductor over the second insulator,
wherein the fifth conductor is electrically connected to the second conductor in the first transistor through the first conductor, and
wherein the fifth conductor is electrically connected to the fourth conductor in the second transistor.

2. The semiconductor device according to claim 1, further comprising a seventh conductor,
wherein the seventh conductor is electrically connected to the fourth conductor in the first transistor,
wherein the seventh conductor is in the same layer as the fifth conductor, and
wherein the seventh conductor and the sixth conductor extend in a same direction.

3. A semiconductor device comprising:
a capacitor over a substrate;
a first transistor and a second transistor over the capacitor; and
a first conductor for electrically connecting the capacitor to the first transistor or the second transistor,
wherein each of the first transistor and the second transistor comprises:
a second conductor;
a third conductor over the second conductor and comprising an opening overlapping with the second conductor;
a metal oxide in contact with a top surface of the second conductor through the opening of the third conductor;
a first insulator in contact with the metal oxide; and
a fourth conductor overlapping with the metal oxide with the first insulator therebetween,
wherein the first insulator is in a concave portion of the metal oxide,
wherein the fourth conductor is in a concave portion of the first insulator,
wherein the capacitor comprises a fifth conductor, a second insulator over the fifth conductor, and the second conductor in the first transistor, and
wherein the second conductor in the first transistor is electrically connected to the fourth conductor in the second transistor through the first conductor.

4. The semiconductor device according to claim 3, further comprising a sixth conductor,
wherein the sixth conductor is electrically connected to the fourth conductor in the first transistor, and
wherein the sixth conductor and the fifth conductor extend in a same direction.

5. The semiconductor device according to claim 3, wherein a channel length of the second transistor is larger than a channel length of the first transistor.

6. A semiconductor device comprising:
a capacitor over a substrate;
a first transistor and a second transistor over the capacitor; and
a first conductor for electrically connecting the capacitor to the first transistor or the second transistor,
wherein each of the first transistor and the second transistor comprises:
a second conductor;
a third conductor over the second conductor and comprising an opening overlapping with the second conductor;
a metal oxide in contact with a top surface of the second conductor through the opening of the third conductor;
a first insulator in contact with the metal oxide; and
a fourth conductor in contact with a top surface of the metal oxide and a top surface of the first insulator,
wherein the capacitor comprises a fifth conductor, a second insulator over the fifth conductor, and the second conductor in the first transistor, and
wherein the second conductor in the first transistor is electrically connected to the third conductor in the second transistor through the first conductor.

7. The semiconductor device according to claim 6, wherein a channel length of the second transistor is larger than a channel length of the first transistor.

8. The semiconductor device according to claim 1,
wherein the metal oxide comprises two or three selected from indium, an element M, and zinc, and
wherein the element M is one or more kinds selected from aluminum, gallium, yttrium, or tin.

9. The semiconductor device according to claim 3,
wherein the metal oxide comprises two or three selected from indium, an element M, and zinc, and
wherein the element M is aluminum, gallium, yttrium, or tin.

10. The semiconductor device according to claim 6,
wherein the metal oxide comprises two or three selected from indium, an element M, and zinc, and
wherein the element M is aluminum, gallium, yttrium, or tin.
